(19) United States
(12) Patent Application Publication
(10) Pub. No.: US 2022/0169771 A1
(43) Pub. Date: Jun. 2, 2022

(54) RESIN, CURABLE COMPOSITION, CURED PRODUCT, COLOR FILTER, SOLID-STATE IMAGING ELEMENT, IMAGE DISPLAY DEVICE, AND POLYMER COMPOUND

(71) Applicant: FUJIFILM Corporation, Tokyo (JP)

(72) Inventors: Yutaro FUKAMI, Shizuoka (JP); Akio MIZUNO, Shizuoka (JP); Yushi KANEKO, Shizuoka (JP); Hirotaka TAKISHITA, Shizuoka (JP)

(73) Assignee: FUJIFILM Corporation, Tokyo (JP)

(21) Appl. No.: 17/673,786

(22) Filed: Feb. 17, 2022

Related U.S. Application Data
(63) Continuation of application No. PCT/JP2020/028279, filed on Jul. 21, 2020.

(30) Foreign Application Priority Data
Aug. 30, 2019 (JP) 2019-158702

(51) Int. Cl. C08F 290/04; G03F 7/00; C08F 20/18

(52) U.S. Cl. CPC C08F 290/046; C08F 20/18; G03F 7/0007

(57) ABSTRACT

Provided are a resin having a graft structure represented by Formula (1); a curable composition and a cured product of the resin; a color filter including the cured product; a solid-state imaging element or an image display device including the color filter; and a novel polymer compound. In Formula (1), P¹ represents a polymer chain, X¹ represents an alkylene group having a length of 3 or more atoms, L represents a single bond or a divalent linking group, and * represents a connection position with a structure including a main chain.

P¹—S—X¹-L-* (1)

### CROSS-REFERENCE TO RELATED APPLICATIONS

This application is a continuation application of International Application No. PCT/JP2020/028279, filed Jul. 21,2020, the disclosure of which is incorporated herein by reference in its entirety. Further, this application claims priority from Japanese Patent Application No. 2019-158702, filed Aug. 30, 2019, the disclosures of which is incorporated herein by reference in its entirety.

### BACKGROUND OF THE INVENTION

### 1. Field of the Invention

The present disclosure relates to a resin, a curable composition, a cured product, a color filter, a solid-state imaging element, an image display device, and a polymer compound.

### 2. Description of the Related Art

In recent years, as a digital camera, a mobile phone with a camera, and the like have been further spreading, there has been a greatly increasing demand for a solid-state imaging element such as a charge coupled device (CCD) image sensor. A color filter or the like has been used as a key device in a display or an optical element.

The color filter has been manufactured using a curable composition including a colorant and a resin. In addition, in a case where a pigment is used as the colorant, the pigment is generally dispersed in the curable composition using a dispersant or the like.

As a dispersant in the related art, dispersants disclosed in JP2007-321141A and WO2008/00776A have been known.

### SUMMARY OF THE INVENTION

An object to be achieved by one embodiment according to the present disclosure is to provide a resin having excellent dispersibility and storage stability.

An object to be achieved by another embodiment according to the present disclosure is to provide a curable composition and a cured product including the resin, a color filter including the cured product, and a solid-state imaging element or an image display device including the color filter.

An object to be achieved by still another embodiment according to the present disclosure is to provide a novel polymer compound.

The present disclosure includes the following aspects.

<1> A resin having a graft structure represented by Formula (1),

P¹—S—X¹-L-* (1)

In Formula (1), P¹ represents a polymer chain, X¹ represents an alkylene group having a length of 3 or more atoms, L represents a single bond or a divalent linking group, and * represents a connection position with a structure including a main chain.

<2> The resin according to <1>,

in which P¹ is a poly(meth)acrylate chain.

<3> The resin according to <1> or <2>,

in which L is a linking group including a urethane bond, a urea bond, an ester bond, an amide bond, or an ether bond.

<4> The resin according to any one of <1> to <3>,

in which the number of consecutive carbon atoms included in X¹ is 3 to 20.

<5> The resin according to any one of <1> to <4>,

in which the resin is an acrylic resin, a polyester resin, a polyamide resin, or a polyurethane resin.

<6> The resin according to any one of <1> to <5>,

in which the resin is a dispersant.

<7> A curable composition comprising:

the resin according to any one of <1> to <6>.

<8> A cured product obtained by curing the curable composition according to <7>.

<9> A color filter comprising:

the cured product according to <8>.

<10> A solid-state imaging element comprising:

the color filter according to <9>.

<11> An image display device comprising:

the color filter according to <9>.

<12> A polymer compound represented by Formula (1a).

P¹—S—X-L-Z¹ (1a)

In Formula (1a), P¹ represents a polymer chain, X¹ represents a divalent linking group having a length of 3 or more atoms, L represents a single bond or a divalent linking group, and Z¹ represents an ethylenically unsaturated group or a group having a diol structure, a diamine structure, or an amino alcohol structure.

<13> The polymer compound according to <12>,

in which P¹ is a poly(meth)acrylate chain.

<14> The polymer compound according to <12> or <13>,

in which L is a linking group including a urethane bond, a urea bond, an ester bond, an amide bond, or an ether bond.

<15> The polymer compound according to any one of <12> to <14>,

in which the ethylenically unsaturated group in Z¹ includes a (meth)acryloxy group.

<16> The polymer compound according to any one of <13> to <16>,

in which the number of consecutive carbon atoms included in X¹ is 3 to 20.

According to one embodiment according to the present disclosure, a resin having excellent dispersibility and storage stability is provided.

According to another embodiment according to the present disclosure, a curable composition and a cured product including the above-described resin, a color filter including the cured product, and a solid-state imaging element or an image display device including the color filter are provided.

According to still another embodiment according to the present disclosure, a novel polymer compound is provided.

### DESCRIPTION OF THE PREFERRED EMBODIMENTS

Hereinafter, the contents of the present disclosure will be described in detail. The configuration requirements will be described below based on the representative embodiments of the present disclosure, but the present disclosure is not limited to such embodiments.

In the present disclosure, a term “to” showing a range of numerical values is used as a meaning including a lower limit value and an upper limit value disclosed before and after the term.

In a range of numerical values described in stages in the present disclosure, the upper limit value or the lower limit value described in one range of numerical values may be replaced with an upper limit value or a lower limit value of the range of numerical values described in other stages. In addition, in a range of numerical values described in the present disclosure, the upper limit value or the lower limit value of the range of numerical values may be replaced with values shown in the examples.

Further, in the present disclosure, in a case where a plurality of substances corresponding to each component in a composition is present, the amount of each component in the composition means the total amount of the plurality of substances present in the composition, unless otherwise specified.

In addition, regarding a term, group (atomic group) of this present disclosure, a term with no description of “substituted” and “unsubstituted” includes both a group not including a substituent and a group including a substituent. For example, an “alkyl group” includes not only an alkyl group having no substituent (unsubstituted alkyl group), but also an alkyl group having a substituent (substituted alkyl group).

In the present disclosure, unless otherwise specified, “Me” represents a methyl group, “Et” represents an ethyl group, “Pr” represents a propyl group, “Bu” represents a butyl group, and “Ph” represents a phenyl group.

In the present disclosure, the concept of “(meth)acryl” includes both acryl and methacryl, and the concept of “(meth)acryloyl” includes both acryloyl and methacryloyl.

In addition, in the present disclosure, a term “step” includes not only the independent step but also a step in which intended purposes are achieved even in a case where the step cannot be precisely distinguished from other steps.

In the present disclosure, a “total solid content” refers to a total mass of components obtained by removing a solvent from the whole composition of the composition. In addition, a “solid content” is a component obtained by removing a solvent as described above, and for example, the component may be solid or may be liquid at 25° C.

In addition, in the present disclosure, “mass %” is identical to “weight %” and “part by mass” is identical to “part by weight”.

Furthermore, in the present disclosure, a combination of two or more preferred aspects is a more preferred aspect.

In addition, the weight-average molecular weight (Mw) and the number-average molecular weight (Mn) in the present disclosure are molecular weights in terms of polystyrene used as a standard substance, which are detected by using a solvent tetrahydrofuran (THF), a differential refractometer, and a gel permeation chromatography (GPC) analysis apparatus using TSKgel GMHxL, TSKgel G4000HxL, and TSKgel G2000HxL (all trade names manufactured by Tosoh Corporation) as columns, unless otherwise specified.

Hereinafter, the present disclosure will be described in detail.

(Resin)

A resin according to an embodiment of the present disclosure has a graft structure represented by Formula (1).

P¹—S—X¹-L-* (1)

In Formula (1), P¹ represents a polymer chain, X¹ represents an alkylene group having a length of 3 or more atoms, L represents a single bond or a divalent linking group, and * represents a connection position with a structure including a main chain.

In recent years, as the number of pixels of an image sensor has increased, the pattern has been finer and thinner. Along with this, a concentration of a pigment in a color filter increases relatively, and further development of a dispersant has been required. The dispersant is generally adsorbed on the pigment through an acid group in a dispersing group, and dispersion stability of the pigment is ensured by a steric repulsive group in the dispersing group. As a result of intensive studies by the present inventors, since the resin having the graft structure represented by Formula (1) according to the present disclosure (hereinafter, also referred to as a “resin represented by Formula (1) according to the present disclosure”) has a certain length from the connection position with a structure including the main chain to P¹, it is presumed that a steric repulsion effect of the graft structure portion is easily exhibited, and that dispersibility and storage stability of the pigment and the like are excellent.

In addition, since the above-described resin has the above-described specific structure, the steric repulsion effect is easily exhibited, and a ratio of the hydrophobic portion in the resin can be suppressed. Therefore, it is presumed that a curable composition including the above-described resin is also excellent in developability as compared with a case of including the dispersant in the related art.

Hereinafter, details of each configuration of the resin represented by Fonnula (1) according to the present disclosure will be described.

The resin represented by Formula (1) according to the present disclosure can be suitably used as a dispersant.

The weight-average molecular weight of the resin represented by Formula (1) according to the present disclosure is preferably 500 to 20,000. The lower limit is preferably 600 or more and more preferably 1,000 or more. The upper limit is preferably 10,000 or less, more preferably 5,000 or less, and still more preferably 3,000 or less.

[P¹]

The resin represented by Formula (1) according to the present disclosure has a graft structure, and in Formula (1), P¹ represents a polymer chain.

Since the resin represented by Formula (1) according to the present disclosure has a polymer chain represented by P¹ as the graft structure, dispersibility and storage stability are excellent.

P¹ is not particularly limited, and examples thereof include a vinyl-based polymer chain, an acrylic polymer chain, and a styrene-based polymer chain.

Examples of the vinyl-based polymer include polyethylene, polypropylene, polystyrene, a vinyl chloride copolymer, a vinyl chloride-vinyl acetate copolymer, polyvinylpyrrolidone, polyvinyl butyral, and polyvinyl alcohol.

The vinyl-based polymer means a polymer including a constitutional unit formed of polyethylene, polypropylene, polystyrene, a vinyl chloride copolymer, a vinyl chloride-vinyl acetate copolymer, polyvinylpyrrolidone, polyvinyl butyral, polyvinyl alcohol, or the like.

Examples of the acrylic polymer include homopolymers and copolymers of acrylic acid-based monomers such as acrylic acid, methacrylic acid, acrylic acid ester, and methacrylic acid ester.

The acrylic polymer means a polymer including a constitutional unit formed of acrylic acid, methacrylic acid, acrylic acid ester, methacrylic acid ester, or the like.

Examples of the styrene-based polymer include polystyrene and acrylonitrile/styrene copolymer (AS resin).

The styrene-based polymer means a polymer including a constitutional unit formed of styrene.

Among these, as P¹, from the viewpoint of dispersibility and storage stability, an acrylic polymer chain is preferable, a poly(meth)acrylate chain is more preferable, and a poly(meth)alkylacrylate chain is still more preferable.

As the alkyl group in the polyalkyl (meth)acrylate chain, an alkyl group having 1 to 12 carbon atoms is preferable, an alkyl group having 1 to 6 carbon atoms is more preferable, and an alkyl group having 1 to 4 carbon atoms is still more preferable.

The polymer chain represented by P¹ may be used singly or in combination of two or more kinds of polymer chains.

From the viewpoint of dispersibility and storage stability, the polymer chain represented by P¹ preferably includes two or more kinds of polymer chains, more preferably includes two to four kinds of polymer chains, still more preferably two or three kinds of polymer chains, and particularly preferably two kinds of polymer chains.

As P¹, from the viewpoint of dispersibility and storage stability, it is preferable to include two to four kinds of polyalkyl (meth)acrylate chains having 1 to 6 carbon atoms, it is more preferable to include two or three kinds of polyalkyl (meth)acrylate chains having 1 to 6 carbon atoms, it is still more preferable to include two kinds of alkyl (meth)acrylate chains having 1 to 4 carbon atoms, and it is particularly preferable to include an alkyl acrylate chain having 1 to 4 carbon atoms and an alkyl methacrylate chain having 1 to 4 carbon atoms.

The Hansen solubility parameter of the polymer chain represented by P¹ is preferably 7.0 (cal/cm³)^{0.5} to 13.0 (cal/cm³)^{0.5}. The upper limit is preferably 12.5 (cal/cm³)^{0.5} or less and more preferably 12.0 (cal/cm³)^{0.5} or less. The lower limit is preferably 7.5 cal/cm³ or more and more preferably 8.0 (cal/cm³)^{0.5} or more.

In a case where the Hansen solubility parameter of the polymer chain is within the above-described range, the dispersibility of the pigment is good and excellent storage stability can be easily obtained.

The Hansen solubility parameter is defined by three-dimensional parameters of London dispersion force element, molecular polarization element (dipole-dipole force element), and hydrogen bond element, and is a value represented by the following expression (H-1). The details regarding the Hansen solubility parameter are described in “PROPERTIES OF POLYMERS” (writer: D. W. VAN KREVELEN, publisher: ELSEVIER SCIENTIFIC PUBLISHING COMPANY, published in 1989, 5th edition).

δ²=(δD)²+(δP)²+(δH)² (H-1)

δ: Hansen solubility parameter

δD: London dispersion force element

δP: molecular polarization element (dipole-dipole force element)

δH: hydrogen bond element

In the present specification, the Hansen solubility parameter of the polymer chain is obtained from the above expression (H-1) by calculating London dispersion force element (δD), molecular polarization element (dipole-dipole force element) (δP), and hydrogen bond element (δH) of the monomer corresponding to the repeating unit of the polymer chain using Hansen Solubility Parameters in Practice (HSPiP), ver. 4.1.07, which is a program developed by Dr. Hansen's group proposed the Hansen solubility parameter.

In addition, in a case where the polymer chain is a copolymer, the sum of values obtained by multiplying the value of Hansen solubility parameter of the monomer which corresponds to each repeating unit of the copolymer by the mass ratio of each repeating unit of the copolymer is used.

In addition, the absolute value obtained by subtracting the solubility parameter (SP value) of the polymer chain represented by P¹ from the SP value of an organic solvent described later is preferably 2.3 or less and more preferably 1.8 or less.

In a case where the absolute value obtained by subtracting the SP value of the polymer chain represented by P¹ from the SP value of the organic solvent is within the above-described range, since the polymer chain represented by P¹ easily spreads in the organic solvent, the storage stability is further improved.

Here, the solubility parameter (SP value) is a value calculated in accordance with the Okitsu method (“Journal of the Adhesion Society of Japan”, 29(5) (1993), authored by Toshinao Okitsu).

Specifically, the SP value is calculated using the following expression. ΔF denotes the value described in the journal.

SP value (δ)=ΣΔF (Molar Attraction Constants)/V (molar volume)

In addition, the unit of the SP value in the present specification is MPa^{1/2}.

In addition, in a case where a mixture of a plurality of organic solvents is used as the organic solvent, the SP value is obtained as a weighted average value according to the content mass ratio of each organic solvent.

Specifically, the above-described weighted average value is “X” obtained by the following mathematical expression 1.

Specifically, with regard to the SP value of an organic solvent A including two or more kinds of organic solvents, in the following mathematical expression 1, the SP value of an organic solvent of the i-item (i represents an integer of 1 or more) contained in the organic solvent A is substituted into Si, and the mass content of the organic solvent of the i-item in the entire organic solvent A is substituted into Wi, and the SP value of the organic solvent A is calculated as X.

$$X = \frac{\sum ( Si \times Wi )}{\sum Wi} \qquad Mathematical expression 1$$

In Formula (1), X¹ represents an alkylene group having a length of 3 or more atoms.

In the present disclosure, an alkylene group having a length of 3 or more atoms means that, in Formula (1), the number of atoms having the shortest chain length from S atom to L is 3 or more.

For example, in a case where Formula (1) has the following structure, the number of atoms having the shortest chain length from S atom to L is 6.

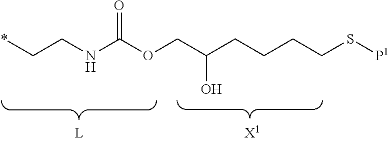

In the above structure, L represents a single bond or a divalent linking group, X¹ represents an alkylene group having a length of 3 or more atoms, P¹ represents a polymer chain, and * represents a connection position with a structure including a main chain.

In Formula (1), only one kind of atom may be included in X¹, or a plurality thereof may be included. From the viewpoint of dispersibility and storage stability, it is preferable that only one kind of atom is included in X¹.

In addition, the above-described alkylene group may have a substituent. Examples of the substituent include a hydroxy group, an amino group, and an alkoxy group.

In Formula (1), from the viewpoint of dispersibility and storage stability, the number of consecutive carbon atoms included in X¹ is preferably 3 to 20, more preferably 4 to 20, still more preferably 4 to 12, and particularly preferably 4 to 10.

In Formula (1), as X¹, from the viewpoint of dispersibility and storage stability, an alkylene group having 4 or more carbon atoms, which is unsubstituted or has a hydroxy group as a substituent, is preferable, an alkylene group having 4 to 20 carbon atoms, which is unsubstituted or has a hydroxy group as a substituent, is more preferable, an alkylene group having 4 to 12 carbon atoms, which is unsubstituted or has a hydroxy group as a substituent, is still more preferable, and an unsubstituted alkylene group having 4 to 10 carbon atoms is particularly preferable.

In the alkylene group having a length of 3 or more atoms, a bonding site on a side which is not bonded to the sulfur atom (S) is preferably bonded to a carbonyl group or a heteroatom, and more preferably bonded to a carbonyl group or an oxygen atom.

The alkylene group having a length of 3 or more atoms may further have a divalent alkylene group which may have a heteroatom between the alkylene group and the sulfur atom (S). Examples of the divalent alkylene group which may have a heteroatom include groups such as —O—, —C(═O)—, and —C(═O)—O—, and groups consisting of two or more of these groups. From the viewpoint of ease of synthesis, dispersibility, and storage stability, it is preferable that the alkylene group having a length of 3 or more atoms does not have a divalent alkylene group which may have a heteroatom between the alkylene group and the sulfur atom (S).

[L]

In Formula (1), L represents a single bond or a divalent linking group.

Examples of the divalent linking group include an alkylene group, and a linking group including a urethane bond, a urea bond, an ester bond, an amide bond, or an ether bond.

As the divalent linking group, from the viewpoint of dispersibility and storage stability, a linking group including a urethane bond, a urea bond, an ester bond, an amide bond, or an ether bond is preferable, a linking group including a urethane bond, a urea bond, an ester bond, or an ether bond is more preferable, and a linking group including a urethane bond is still more preferable.

In a case where L is a divalent linking group, a linking group having a structure represented by (L1) is preferable.

**-L¹-L²-* (L1)

In (L1), L¹ represents an alkylene group, a urethane bond, a urea bond, an ester bond, an amide bond, or an ether bond, L² represents an alkylene group having 1 to 10 carbon atoms or —R^{L1}—O—R^{L2}—, R^{L1} and R^{L2} each independently represent an alkylene group having 1 to 4 carbon atoms, ** represents a connection position with X¹ in Formula (1), and * represents a connection position with the structure including the main chain.

The alkylene group having 1 to 10 carbon atoms, represented by L², may be a linear, branched, or cyclic alkylene group, and may have a substituent.

From the viewpoint of dispersibility and storage stability, the alkylene group represented by L² is preferably a linear or cyclic alkylene group, and more preferably a linear alkylene group.

Suitable examples of the substituent included in the alkylene group having 1 to 10 carbon atoms include a hydroxy group.

As the alkylene group having 1 to 10 carbon atoms, a linear alkylene group having 2 to 8 carbon atoms or a cyclic alkylene group having 4 to 8 carbon atoms is preferable, a linear alkylene group having 2 to 4 carbon atoms or a cyclic alkylene group having 4 to 6 carbon atoms is more preferable, and a linear alkylene group having 2 or 3 carbon atoms is still more preferable.

From the viewpoint of dispersibility and storage stability, it is preferable that L¹ is a urethane bond, a urea bond, an ester bond, an amide bond, or an ether bond and L² is a linear alkylene group having 2 to 8 carbon atoms or a cyclic alkylene group having 4 to 8 carbon atoms, it is more preferable that L¹ is a urethane bond and L² is a linear alkylene group having 2 to 4 carbon atoms, or that L¹ is an ether bond and L² is a cyclic alkylene group having 4 to 6 carbon atoms, and it is still more preferable that L¹ is a urethane bond and L² is a linear alkylene group having 2 or 3 carbon atoms.

Examples of a combination of L¹ and L² in Formula (L1) include the following combinations, but it is needless to say the present disclosure is not limited thereto. In L² below, a wavy line represents a connection position with other configurations.

L

| L¹ | L² |
|---|---|
| Urethane bond | —C₂H₄— |
| Urea bond | —C₂H₄— |
| Ester bond | —C₂H₄— |
| Amide bond | —C₂H₄— |
| Ether bond | —C₂H₄— |
| Urethane bond | —C₂H₄—O—C₂H₄— |
| Ether bond | —CH₂—CH(OH)—CH₂— |
| Ether bond | —CH₂—CH(OH)—CH₂—O—CH₂— |
| Ether bond | 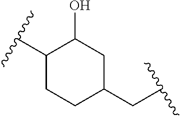 [SMILES: *CC1CCC(*)C(O)C1] |
| Ether bond | 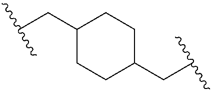 [SMILES: *CC1CCC(C*)CC1] |
| Ester bond | —C₇H₁₄— |
| Ether bond | —CH₂— |

The resin represented by Formula (1) according to the present disclosure may be an addition polymerization-type resin, a polycondensation resin, or a polyaddition resin.

In the present disclosure, the polycondensation resin refers to a resin obtained by a polycondensation reaction, and the polyaddition resin refers to a resin obtained by a polyaddition reaction.

Examples of the polycondensation resin include a polyamide resin and a polyester resin. In addition, examples of the polyaddition resin include a polyurethane resin and a polyurea resin.

Examples of the addition polymerization-type resin include an acrylic resin and a styrene resin.

As the resin represented by Formula (1) according to the present disclosure, from the viewpoint of dispersibility and storage stability, an acrylic resin, a polyester resin, a polyamide resin, or a polyurethane resin is preferable, and an acrylic resin is more preferable.

In the resin represented by Formula (1) according to the present disclosure, from the viewpoint of dispersibility and storage stability, it is preferable that, in Formula (1), P¹ includes two to four kinds of polyalkyl (meth)acrylate chains having 1 to 6 carbon atoms (more preferably, including two or three kinds of polyalkyl (meth)acrylate chains having 1 to 6 carbon atoms, still more preferably, including two kinds of alkyl (meth)acrylate chains having 1 to 4 carbon atoms, and particularly preferably, including an alkyl acrylate chain having 1 to 4 carbon atoms and an alkyl methacrylate chain having 1 to 4 carbon atoms), X¹ is an alkylene group having 4 or more carbon atoms (more preferably, an alkylene group having 4 to 20 carbon atoms, still more preferably, an alkylene group having 4 to 12 carbon atoms, and particularly preferably, an alkylene group having 4 to 10 carbon atoms), and L is a divalent linking group (more preferably, a linking group having the structure represented by (L1), still more preferably, L¹ in (L1) is a urethane bond, a urea bond, an ester bond, an amide bond, or an ether bond and L² is a linear alkylene group having 2 to 8 carbon atoms or a cyclic alkylene group having 4 to 8 carbon atoms, particularly preferably, L¹ is a urethane bond and L² is a linear alkylene group having 2 to 4 carbon atoms, or L¹ is an ether bond and L² is a cyclic alkylene group having 4 to 6 carbon atoms, and most preferably, L¹ is a urethane bond and L² is a linear alkylene group having 2 or 3 carbon atoms).

The resin represented by Formula (1) according to the present disclosure is preferably a resin obtained by polymerizing a polymer compound having a graft structure represented by Formula (1a).

In addition, the polymer compound (macromonomer) represented by Formula (1a) according to the present disclosure is a novel compound.

P¹—S—X¹-L-Z¹ (1a)

In Formula (1a), P¹ represents a polymer chain, X¹ represents a divalent linking group having a length of 3 or more atoms, L represents a single bond or a divalent linking group, and Z¹ represents an ethylenically unsaturated group or a group having a diol structure, a diamine structure, or an amino alcohol structure.

P¹, X¹, and L in Formula (l a) have the same meaning as P¹, X¹, and L in Formula (1) described above, the preferred aspects thereof are also the same.

[Z¹]

In Formula (1a), Z¹ represents an ethylenically unsaturated group or a group having a diol structure, a diamine structure, or an amino alcohol structure.

The ethylenically unsaturated group is not particularly limited, but examples thereof include a vinyl group, an allyl group, a vinylphenyl group, a (meth)acrylamide group, and a (meth)acryloxy group. Among these, from the viewpoint of reactivity, the ethylenically unsaturated group is preferably a (meth)acryloxy group or a (meth)acrylamide group and more preferably a (meth)acryloxy group.

Examples of the group having a diol structure include a group having a 1,2-diol structure and a group having a 1,3-diol structure, and more specific examples thereof include a group obtained by removing one hydrogen atom other than a hydroxy group from 1,2-ethanediol, 1,2-propanediol, 1,3-propanediol, 1,2-butanediol, 1,3-butanediol, 1,2-pentanediol, 1,2-hexanediol, 1,2-heptanediol, diethanolamine, or the like.

Among these, from the viewpoint of dispersibility and storage stability, the group having a diol structure is preferably a group obtained by removing one hydrogen atom other than a hydroxy group from 1,2-ethanediol, 1,2-propanediol, 1,3-propanediol, 1,2-butanediol, or 1,3-butanediol.

Examples of the group having a diamine structure include a group having a 1,2-diamine structure and a group having a 1,3-diamine structure, and more specific examples thereof include a group obtained by removing one hydrogen atom other than an amino group from ethylenediamine, 1,2-diaminopropane, 1,3-diaminopropane, 1,4-diaminobutane, or the like.

Among these, from the viewpoint of dispersibility and storage stability, the group having a diamine structure is preferably a group obtained by removing one hydrogen atom other than an amino group from ethylenediamine, 1,2-diaminopropane, 1,3-diaminopropane, or 1,4-diaminobutane.

Examples of the group having an amino alcohol structure include amino alcohol having no diol structure, and examples thereof include a group obtained by removing one hydrogen atom other than a hydroxy group and an amino group from aminoethoxyethanol, isopropanolamine, triethanolamine, monoethanolamine (2-aminoethanol), N,N-dimethylethanolamine, N,N-diethylethanolamine, N,N-dibutylethanolamine, N-methylethanolamine, N-(2-aminoethyl) ethanolamine, or the like.

From the viewpoint of dispersibility and storage stability, Z¹ in Formula (1a) is preferably an ethylenically unsaturated group or a group having a diol structure, more preferably an ethylenically unsaturated group, and still more preferably a (meth)acryloxy group.

From the viewpoint of dispersibility and storage stability, the weight-average molecular weight (Mw) of the polymer compound represented by Formula (1a) according to the present disclosure is preferably 1,500 to 5,000, more preferably 2,000 to 4,000, and still more preferably 2,500 to 3,500.

The content of the polymer compound represented by Formula (1a) according to the present disclosure is preferably 10 parts by mass to 100 parts by mass, more preferably 20 parts by mass to 80 parts by mass, and still more preferably 30 parts by mass to 60 parts by mass with respect to 100 parts by mass of the total content including resins other than the resin represented by Formula (1) according to the present disclosure described later.

Suitable examples of the polymer compound represented by Formula (1a) according to the present disclosure include compounds shown below, but it is needless to say that the polymer compound represented by Formula (1a) according to the present disclosure is not limited thereto.

In addition, examples of the resin represented by Formula (1) according to the present disclosure include compounds obtained by polymerizing the following exemplary compounds, but it is needless to say that the resin represented by Formula (1) according to the present disclosure is not limited thereto.

In the following exemplary compounds, for example, “—C6” represented by X¹ represents an alkylene group having 6 carbon atoms, and “—C2-O—C2-” represented by L² represents “—C₂H₄—O—C₂H₄—”. In addition, a wavy line represents a connection position with other configurations.

| Polymer | | | | | | |
|---|---|---|---|---|---|---|
| compound | | | | | | |
| represented by | | | | L | | |
| Formula (1a) | Monomer forming P¹ | | X¹ | L¹ | L² | Z¹ |
| R1 | Methyl methacrylate | Butyl acrylate | —C6— | Urethane | —C2— | Methacryloxy group |
| R2 | Methyl methacrylate | Butyl acrylate | —C3— | Urethane | —C2— | Methacryloxy group |
| R3 | Methyl methacrylate | Butyl acrylate | —C4— | Urethane | —C2— | Methacryloxy group |
| R4 | Methyl methacrylate | Butyl acrylate | —C5— | Urethane | —C2— | Methacryloxy group |
| R6 | Methyl methacrylate | Butyl acrylate | —C8— | Urethane | —C2— | Methacryloxy group |
| R9 | Methyl methacrylate | Butyl acrylate | —C20— | Urethane | —C2— | Methacryloxy group |
| R10 | Methyl methacrylate | Butyl acrylate | —C6— | Urea | —C2— | Methacryloxy group |
| R11 | Methyl methacrylate | Butyl acrylate | —C6— | Ester | —C2— | Methacryloxy group |
| R12 | Methyl methacrylate | Butyl acrylate | —C6— | Amide | —C2— | Methacryloxy group |
| R13 | Methyl methacrylate | Butyl acrylate | —C6— | Ether | —C2— | Methacryloxy group |
| R14 | Methyl methacrylate | Butyl acrylate | —C6— | Urethane | —C2—O—C2— | Methacryloxy group |
| R15 | Methyl methacrylate | Butyl acrylate | —C6— | Urethane | —C2— | Acryloxy group |
| R17 | Methyl methacrylate | Butyl acrylate | —C3— | None (single bond) | | Group having |
| | | | | | | diol structure |
| R18 | Methyl methacrylate | Butyl acrylate | —C3— | None | | Diol group |
| R19 | Ethyl methacrylate | | —C6— | Urethane | —C2— | Methacryloxy group |
| R20 | Ethyl methacrylate | Butyl acrylate | —C6— | Urethane | —C2— | Methacryloxy group |
| R21 | Methyl methacrylate | HEMA | —C6— | Urethane | —C2— | Methacryloxy group |
| R22 | Methyl methacrylate | Methacrylic acid | —C6— | Urethane | —C2— | Methacryloxy group |
| R23 | Methyl methacrylate | Butyl acrylate | —C6— | None | None | Methacryloxy group |
| R24 | Methyl methacrylate | Butyl acrylate | —C6— | None | None | Acryloxy group |
| R25 | Methyl methacrylate | Butyl acrylate | —C6— | Ether | —C1—C(OH)—C1— | Methacryloxy group |
| R26 | Methyl methacrylate | Butyl acrylate | —C6— | Ether | —C1—C(OH)—C1— | Acryloxy group |
| R27 | Methyl methacrylate | Butyl acrylate | —C6— | Ether | —C1—C(OH)—C1—O—C4— | Acryloxy group |
| R28 | Methyl methacrylate | Butyl acrylate | —C6— | Ether | 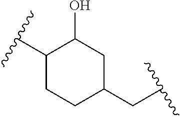 [SMILES: *CC1CCC(*)C(O)C1] | Methacryloxy group |
| R29 | Methyl methacrylate | Butyl acrylate | —C6— | Ether | 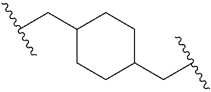 [SMILES: *CC1CCC(C*)CC1] | Acryloxy group |
| R30 | Methyl methacrylate | Butyl acrylate | —C6— | Ether | —C2— | Acrylamide group |
| R31 | Methyl methacrylate | Butyl acrylate | —C6— | Ether | —C1— | Styryl group |
| R32 | Methyl methacrylate | Butyl acrylate | —C6— | Ester | —C7— | Allyl group |
| R33 | Methyl methacrylate | Butyl acrylate | —C6— | Ether | —C1— | Vinyl ester group |
| R50 | Methyl methacrylate | Butyl acrylate | —C3— | Urethane | —C2— | Methacryloxy group |
| R51 | Methyl methacrylate | Butyl acrylate | —C3— | Urethane | —C2— | Methacryloxy group |
| R52 | Methyl methacrylate | Butyl acrylate | —C3— | Urethane | —C2— | Methacryloxy group |
| R53 | Methyl methacrylate | Butyl acrylate | —C9— | Urethane | —C2— | Methacryloxy group |
| R54 | Methyl methacrylate | Butyl acrylate | —C11— | Urethane | —C2— | Methacryloxy group |
| R55 | Methyl methacrylate | Butyl acrylate | —C3— | None | | Group having |
| | | | | | | diamine structure |
| R56 | Methyl methacrylate | Butyl acrylate | —C3— | None | | Group having |
| | | | | | | diamine structure |
| R57 | Methyl methacrylate | Butyl methacrylate | —C6— | Urethane | —C2— | Methacryloxy group |
| R58 | Methyl methacrylate | Benzyl methacrylate | —C6— | Urethane | —C2— | Methacryloxy group |
| R59 | Methyl methacrylate | Lauryl methacrylate | —C6— | Urethane | —C2— | Methacryloxy group |
| R60 | Methyl methacrylate | HPMA | —C6— | Urethane | —C2— | Methacryloxy group |
| R61 | Methyl methacrylate | Dipropylene glycol acrylate | —C6— | Urethane | —C2— | Methacryloxy group |
| R62 | Butyl acrylate | Butyl methacrylate | —C6— | Urethane | —C2— | Methacryloxy group |
| R63 | Butyl acrylate | Benzyl methacrylate | —C6— | Urethane | —C2— | Methacryloxy group |
| R64 | Butyl acrylate | Lauryl methacrylate | —C6— | Urethane | —C2— | Methacryloxy group |
| R65 | Butyl acrylate | HPMA | —C6— | Urethane | —C2— | Methacryloxy group |
| R66 | Butyl acrylate | Dipropylene glycol acrylate | —C6— | Urethane | —C2— | Methacryloxy group |
| R67 | Butyl methacrylate | Benzyl methacrylate | —C6— | Urethane | —C2— | Methacryloxy group |

A method for producing the polymer compound represented by Formula (1a) according to the present disclosure is not particularly limited and the polymer compound can be produced by various known methods. Examples thereof include a method in which, as shown in the synthesis scheme below, a compound used for introducing S in Formula (1a) and a compound used for introducing P¹ are polymerized in a solvent using a polymerization initiator, the obtained compound is reacted with a compound used for introducing Z¹, and then the obtained compound is further polymerized in a solvent using a polymerization initiator.

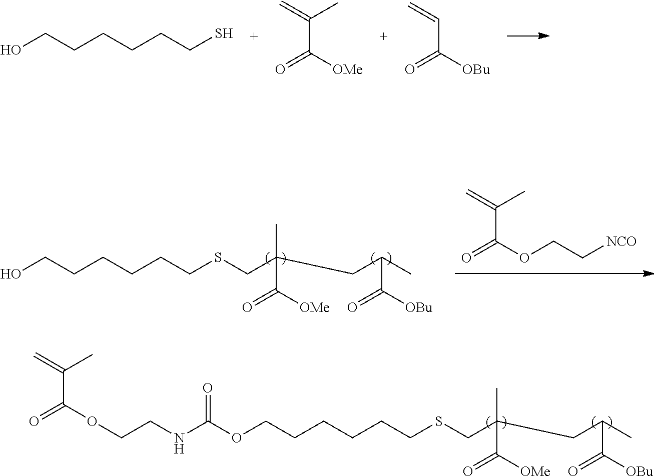

Examples of the compound used for introducing P¹ in Formula (1a) include a vinyl-based monomer, an acrylic monomer, and a styrene-based monomer.

Among these, as the compound used for introducing P¹, from the viewpoint of dispersibility and storage stability, an acrylic monomer is preferable, a (meth)acrylate is more preferable, and an alkyl (meth)acrylate is still more preferable.

As the alkyl (meth)acrylate, an alkyl (meth)acrylate having 1 to 12 carbon atoms is preferable, an alkyl (meth)acrylate having 1 to 6 carbon atoms is more preferable, and an alkyl (meth)acrylate having 1 to 4 carbon atoms is still more preferable.

Suitable examples of the compound used for introducing S in Formula (1a) include a compound containing a hydroxy group and a thiol group.

Examples of the compound containing a hydroxy group and a thiol group include mercaptoethanol, mercaptobutanol (3-mercapto-3-methyl-1-butanol), mercaptopropanol (3-mercapto-1-propanol), mercaptobenzoyl alcohol, mercaptohexanol, mercaptoundecanol, and mercaptophenol.

Among these, mercaptobutanol, mercaptopropanol, mercaptohexanol, mercaptoundecanol, or the like is preferable.

The compound used for introducing Z¹ in Formula (1a) can be appropriately selected depending on the desired polymer compound, and examples thereof include a compound having an epoxy group and an ethylenically unsaturated group (for example, glycidyl methacrylate and the like) and a compound having an isocyanate group and an ethylenically unsaturated group (2-isocyanatoethyl methacrylate and the like).

The above-described solvent is not particularly limited as long as it is a known organic solvent, but a solvent used in a curable composition according to the embodiment of the present disclosure described later is suitably used. The solvent may be used alone or in combination of two or more kinds thereof.

As the time of the polymerization reaction, for example, it is sufficient that the polymerization reaction may be carried out until the ethylenically unsaturated group included in the monomer derived from Z¹ disappears, and it is preferable to be 1 hour to 24 hours. In addition, the temperature of the above-described reaction is preferably 50° C. to 95° C.

(Curable Composition)

The curable composition according to the embodiment of the present disclosure preferably includes the resin represented by Formula (1) according to the present disclosure. The resin represented by Formula (1) according to the present disclosure may be included alone or in combination of two or more thereof.

The content of the resin represented by Formula (1) according to the present disclosure in the total solid content of the curable composition is preferably 5 mass % to 50 mass %. The lower limit is more preferably 10 mass % or more and particularly preferably 12 mass % or more. The upper limit is more preferably 40 mass % or less, still more preferably 35 mass % or less, and particularly preferably 30 mass % or less.

<Resin>

The curable composition according to the embodiment of the present disclosure preferably includes a resin other than the resin represented by Formula (1) according to the present disclosure (hereinafter, also referred to as “other resins”).

Suitable examples of the above-described other resins include a dispersant and a binder polymer.

From the viewpoint of film-forming property and dispersibility, it is preferable that the curable composition according to the embodiment of the present disclosure includes a binder polymer other than the resin represented by Formula (1) according to the present disclosure.

The binder polymer is blended in, for example, an application for dispersing particles such as a pigment in a composition or an application as a binder. Mainly, a resin which is used for dispersing particles such as a pigment is also referred to as a dispersant. However, such applications of the resin are only exemplary, and the resin can also be used for other purposes in addition to such applications.

The weight-average molecular weight (Mw) of the binder polymer is preferably 2,000 to 2,000,000. The upper limit is preferably 1,000,000 or less and more preferably 500,000 or less. The lower limit is preferably 3,000 or more and more preferably 5,000 or more.

Examples of the binder polymer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof.

The binder polymer may have an acid group. Examples of the acid group include a carboxy group, a phosphoric acid group, a sulfo group, and a phenolic hydroxy group, and a carboxy group is preferable. Among these acid groups, one kind may be used alone, or two or more kinds may be used in combination. The resin having an acid group can also be used as an alkali-soluble resin.

The resin having an acid group is preferably a polymer having a carboxy group in the side chain. Specific examples thereof include methacrylic acid copolymers, acrylic acid copolymers, itaconic acid copolymers, crotonic acid copolymers, maleic acid copolymers, partially esterified maleic acid copolymers, alkali-soluble phenol resins such as novolac resin, acidic cellulose derivatives having a carboxy group in the side chain, and resins in which an acid anhydride is added to a polymer having a hydroxy group. In particular, a copolymer of a (meth)acrylic acid and another monomer copolymerizable therewith is suitable as the alkali-soluble resin.

Examples of another monomer copolymerizable with the (meth)acrylic acid include alkyl (meth)acrylate, aryl (meth)acrylate, and a vinyl compound. Examples of the alkyl (meth)acrylate and the aryl (meth)acrylate include methyl (meth)acrylate, ethyl (meth)acrylate, propyl (meth)acrylate, butyl (meth)acrylate, isobutyl (meth)acrylate, pentyl (meth)acrylate, hexyl (meth)acrylate, octyl (meth)acrylate, phenyl (meth)acrylate, benzyl (meth)acrylate, tolyl (meth)acrylate, naphthyl (meth)acrylate, cyclohexyl (meth)acrylate, and glycidyl (meth)acrylate. Examples of the vinyl compound include styrene, α-methylstyrene, vinyltoluene, acrylonitrile, vinyl acetate, N-vinylpyrrolidone, a polystyrene macromonomer, and a polymethyl methacrylate macromonomer. In addition, examples of other monomers include the N-position-substituted maleimide monomers described in JP1998-300922A (JP-H10-300922A), such as N-phenylmaleimide and N-cyclohexylmaleimide.

Such other monomers copolymerizable with (meth)acrylic acids may be used singly or in combination of two or more kinds thereof.

As the resin having an acid group, a benzyl (meth)acrylate/(meth)acrylic acid copolymer, a benzyl (meth)acrylate/(meth)acrylic acid/2-hydroxyethyl (meth)acrylate copolymer, or a multicomponent copolymer formed of benzyl (meth)acrylate/(meth)acrylic acid/other monomers can be preferably used. In addition, copolymers described in JP1995-140654A (JP-H07-140654A) obtained by copolymerization of 2-hydroxyethyl (meth)acrylate can be preferably used, and examples thereof include: a copolymer including 2-hydroxypropyl (meth)acrylate, a polystyrene macromonomer, benzyl methacrylate, and methacrylic acid; a copolymer including 2-hydroxy-3-phenoxypropyl acrylate, a polymethyl methacrylate macromonomer, benzyl methacrylate, and methacrylic acid; a copolymer including 2-hydroxyethyl methacrylate, a polystyrene macromonomer, methyl methacrylate, and methacrylic acid; or a copolymer including 2-hydroxyethyl methacrylate, a polystyrene macromonomer, benzyl methacrylate, and methacrylic acid.

Preferred examples of the resin having an acid group also include polymers described in paragraphs 0153 to 0167 of JP2018-173660A.

With regard to the resin having an acid group, reference can be made to the description in paragraphs 0558 to 0571 of JP2012-208494A (paragraphs 0685 to 0700 of the corresponding US2012/0235099A) and the description in paragraphs 0076 to 0099 of JP2012-198408A, the contents of which are incorporated herein by reference. A commercially available product can also be used as the resin having an acid group.

The acid value of the resin having an acid group is preferably 30 mgKOH/g to 200 mgKOH/g. The lower limit is preferably 50 mgKOH/g or more and more preferably 70 mgKOH/g or more. The upper limit is preferably 150 mgKOH/g or less and more preferably 120 mgKOH/g or less.

The curable composition according to the embodiment of the present disclosure preferably includes a resin other than the resin represented by Formula (1) according to the present disclosure (hereinafter, also referred to as “other resins”) as a dispersant.

Examples of the other resins include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxy group. The acid value of the acidic dispersant (acidic resin) is preferably 40 mgKOH/g to 105 mgH/g, more preferably 50 mgKOH/g to 105 mgKOH/g, and still more preferably 60 mgKOH/g to 105 mgKOH/g. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The basic group included in the basic dispersant is preferably an amino group.

The other resins used as the dispersant preferably include a structural repeating unit having an acid group. By the resin, which is used as the dispersant, including the structural repeating unit having an acid group, in a case where a pattern is formed using a photolithography method, the amount of residues generated in a base of a pixel can be reduced.

The other resins used as the dispersant is also preferably a graft resin other than the resin represented by Formula (1) according to the present disclosure.

It is preferable that a graft chain included in the graft resin includes at least one structural repeating unit selected from the group consisting of a polyester structural repeating unit, a polyether structural repeating unit, a poly(meth)acrylic structural repeating unit, a polyurethane structural repeating unit, a polyurea structural repeating unit, and a polyamide structural repeating unit, it is more preferable that the graft chain includes at least one structural repeating unit selected from the group consisting of a polyester structural repeating unit, a polyether structural repeating unit, and a poly(meth)acrylic structural repeating unit, and it is still more preferable that the graft chain includes a poly(meth) acrylic structural repeating unit.

With regard to details of the graft resin, reference can be made to the description in paragraphs 0025 to 0094 of JP2012-255128A, the contents of which are incorporated herein by reference.

It is also preferable that the other resins used as the dispersant are a polyimine-based dispersant including a nitrogen atom in at least one of the main chain or the side chain. As the polyimine-based dispersant, a resin having a main chain which has a partial structure having a functional group of pKa14 or less, and a side chain which has 40 to 10,000 atoms, in which at least one of the main chain or the side chain has a basic nitrogen atom, is preferable. The basic nitrogen atom is not particularly limited as long as it is a nitrogen atom exhibiting basicity. With regard to the polyimine-based dispersant, reference can be made to the description in paragraphs 0102 to 0166 of JP2012-255128A, the contents of which are incorporated herein by reference.

It is also preferable that the other resins used as the dispersant are a resin having a structure in which a plurality of polymer chains are bonded to a core portion. Examples of such a resin include dendrimers (including star polymers). In addition, specific examples of the dendrimer include polymer compounds C-1 to C-31 described in paragraphs 0196 to 0209 of JP2013-043962A.

From the viewpoint of dispersibility and storage stability, the other resins used as the dispersant preferably includes a polyester resin having a carboxy group and a graft chain. In addition, from the viewpoint of the edge shape of a patterned cured product to be obtained, adhesiveness, and defect suppression, the above-described polyester resin is preferably a polyester resin having a carboxy group in the main chain and a graft chain in the side chain.

Further, from the viewpoint of the edge shape of the patterned cured product to be obtained, adhesiveness, and defect suppression, the above-described graft chain is preferably an addition polymerization-type resin chain and more preferably an acrylic resin chain.

From the viewpoint of dispersibility and storage stability, the other resins used as the dispersant preferably includes a resin having an aromatic carboxy group. The above-described resin having an aromatic carboxy group may include the aromatic carboxy group in the main chain of the structural repeating unit, or in the side chain of the structural repeating unit, but it is preferable that the aromatic carboxy group is included in the main chain of the structural repeating unit. In the above-described aromatic carboxy group, the number of carboxy groups bonded to the aromatic ring is preferably 1 to 4 and more preferably 1 or 2.

As the resin having an aromatic carboxy group, from the viewpoint of the edge shape of the patterned cured product to be obtained, adhesiveness, and defect suppression, a resin obtained by reacting a hydroxy group in a vinyl polymer (a) which is produced by a radical polymerization of an ethylenically unsaturated monomer in the presence of a compound (al) having two hydroxy groups and one thiol group in a molecule, and has two hydroxy groups in one terminal region, with an acid anhydride group in a tetracarboxylic acid anhydride (b), is preferable. Suitable examples of the compound (al) having two hydroxy groups and one thiol group, the vinyl polymer (a) having two hydroxy groups in one terminal region, and the tetracarboxylic acid anhydride (b) include each compound described later.

In addition, from the viewpoint of the edge shape of the patterned cured product to be obtained, adhesiveness, and defect suppression, the resin having an aromatic carboxy group is preferably a resin having a structural repeating unit represented by Formula (b-10).

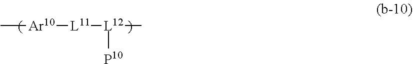

In Formula (b-10), Ar¹⁰ represents a group including an aromatic carboxy group, L¹¹ represents —COO— or —CONH—, L¹² represents a trivalent linking group, and P¹⁰ represents a polymer chain having an ethylenically unsaturated group.

In Formula (b-10), examples of the group including an aromatic carboxy group, represented by Ar¹⁰, include a structure derived from an aromatic tricarboxylic acid anhydride and a structure derived from an aromatic tetracarboxylic acid anhydride. Examples of the aromatic tricarboxylic acid anhydride and the aromatic tetracarboxylic acid anhydride include compounds having the following structures.

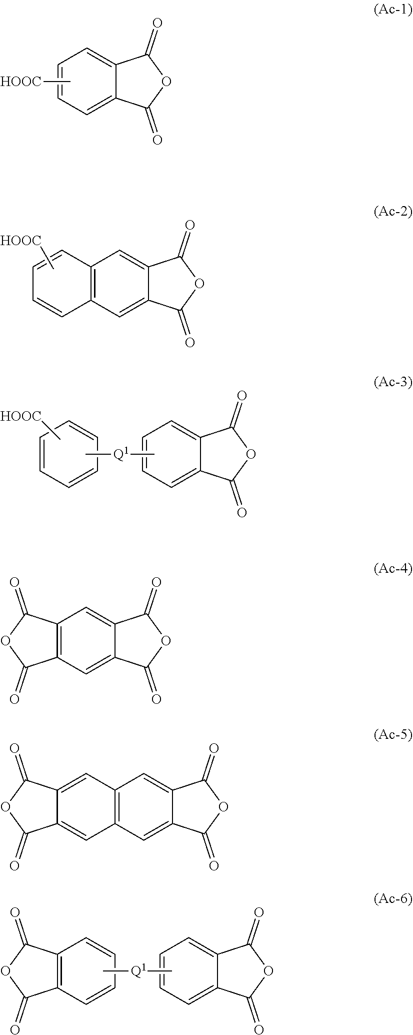

In the formulae, Q¹ represents a single bond, —O—, —CO—, —COOCH₂CH₂OCO—, —SO₂—, —C(CF₃)₂—, a group represented by Formula (Q-1), or a group represented by Formula (Q-2).

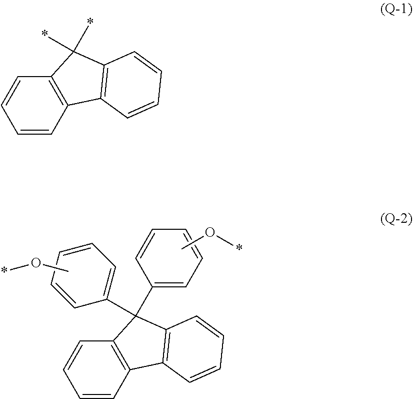

Specific examples of the aromatic tricarboxylic acid anhydride include a benzenetricarboxylic acid anhydride (1,2,3-benzenetricarboxylic acid anhydride, trimellitic acid anhydride [1,2,4-benzenetricarboxylic acid anhydride], and the like), a naphthalenetricarboxylic acid anhydride (1,2,4-naphthalenetricarboxylic acid anhydride, 1,4,5-naphthalenetricarboxylic acid anhydride, 2,3,6-naphthalenetricarboxylic acid anhydride, 1,2,8-naphthalenetricarboxylic acid anhydride, and the like), 3,4,4′-benzophenonetricarboxylic acid anhydride, 3,4,4′-biphenylethertricarboxylic acid anhydride, 3,4,4′-biphenyltricarboxylic acid anhydride, 2,3,2′-biphenyltricarboxylic acid anhydride, 3,4,4′-biphenylmethanetricarboxylic acid anhydride, and 3,4,4′-biphenylsulfonetricarboxylic acid anhydride.

Specific examples of the aromatic tetracarboxylic acid anhydride include pyromellitic acid dianhydride, ethylene glycol dianhydrous trimellitic acid ester, propylene glycol dianhydrous trimellitic acid ester, butylene glycol dianhydrous trimellitic acid ester, 3,3′,4,4′-benzophenonetetracarboxylic acid dianhydride, 3,3′,4,4′-biphenylsulfonetetracarboxylic acid dianhydride, 1,4,5,8-naphthalenetetracarboxylic acid dianhydride, 2,3,6,7-naphthalenetetracarboxylic acid dianhydride, 3,3′,4,4′-biphenylethertetracarboxylic acid dianhydride, 3,3′,4,4′-dimethyldiphenylsilanetetracarboxylic acid dianhydride, 3,3′,4,4′-tetraphenylsilanetetracarboxylic acid dianhydride, 1,2,3,4-frantetracarboxylic acid dianhydride, 4,4′-bis(3,4-dicarboxyphenoxy)diphenylsulfide dianhydride, 4,4′-bis(3,4-dicarboxyphenoxy)diphenylsulfone dianhydride, 4,4′-bis (3,4-dicarboxyphenoxy) diphenylpropane dianhydride, 3,3′,4,4′-perfluoroisopropyridendiphthalic acid dianhydride, 3,3′,4,4′-biphenyltetracarboxylic acid dianhydride, bis(phthalic acid) phenylphosphineoxide dianhydride, p-phenylene-bis(triphenylphthalic acid) dianhydride, m-phenylene-bis(triphenylphthalic acid) dianhydride, bis(triphenylphthalic acid)-4,4′-diphenylether dianhydride, bis(triphenylphthalic acid)-4,4′-diphenylmethane dianhydride, 9,9-bis(3,4-dicarboxyphenyl)fluorene dianhydride, 9,9-bis[4-(3,4-dicarboxyphenoxy)phenyl]fluorene dianhydride, 3,4-dicarboxy-1,2,3,4-tetrahydro-1-naphthalenesuccinic acid dianhydride, and 3,4-dicarboxy-1,2,3,4-tetrahydro-6-methyl-1-naphthalenesuccinic acid dianhydride.

Specific examples of the group include an aromatic carboxy group represented by Ar¹⁰ include a group represented by Formula (Ar-1), a group represented by Formula (Ar-2), and a group represented by Formula (Ar-3).

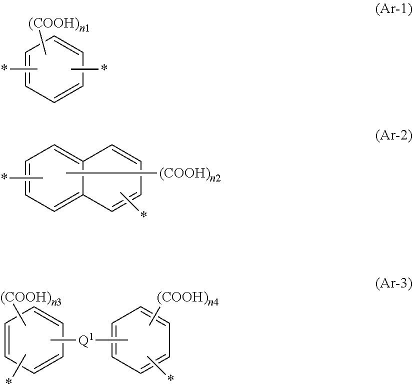

In Formula (Ar-1), n1 represents an integer of 1 to 4, and is preferably an integer of 1 or 2 and more preferably 2.

In Formula (Ar-2), n2 represents an integer of 1 to 8, and is preferably an integer of 1 or 4, more preferably 1 or 2, and still more preferably 2.

In Formula (Ar-3), n3 and n4 each independently represent an integer of 0 to 4, and are preferably an integer of 0 or 2, more preferably 1 or 2, and still more preferably 1. However, at least one of n3 or n4 is an integer of 1 or more.

In Formula (Ar-3), Q¹ represents a single bond, —O—, —CO—, —COOCH₂CH₂OCO—, —SO₂—, —C(CF₃)₂—, the above-described group represented by Formula (Q-1), or the above-described group represented by Formula (Q-2).

In Formula (b-10), L¹¹ represents —COO— or —CONH—, preferably —COO—.

In Formula (b-10), examples of the trivalent linking group represented by L¹² include a trivalent hydrocarbon group, and a trivalent group formed by a combination of two or more selected from a hydrocarbon group, —O—, —CO—, —COO—, —OCO—, —NH—, —S—, and a group. Examples of the hydrocarbon group include an aliphatic hydrocarbon group and an aromatic hydrocarbon group. The number of carbon atoms in the aliphatic hydrocarbon group is preferably 1 to 30, more preferably 1 to 20, and still more preferably 1 to 15. The aliphatic hydrocarbon group may be linear, branched, or cyclic. The number of carbon atoms in the aromatic hydrocarbon group is preferably 6 to 30, more preferably 6 to 20, and still more preferably 6 to 10. The hydrocarbon group may have a substituent. Examples of the substituent include a hydroxy group.

In Formula (b-10), P¹⁰ represents a polymer chain having a (meth)acryloyl group. It is preferable that the polymer chain represented by P¹⁰ has at least one repeating unit selected from the group consisting of a poly(meth)acrylic structural repeating unit, a polyether structural repeating unit, a polyester structural repeating unit, and a polyol structural repeating unit. The weight-average molecular weight of the polymer chain P¹⁰ is preferably 500 to 20,000. The lower limit is preferably 600 or more and more preferably 1,000 or more. The upper limit is preferably 10,000 or less, more preferably 5,000 or less, and still more preferably 3,000 or less. In a case where the weight-average molecular weight of P¹⁰ is within the above-described range, dispersibility of the pigment in the composition is good. This resin is preferably used as a dispersant.

In Formula (b-10), the polymer chain represented by P¹⁰ is preferably a polymer chain including a structural repeating unit represented by Formulae (P-1) to (P-5), and more preferably a polymer chain including a structural repeating unit represented by Formula (P-5).

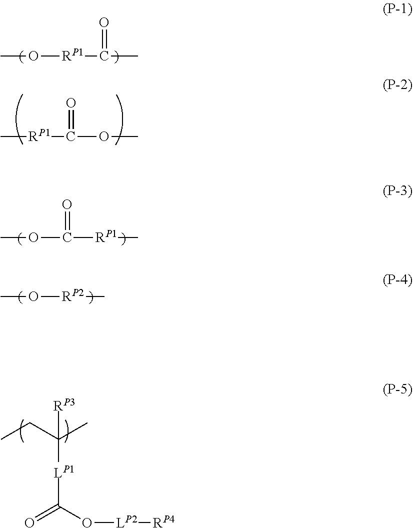

In the formulae, R^{P1} and R^{P2} each represent an alkylene group. As the alkylene group represented by R^{P1} and R^{P2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable. In the formulae, R^{P3} represents a hydrogen atom or a methyl group.

In the formulae, L^{P1} represents a single bond or an arylene group and L^{P2} represents a single bond or a divalent linking group. L^{P1} is preferably a single bond. Examples of the divalent linking group represented by L^{P2} include an alkylene group (preferably an alkylene group having 1 to 12 carbon atoms), an arylene group (preferably an arylene group having 6 to 20 carbon atoms), —NH—, —δO—, —SO₂—, —CO—, —O—, —COO—, —OCO—, —S—, —NHCO—, —CONH—, and a group formed by a combination of two or more these groups.

R^{P4} represents a hydrogen atom or a substituent. Examples of the substituent include a hydroxy group, a carboxy group, an alkyl group, an aryl group, a heteroaryl group, an alkoxy group, an aryloxy group, a heteroaryloxy group, an alkylthioether group, an arylthioether group, a heteroarylthioether group, and an ethylenically unsaturated group.

In addition, the polymer chain represented by P¹⁰ is more preferably a polymer chain having a structural repeating unit including an ethylenically unsaturated group in the side chain. In addition, the proportion of the structural repeating unit including an ethylenically unsaturated group in the side chain with respect to total structural repeating units constituting P¹⁰ is preferably 5 mass % or more, more preferably 10 mass % or more, and still more preferably 20 mass % or more. The upper limit may be 100 mass %, and is preferably 90 mass % or less and still more preferably 60 mass % or less.

In addition, it is also preferable that the polymer chain represented by P¹⁰ has a structural repeating unit having an acid group. Examples of the acid group include a carboxy group, a phosphoric acid group, a sulfo group, and a phenolic hydroxy group. According to this aspect, the dispersibility of the pigment in the composition can be further improved. Furthermore, developability can also be further improved. The proportion of the structural repeating unit having an acid group is preferably 1 mass % to 30 mass %, more preferably 2 mass % to 20 mass %, and still more preferably 3 mass % to 10 mass %.

In addition, the resin having the structural repeating unit represented by Formula (b-10) can be produced by reacting at least one acid anhydride selected from the group consisting of an aromatic tetracarboxylic acid anhydride and an aromatic tricarboxylic acid anhydride with a hydroxy group-containing compound.

Examples of the aromatic tetracarboxylic acid anhydride and the aromatic tricarboxylic acid anhydride include those described above. The hydroxy group-containing compound is not particularly limited as long as it has a hydroxy group in the molecule, but is preferably a polyol having two or more hydroxy groups in the molecule.

In addition, as the hydroxy group-containing compound, it is also preferable to use a compound having two hydroxy groups and one thiol group in the molecule. Examples of the compound having two hydroxy groups and one thiol group in the molecule include 1-mercapto-1,1-methanediol, 1-mercapto-1,1-ethanediol, 3-mercapto-1,2-propanediol (thioglycerin), 2-mercapto-1,2-propanediol, 2-mercapto-2-methyl-1,3-propanediol, 2-mercapto-2-ethyl-1,3-propanediol, 1-mercapto-2,2-propanediol, 2-mercaptoethyl-2-methyl-1,3-propanediol, and 2-mercaptoethyl-2-ethyl-1,3-propanediol. Examples of other hydroxy group-containing compounds include compounds described in paragraphs 0084 to 0095 of JP2018-101039A, the contents of which are incorporated herein by reference.

The molar ratio (acid anhydride group/hydroxy group) of the acid anhydride group in the acid anhydride to the hydroxy group in the hydroxy group-containing compound is preferably 0.5 to 1.5.

In addition, the resin having the structural repeating unit represented by Formula (b-10) can be synthesized by the methods shown in the following synthesis method (1) or (2).

[Synthesis Method (1)]

Producing method of radically polymerizing a polymerizable monomer having an ethylenically unsaturated group in the presence of a hydroxy group-containing thiol compound (preferably a compound having two hydroxy groups and one thiol group in the molecule) to synthesize a vinyl polymer having two hydroxy groups in one terminal region, and reacting the synthesized vinyl polymer with one or more aromatic acid anhydride selected from the aromatic tetracarboxylic acid anhydride and the aromatic tricarboxylic acid anhydride.

[Synthesis Method (2)]

Producing method of reacting a hydroxy group-containing compound (preferably a compound having two hydroxy groups and one thiol group in the molecule) with one or more aromatic acid anhydride selected from the aromatic tetracarboxylic acid anhydride and the aromatic tricarboxylic acid anhydride, and radically polymerizing a polymerizable monomer having an ethylenically unsaturated group in the presence of the obtained reactant. In the synthesis method (2), after radically polymerizing the polymerizable monomer having a hydroxy group, the reactant may be further reacted with a compound having an isocyanate group (for example, a compound having an isocyanate group and the above-described functional group A). As a result, the functional group A can be introduced into the polymer chain P¹⁰.

In addition, the resin having the structural repeating unit represented by Formula (b-10) can also be synthesized according to the method described in paragraph Nos. 0120 to 0138 of JP2018-101039A.

The weight-average molecular weight of the resin having the structural repeating unit represented by Formula (b-10) is preferably 2,000 to 35,000. The upper limit is preferably 25,000 or less, more preferably 20,000 or less, and still more preferably 15,000 or less. The lower limit is preferably 4,000 or more, more preferably 6,000 or more, and still more preferably 7,000 or more.

The acid value of the resin having the structural repeating unit represented by Formula (b-10) is preferably 5 to 200 mgKOH/g. The upper limit is preferably 150 mgKOH/g or less, more preferably 100 mgKOH/g or less, and still more preferably 80 mgKOH/g or less. The lower limit is preferably 10 mgKOH/g or more, more preferably 15 mgKOH/g or more, and still more preferably 20 mgKOH/g or more.

The above-described resin having an aromatic carboxy group may be used alone or in combination of two or more kinds thereof.

The content of the above-described resin having an aromatic carboxy group is preferably 1 mass % to 50 mass % with respect to the total solid content of the curable composition. The lower limit is preferably 3 mass % or more, more preferably 5 mass % or more, and still more preferably 10 mass % or more. The upper limit is preferably 45 mass % or less and more preferably 40 mass % or less.

In addition, specific examples of the above-described resin having an aromatic carboxy group include compounds described in JP2017-156652, the content of which is incorporated herein by reference.

In addition, the curable composition according to the embodiment of the present disclosure preferably includes a resin (hereinafter, also referred to as a specific resin) which satisfies at least one of the following requirement 1 or the following requirement 2.

Requirement 1: the resin includes a constitutional unit having, in the same side chain, an anionic structure, a quaternary ammonium cationic structure which is ionically bonded to the anionic structure, and a radically polymerizable group.

Requirement 2: the resin includes a constitutional unit having, in a side chain, a quaternary ammonium cationic structure and a group to which a radically polymerizable group is linked.

The specific resin may be a linear polymer compound, a star polymer compound, or a comb-shaped polymer compound. In addition, the form of the resin does not matter, and the resin may be a star polymer compound having a plurality of branching points and having a specific terminal group, which is described in JP2007-277514A.

The molecular weight (in a case of having a molecular weight distribution, weight-average molecular weight) of the side chain in the requirement 1 or the requirement 2 is preferably 50 to 1,500 and more preferably 100 to 1,000.

In addition, the specific resin is preferably an addition polymerization-type resin and more preferably an acrylic resin. In a case where the specific resin is an addition polymerization-type resin, examples of the specific resin include an aspect in which the side chain in the requirement 1 or the requirement 2 is a molecular chain bonded to a molecular chain formed by the addition polymerization, and is a molecular chain formed by a method other than addition polymerization.

In addition, the specific resin may be a dispersant. In the present specification, a resin which mainly is used for dispersing particles such as a pigment is also referred to as a dispersant. However, such applications of the specific resin are only exemplary, and the specific resin can also be used for other purposes in addition to such applications.

[Requirement 1]

In the above-described requirement 1, with regard to the constitutional unit having, in the same side chain, an anionic structure, a quaternary ammonium cationic structure which is ionically bonded to the anionic structure, and a radically polymerizable group, the anionic structure and the quaternary ammonium cationic structure may be ionically bonded or dissociated.

In addition, the side chain in the requirement 1 may have at least one anionic structure, quaternary ammonium cationic structure, and radically polymerizable group, respectively, or may have a plurality of at least one selected from the group consisting of an anionic structure, a quaternary ammonium cationic structure, and a radically polymerizable group in one side chain.

—Anionic Structure—

The anionic structure in the above-described requirement 1 is not particularly limited, and examples thereof include anions derived from an acid group, such as carboxylate anion, sulfonate anion, phosphonate anion, phosphinate anion, and phenolate anion. Among these, carboxylate anion is preferable.

In addition, the anionic structure in the requirement 1 may be directly connected to the main chain of the resin. For example, in a case where a carboxy group (side group) included in a constitutional unit derived from acrylic acid in an acrylic resin is anionized, the structure is an anionic structure directly connected to the main chain of the resin.

In addition, the distance (number of atoms) between the main chain and the quaternary ammonium cationic structure in a case where the anionic structure and the quaternary ammonium cationic structure are bonded to each other is preferably 4 atoms to 70 atoms, more preferably 4 atoms to 50 atoms, and still more preferably 4 atoms to 30 atoms.

In the present specification, the distance between two structures in a polymer compound means the number of atoms of a linking group which connects the two structures at the shortest.

The distance between the quaternary ammonium cationic structure and the radically polymerizable group is preferably 2 atoms to 30 atoms, more preferably 3 atoms to 20 atoms, and still more preferably 4 atoms to 15 atoms.

The distance between the radically polymerizable group and the main chain is preferably 6 atoms to 100 atoms, more preferably 6 atoms to 70 atoms, and still more preferably 6 atoms to 50 atoms.

—Quaternary Ammonium Cationic Structure (Requirement 1)—

As the quaternary ammonium cationic structure in the above-described requirement 1, a structure in which at least three of four groups including four carbon atoms bonded to the nitrogen atom are hydrocarbon groups is preferable, and it is more preferable that at least three thereof are alkyl groups.

Among the above-described four groups including four carbon atoms bonded to the nitrogen atom, at least one thereof is a linking group including a bonding site with the radically polymerizable group. The above-described linking group is preferably a divalent to hexavalent linking group, more preferably a divalent to tetravalent linking group, and still more preferably a divalent or trivalent linking group. Examples of the above-described linking group include a group represented L^{A2} in Formula (A1) described later.

In addition, among the above-described four groups including four carbon atoms bonded to the nitrogen atom, it is preferable that only one thereof is the above-described linking group.

Among the above-described four groups including four carbon atoms, it is preferable that two or three thereof are alkyl groups having 1 to 4 carbon atoms, and it is more preferable that two thereof are alkyl groups having 1 to 4 carbon atoms and one of the remaining two groups is a hydrocarbon group having 4 to 20 carbon atoms. In addition, the above-described two or three alkyl groups may be the same group or different groups.

As the above-described alkyl group having 1 to 4 carbon atoms, a methyl group or an ethyl group is preferable, and a methyl group is more preferable.

As the above-described hydrocarbon group having 4 to 20 carbon atoms, an alkyl group having 4 to 20 carbon atoms or a benzyl group is preferable.

In the above-described requirement 1, in a case where the side chain includes a plurality of quaternary ammonium cationic structures, the quaternary ammonium cationic structures may be bonded to each other through a linking group to form a ring structure. Examples of the ring structure formed include a ring structure represented by the following formulae. In the following formulae, * represents a bonding site with a linking group which includes a bonding site with the radically polymerizable group.

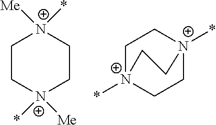 [SMILES: *[N+]1(C)CC[N+](*)(C)CC1 ; *[N+]12CC[N+](*)(CC1)CC2]

—Radically Polymerizable Group (Requirement 1)—

As the radically polymerizable group, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Requirement 2]

In the side chain in the above-described requirement 2, the quaternary ammonium cationic structure and the radically polymerizable group are linked to each other. That is, one side chain has both at least one quaternary ammonium cationic structure and at least one radically polymerizable group.

The side chain in the requirement 2 may have at least one quaternary ammonium cationic structure and radically polymerizable group, respectively, or may have a plurality of at least one selected from the group consisting of a quaternary ammonium cationic structure and a radically polymerizable group in one side chain.

In addition, the distance (number of atoms) between the main chain and the quaternary ammonium cationic structure is preferably 4 atoms to 20 atoms, more preferably 4 atoms to 15 atoms, and most preferably 4 atoms to 10 atoms.

The distance between the quaternary ammonium cationic structure and the polymerizable group is preferably 2 atoms to 30 atoms, more preferably 3 atoms to 20 atoms, and still more preferably 4 atoms to 15 atoms.

The distance between the polymerizable group and the main chain is preferably 6 atoms to 50 atoms, more preferably 6 atoms to 30 atoms, and still more preferably 6 atoms to 20 atoms.

—Quaternary Ammonium Cationic Structure (Requirement 2)—

As the quaternary ammonium cationic structure in the above-described requirement 2, a structure in which at least two of four groups including four carbon atoms bonded to the nitrogen atom are hydrocarbon groups is preferable, and it is more preferable that at least two thereof are alkyl groups.

As the above-described hydrocarbon group, an alkyl group or an aryl group is preferable, and an alkyl group or a phenyl group is more preferable.

As the above-described alkyl group, an alkyl group having 1 to 4 carbon atoms is preferable, a methyl group or an ethyl group is more preferable, and a methyl group is still more preferable. In addition, the above-described two alkyl groups may be the same group or different groups.

Among the above-described four groups including four carbon atoms bonded to the nitrogen atom, at least one thereof is a linking group including a bonding site with the radically polymerizable group, and at least one thereof is a linking group including a bonding site with the main chain in the specific resin.

The above-described linking group with the radically polymerizable group is preferably a divalent to hexavalent linking group, more preferably a divalent to tetravalent linking group, and still more preferably a divalent or trivalent linking group. Examples of the above-described linking group include a group represented L^{B2} in Formula (B1) described later.

The above-described linking group including a bonding site with the main chain in the specific resin is preferably a divalent linking group. Examples of the above-described linking group include a group represented L^{B1} in Formula (B1) described later.

The counter anion of the quaternary ammonium cationic structure in the requirement 2 may be present in the specific resin, or in other components included in the curable composition, but it is preferable to be present in the specific resin.

—Radically Polymerizable Group (Requirement 2)—

As the radically polymerizable group, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Constitutional Unit Represented by Formula (A1) and Constitutional Unit Represented by Formula (B1)]

It is preferable that the above-described resin includes at least one of a constitutional unit represented by Formula (A1) or a constitutional unit represented by Formula (B1).

A resin including the constitutional unit represented by Formula (A1) is a resin satisfying the requirement 1, and a resin including the constitutional unit represented by Formula (B1) is a resin satisfying the requirement 2.

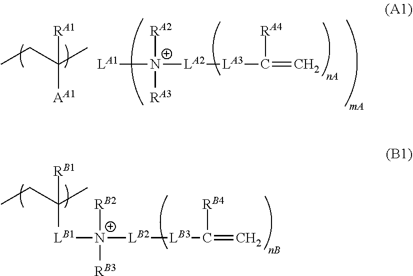

In Formula (A1), R^{A1} represents a hydrogen atom or an alkyl group,

A^{A1} represents a structure including a group in which a proton is separated from an acid group,

R^{A2} and R^{A3} each independently represent an alkyl group or an aralkyl group,

L^{A1} represents a monovalent substituent in a case where mA is 1, or represents an mA-valent linking group in a case where mA is 2 or more,

L^{A2} represents an (nA+1)-valent linking group,

L^{A3} represents a divalent linking group,

R^{A4} represents a hydrogen atom or an alkyl group,

nA represents an integer of 1 or more, and

mA represents an integer of 1 or more,
where in a case where mA is 2 or more, two or more R^{A2}'s, two or more R^{A3}'s, and two or more L^{A2}'s may be the same or different from each other,
in a case where mA is 2 or more, at least one of mA pieces of structures including a quaternary ammonium cation, which is selected from the group consisting of R^{A2} and R^{A3} included in one structure, may form a ring structure with at least one selected from the group consisting of R^{A2} and R^{A3} included in another structure,
in a case where at least one selected from the group consisting of nA and mA is 2 or more, two or more L^{A3}'s and two or more R^{A4}'s may be the same or different from each other, and
at least two of R^{A2}, R^{A3}, or L^{A2} may be bonded to each other to form a ring.

In Formula (B1), R^{B1} represents a hydrogen atom or an alkyl group,

L^{B1} represents a divalent linking group,

R^{B2} and R^{B3} each independently represent an alkyl group,

L^{B2} represents an (nB+1)-valent linking group,

L^{B3} represents a divalent linking group,

R^{B4} represents a hydrogen atom or an alkyl group, and

nB represents an integer of 1 or more,
where in a case where nB is 2 or more, two or more L^{B3}'s and two or more R^{B4}'s may be the same or different from each other, and
at least two of R^{B2}, R^{B3}, L^{B1}, or L^{B2} may be bonded to each other to form a ring.

In Formula (A1), R^{A1} is preferably a hydrogen atom or an alkyl group having 1 to 4 carbon atoms and more preferably a hydrogen atom or a methyl group.

In Formula (A1), A^{A1} represents a structure including a group in which a proton is separated from an acid group, and examples of the acid group include a carboxy group, a sulfo group, a phosphoric acid group, a phosphonic acid group, and a phenolic hydroxy group, and a carboxy group is preferable. The number of acid groups included in A^{A1} may be one or plural, and it is preferable to be one. In addition, the acid group in A^{A1} may be bonded to a carbon atom to which R^{A1} in Formula (A1) is bonded directly or through a linking group. As the above-described linking group, a hydrocarbon group, an ether bond (—O—), an ester bond (—COO—), an amide bond (—CONH—), or a group in which two or more of these are bonded is preferable. Examples of the above-described hydrocarbon group include a divalent hydrocarbon group, and an alkylene group or an arylene group is preferable, and an alkylene group having 1 to 20 carbon atoms or a phenylene group is more preferable. In addition, in the present specification, unless otherwise specified, a hydrogen atom in the amide bond may be replaced with a known substituent such as an alkyl group and an aryl group.

In Formula (A1), R^{A2} and R^{A3} are each independently preferably an alkyl group, more preferably an alkyl group having 1 to 10 carbon atoms, still more preferably an alkyl group having 1 to 4 carbon atoms, particularly preferably a methyl group or an ethyl group, and most preferably a methyl group.

In Formula (A1), in a case where R^{A2} or R^{A3} is an aralkyl group, an aralkyl group having 7 to 22 carbon atoms is preferable, an aralkyl group having 7 to 10 carbon atoms is more preferable, and a benzyl group is still more preferable.

In Formula (A1), in a case where mA is 2 or more, L^{A1} is preferably an mA-valent hydrocarbon group, and more preferably a saturated aliphatic hydrocarbon, an aromatic hydrocarbon, or a group that mA hydrogen atoms are removed from or a structure in which two or more of these are bonded. In a case where mA is 1, L^{A}1 is preferably an alkyl group, an aryl group, or an aralkyl group, and more preferably an alkyl group having 4 to 20 carbon atoms or a benzyl group.

In Formula (A1), L^{A2} is preferably any one of groups represented by Formulae (C1-1) to (C4-1) described later.

In Formula (A1), L^{A3} is preferably an ether bond (—O—), an ester bond (—COO—), an amide bond (—NHCO—), an alkylene group, or an arylene group, and more preferably an ester bond or a phenylene group.

In Formula (A1), R^{A4} is preferably a hydrogen atom or an alkyl group having 1 to 4 carbon atoms and more preferably a hydrogen atom or a methyl group.

In Formula (A1), nA is preferably 1 to 10, more preferably 1 to 4, still more preferably 1 or 2, and particularly preferably 1.

In Formula (A1), mA is preferably 1 to 10, more preferably 1 to 4, and still more preferably 1 to 3.

In Formula (B1), R^{B1} is preferably a hydrogen atom or an alkyl group having 1 to 4 carbon atoms and more preferably a hydrogen atom or a methyl group.

In Formula (B1), LBl represents a divalent linking group, and a hydrocarbon group, an ether bond (—O—), an ester bond (—COO—), an amide bond (—CONH—), or a group in which two or more of these are bonded is preferable. Examples of the above-described hydrocarbon group include a divalent hydrocarbon group, and an alkylene group or an arylene group is preferable, and an alkylene group having 1 to 20 carbon atoms or a phenylene group is more preferable.

In Formula (B1), R^{B2} and R^{B3} are each independently preferably an alkyl group having 1 to 10 carbon atoms, more preferably an alkyl group having 1 to 4 carbon atoms, still more preferably a methyl group or an ethyl group, and particularly preferably a methyl group.

In Formula (B1), L^{B2} is preferably any one of groups represented by Formulae (C1-1) to (C4-1) described later.

In Formula (B1), L^{B3} is preferably an ether bond (—O—), an ester bond (—COO—), an amide bond (—NHCO—), an alkylene group, or an arylene group, and more preferably an ester bond or a phenylene group.

In Formula (B1), nB is preferably 1 to 10, more preferably 1 to 4, still more preferably 1 or 2, and particularly preferably 1.

The specific resin may have one kind of the constitutional unit represented by Formula (A1), or may have two or more kinds thereof.

In addition, the specific resin may have one kind of the constitutional unit represented by Formula (B1), or may have two or more kinds thereof.

The content (in a case of including two or more kinds, total content) of the constitutional unit represented by Formula (A1) and the constitutional unit represented by Formula (B1) is preferably 1 mass % to 60 mass %, more preferably 5 mass % to 40 mass %, and still more preferably 5 mass % to 20 mass % with respect to the total mass of the specific resin.

[Constitutional Unit D]

It is also preferable that the specific resin has a radically polymerizable group and further includes a constitutional unit D which is different from the constitutional unit represented by Formula (A1) and the constitutional unit represented by Formula (B1).

As the radically polymerizable group in the constitutional unit D, a group having an ethylenically unsaturated group is preferable. Examples of the group having an ethylenically unsaturated group include a vinyl group, a (meth)allyl group, a (meth)acrylamide group, a (meth)acryloxy group, and a vinylphenyl group. Among these, from the viewpoint of reactivity, a (meth)acryloxy group or a vinylphenyl group is preferable, and a (meth)acryloxy group is more preferable.

[Constitutional Unit Represented by Formula (D1)]

The specific resin preferably further includes a constitutional unit represented by Formula (D1) as the constitutional unit D.

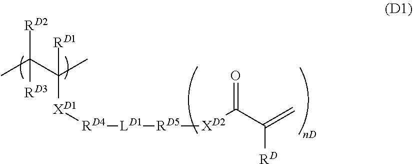

In Formula (D1), R^{D1} to R^{D3} each independently represent a hydrogen atom or an alkyl group,

X^{D1} represents —COO—, —CONR^{D6}—, or an arylene group, where R^{D6} represents a hydrogen atom, an alkyl group, or an aryl group,

R^{D4} represents a divalent linking group,

L^{D1} represents a group represented by Formula (D2), Formula (D3), or Formula (D3′),

R^{D5} represents an (n+1)-valent linking group,

X^{D2} represents an oxygen atom or NR^{D7}—, where R^{D7} represents a hydrogen atom, an alkyl group, or an aryl group,

R^{D} represents a hydrogen atom or a methyl group, and

nD represents an integer of 1 or more,
where in a case where nD is 2 or more, two or more X^{D2}'s and two or more R^{D}'s may be the same or different from each other.

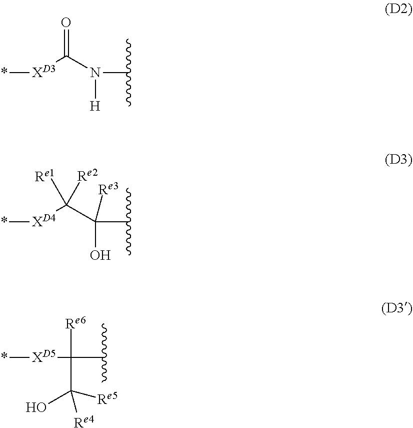

In Formulae (D2), (D3), and (D3′), X^{D3} represents an oxygen atom or —NH—,

X^{D4} represents an oxygen atom or COO—,

R^{e1} to R^{e3} each independently represent a hydrogen atom or an alkyl group, where at least two of R^{e1} to R^{e3} may be bonded to each other to form a ring structure,

X^{D5} represents an oxygen atom or —COO—,

R^{e4} to R^{e6} each independently represent a hydrogen atom or an alkyl group, where at least two of R^{e4} to R^{e6} may be bonded to each other to form a ring structure, and

* and a wavy line represent a bonding position with other structures.

From the viewpoint of deep portion curing properties, R^{D1} to R^{D3} in Formula (D1) are each independently preferably a hydrogen atom or a methyl group, and more preferably a hydrogen atom. In addition, from the viewpoint of deep portion curing properties, it is still more preferable that R^{D1} is a hydrogen atom or a methyl group, and R^{D2} and R^{D3} are hydrogen atoms. In a case where L^{D1} is the group represented by Formula (D2), R^{D1} is still more preferably a methyl group, and in a case where L^{D1} is the group represented by Formula (D3) or Formula (D3′), R^{D1} is still more preferably a hydrogen atom.

From the viewpoint of deep portion curing properties, X^{D1} in Formula (D1) is preferably —COO— or —CONR^{D6}— and more preferably —COO—. In a case where X^{D1} is an arylene group, it is preferable to be a divalent aromatic hydrocarbon group having 6 to 20 carbon atoms, more preferable to be a phenylene group or a naphthylene group, and still more preferable to be a phenylene group. In a case where X^{D1} is —COO—, it is preferable that the carbon atom in —COO— is bonded to the carbon atom to which R^{D1} in Formula (D1) is bonded. In a case where X^{D1} is —CONR^{D6}—, it is preferable that the carbon atom in —CONR^{D6}— is bonded to the carbon atom to which R^{D1} in Formula (D1) is bonded.

R^{D6} is preferably a hydrogen atom or an alkyl group and more preferably a hydrogen atom.

From the viewpoint of deep portion curing properties, R^{D4} in Formula (D1) is preferably a hydrocarbon group or a group in which two or more hydrocarbon groups are bonded to one or more structures selected from the group consisting of ether bonds and ester bonds, and more preferably a hydrocarbon group or a group in which two or more hydrocarbon groups are bonded to one or more ester bonds.

In addition, R^{D4} in Formula (D1) is preferably a group in which two or more groups selected from the group consisting of an alkylene group, an ether group, a carbonyl group, a phenylene group, a cycloalkylene group, and an ester bond are bonded, and more preferably a group in which two or more groups selected from the group consisting of an alkylene group, an ether group, and an ester bond are bonded.

In addition, from the viewpoint of deep portion curing properties, R^{D4} in the formula is preferably a group having a total of 2 to 60 atoms, more preferably a group having a total of 2 to 50 atoms, and particularly preferably a group having a total of 2 to 40 atoms.

From the viewpoint of deep portion curing properties, nD in Formula (D1) is preferably an integer of 1 to 6, more preferably an integer of 1 to 3, and still more preferably 1.

From the viewpoint of deep portion curing properties, R^{D5} in Formula (D1) is preferably a divalent linking group, more preferably an alkylene group or a group in which two or more alkylene groups are bonded to one or more structures selected from the group consisting of ether bonds and ester bonds, still more preferably an alkyleneoxyalkylene group, and particularly preferably a methyleneoxy-n-butylene group.

In addition, from the viewpoint of deep portion curing properties, R^{D5} in Formula (D1) is preferably a group having a total of 2 to 40 atoms, more preferably a group having a total of 2 to 30 atoms, and particularly preferably a group having a total of 2 to 20 atoms.

From the viewpoint of deep portion curing properties, X^{D2} in Formula (D1) is preferably an oxygen atom.

R^{D7} is preferably a hydrogen atom or an alkyl group and more preferably a hydrogen atom.

R^{D} is preferably a hydrogen atom.

From the viewpoint of dispersibility, L^{D1} in Formula (D1) is preferably the group represented by Formula (D2), and from the viewpoint of formation of a pattern shape and suppression of development residue, L^{D1} in Formula (D1) is preferably the group represented by Formula (D3) or Formula (D3′).

In Formulae (D2), (D3), and (D3′), it is preferable that * is a bonding site with R^{D4} and a wavy line is a bonding site with R^{D5}.

From the viewpoint of deep portion curing properties and dispersibility, X^{D3} in Formula (D2) is preferably an oxygen atom.

In addition, in a case where L^{D1} is the group represented by Formula (D2), from the viewpoint of deep portion curing properties and dispersibility, it is particularly preferable that R^{D4} is a group selected from the group consisting of an ethylene group, an n-propylene group, an isopropylene group, an n-butylene group, and an isobutylene group, and R^{D}s is an ethylene group.

From the viewpoint of deep portion curing properties, formation of a pattern shape, and suppression of development residue, X^{D4} in Formula (D3) or Formula (D3′) is preferably —COO—. In a case where X^{D4} is —COO—, it is preferable that the oxygen atom in —COO— is bonded to the carbon atom to which R^{e1} is bonded.

From the viewpoint of deep portion curing properties, formation of a pattern shape, and suppression of development residue, R^{e1} to R^{e3} in Formula (D3) or Formula (D3′) are preferably hydrogen atoms.

In addition, in a case where L^{D1} is the group represented by Formula (D3) of Formula (D3′), from the viewpoint of deep portion curing properties, formation of a pattern shape, and suppression of development residue, it is particularly preferable that R^{D4} is a hydrocarbon group, a group in which two or more hydrocarbon groups are bonded to one or more structures selected from the group consisting of ether bonds and ester bonds, or any group represented by the following structures, and R^{D5} is an alkylene group or a group in which two or more alkylene groups are bonded to one or more structures selected from the group consisting of ether bonds and ester bonds.

The specific resin may have one kind of the constitutional unit represented by Formula (D1), or may have two or more kinds thereof.

From the viewpoint of developability, formation of a pattern shape, dispersion stability, and deep portion curing properties, the content of the constitutional unit represented by Formula (D1) is preferably 1 mass % to 80 mass %, more preferably 1 mass % to 70 mass %, and particularly preferably 1 mass % to 60 mass % with respect to the total mass of the specific resin.

[Constitutional Unit Represented by Formula (D4)]

From the viewpoint of dispersion stability and developability, the specific resin preferably further has a constitutional unit represented by Formula (D4).

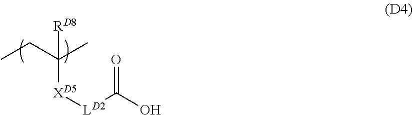

In Formula (D4), R^{D8} represents a hydrogen atom or an alkyl group, X^{D5} represents —COO—, —CONR^{B}—, or an arylene group, where R^{B} represents a hydrogen atom, an alkyl group, or an aryl group, and L^{D2} represents an aliphatic hydrocarbon group having 1 to 10 carbon atoms, an aromatic hydrocarbon group having 6 to 20 carbon atoms, or a group in which two or more groups selected from the group consisting of aliphatic hydrocarbon groups having 1 to 10 carbon atoms and aromatic hydrocarbon groups having 6 to 20 carbon atoms are bonded to one or more groups selected from the group consisting of ether bonds and ester bonds. Furthermore, in a case where X^{D5} is an arylene group, L^{D2} may be a single bond.

R^{D8} in Formula (D4) is preferably a hydrogen atom.

From the viewpoint of dispersion stability, X^{D5} in Formula (D4) is preferably —COO— or —CONR^{B}— and more preferably —COO—. In a case where X^{D5} is —COO—, it is preferable that the carbon atom in —COO— is bonded to the carbon atom to which R^{D8} in Formula (D4) is bonded. In a case where X^{D5} is —CONR^{DB}—, it is preferable that the carbon atom in —CONR^{DB}— is bonded to the carbon atom to which R^{D8} in Formula (D4) is bonded.

R^{B} is preferably a hydrogen atom or an alkyl group and more preferably a hydrogen atom.

From the viewpoint of dispersion stability, L^{D2} in Formula (D4) is preferably an aliphatic hydrocarbon group having 1 to 10 carbon atoms, or a group in which two or more aliphatic hydrocarbon groups having 1 to 10 carbon atoms are bonded to one or more ester bonds, still more preferably an aliphatic hydrocarbon group having 1 to 10 carbon atoms, and particularly preferably an alkylene group having 1 to 10 carbon atoms.

The specific resin may have one kind of the constitutional unit represented by Formula (D4), or may have two or more kinds thereof.

From the viewpoint of developability, formation of a pattern shape, and dispersion stability, the content of the constitutional unit represented by Formula (D4) is preferably 20 mass % to 80 mass %, more preferably 20 mass % to 70 mass %, and particularly preferably 20 mass % to 60 mass % with respect to the total mass of the specific resin.

[Constitutional Unit Represented by Formula (D5)]

From the viewpoint of dispersion stability, the specific resin preferably has a constitutional unit represented by Formula (D5), and from the viewpoint of dispersion stability and developability, the specific resin more preferably further has the constitutional unit represented by Formula (D4) and a constitutional unit represented by Formula (D5).

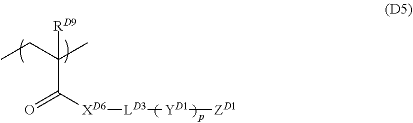

In Formula (D5), R^{D9} represents a hydrogen atom or an alkyl group,

X^{D6} represents an oxygen atom or NR^{C}—, where R^{C} represents a hydrogen atom, an alkyl group, or an aryl group,

L^{D3} represents a divalent linking group,

Y^{D1} represents an alkyleneoxy group or an alkylenecarbonyloxy group,

Z^{D1} represents an aliphatic hydrocarbon group having 1 to 20 carbon atoms or an aromatic hydrocarbon group having 6 to 20 carbon atoms, and

p represents an integer of 1 or more, where in a case where p is 2 or more, p pieces of Y^{D1}'s may be the same or different from each other.

R^{D9} in Formula (D5) is preferably a hydrogen atom or a methyl group and more preferably a methyl group.

From the viewpoint of dispersion stability, X^{D6} in Formula (D5) is preferably an oxygen atom.

R^{C} is preferably a hydrogen atom or an alkyl group and more preferably a hydrogen atom.

From the viewpoint of dispersion stability, L^{D3} in Formula (D5) is preferably a group having a total of 2 to 30 atoms, more preferably a group having a total of 3 to 20 atoms, and particularly preferably a group having a total of 4 to 10 atoms.

In addition, from the viewpoint of dispersion stability, L^{D3} in Formula (D5) is preferably a group having a urethane bond or a urea bond, more preferably a group having a urethane bond, and particularly preferably a group in which an alkylene group and a urethane bond are bonded to each other.

From the viewpoint of dispersion stability, Y^{D1} in Formula (D5) is preferably an alkylenecarbonyloxy group. In addition, in a case where p pieces of Y_{D1}'s include a plurality of structures, those structures may be arranged at random, or may be arranged by forming blocks.

From the viewpoint of dispersion stability, the number of carbon atoms in the alkylenecarbonyloxy group is preferably 2 to 30, more preferably 3 to 10, and particularly preferably 5 to 8.

From the viewpoint of dispersion stability, p is an integer of 1 or more, and is preferably an integer of 3 or more.

In addition, p is preferably 100 or less, more preferably 60 or less, and particularly preferably 40 or less.

From the viewpoint of dispersion stability, Z^{D1} in Formula (D5) is preferably an aliphatic hydrocarbon group having 1 to 20 carbon atoms, more preferably an alkyl group having 4 to 20 carbon atoms, and particularly preferably an alkyl group having 6 to 20 carbon atoms.

In addition, from the viewpoint of dispersion stability, the above-described alkyl group in Z^{D1} is preferably a branched alkyl group.

The specific resin may have one kind of the constitutional unit represented by Formula (D5), or may have two or more kinds thereof.

From the viewpoint of developability and dispersion stability, the content of the constitutional unit represented by Formula (D5) is preferably 5 mass % to 80 mass %, more preferably 5 mass % to 70 mass %, and particularly preferably 5 mass % to 60 mass % with respect to the total mass of the specific resin.

[Other Constitutional Units]

The specific resin may have a constitutional unit other than the above-described constitutional units represented by Formula (A1), Formula (B1), Formula (D1), Formula (D4), and Formula (D5).

The other constitutional units are not particularly limited, and a known constitutional unit may be used.

The weight-average molecular weight (Mw) of the specific resin is preferably 1,000 or more, more preferably 1,000 to 200,000, and particularly preferably 1,000 to 100,000.

From the viewpoint of deep portion curing properties, formation of a pattern shape, and substrate adhesiveness, the ethylenically unsaturated bonding value (C═C value) of the specific resin is preferably 0.01 mmol/g to 2.5 mmol/g, more preferably 0.05 mmol/g to 2.3 mmol/g, still more preferably 0.1 mmol/g to 2.2 mmol/g, and particularly preferably 0.1 mmol/g to 2.0 mmol/g.

The ethylenically unsaturated bonding value of the specific resin refers to a molar amount of ethylenically unsaturated groups per 1 g of the solid content of the specific resin. The ethylenically unsaturated bonding value can be specified from the amount of the raw material charged to form the specific resin.

From the viewpoint of developability, the acid value of the specific resin is preferably 30 mgKOH/g to 110 mgKOH/g and more preferably 40 mgKOH/g to 90 mgKOH/g. The acid value is measured by the method described above.

From the viewpoint of adhesiveness with the support, the amine value of the specific resin is preferably 0.03 mmol/g to 0.8 mmol/g and more preferably 0.1 mmol/g to 0.5 mmol/g.

The above-described amine value is measured by the following method.

Approximately 0.5 g of the sample is precisely weighed and dissolved in 50 mL of acetic acid, and the mixture is titrated with a 0.1 mol/L acetic acid perchlorate solution using an electric titration method (potential difference titration) and an automatic potentiometric titrator (AT-710M; manufactured by KYOTO ELECTRONICS MANUFACTURING CO., LTD.). In addition, a blank test was performed in the same manner as described above to make corrections.

Amine value (mmol/g)=a×5.611/c

a: consumption amount (mL) of 0.1 mol/L perchloric acid

c: amount (g) of sample

In the present disclosure, as the polymerizable resin, a compound (hereinafter, also referred to as a compound (SP-1)) represented by Formula (SP-1) can also be used. The compound (SP-1) can be preferably used as a dispersant.

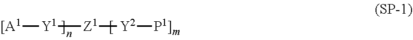

In the formula, Z¹ represents an (m+n)-valent linking group;

Y¹ and Y² each independently represent a single bond or a linking group;

A¹ represents a group including a pigment absorbing portion;

P¹ represents a polymer chain;

n represents 1 to 20, m represents 1 to 20, and m+n is 3 to 21;

n Y¹'s and n A¹'s each may be the same or different from each other;

m Y²'s and m P¹'s each may be the same or different from each other; and

at least one of Z¹, A¹, or P¹ represents an ethylenically unsaturated group.

Examples of the ethylenically unsaturated group included in the compound (SP-1) include a vinyl group, a vinyloxy group, an allyl group, a methallyl group, a (meth)acryloyl group, a styrene group, a cinnamoyl group, and a maleimide group. Among these, a (meth)acryloyl group, a styrene group, or a maleimide group is preferable, a (meth)acryloyl group is more preferable, and an acryloyl group is particularly preferable.

In the compound (SP-1), the ethylenically unsaturated group may be included in any of Z¹, A¹, or P¹, but it is preferable to be included in P¹. In addition, in a case where P¹ includes an ethylenically unsaturated group, P¹ is preferably a polymer chain having a repeating unit including the ethylenically unsaturated group in the side chain.

In Formula (SP-1), A1 represents a group including a pigment absorbing portion. Examples of the pigment absorbing portion include an organic coloring agent structure, a heterocyclic ring structure, an acid group, a group having a basic nitrogen atom, a urea group, a urethane group, a group having a coordinating oxygen atom, a hydrocarbon group having 4 or more carbon atoms, an alkoxysilyl group, an epoxy group, an isocyanate group, and a hydroxy group. Among these, a heterocyclic ring structure, an acid group, a group having a basic nitrogen atom, a hydrocarbon group having 4 or more carbon atoms, or a hydroxy group is preferable, and from the viewpoint of dispersibility of the colorant, an acid group is more preferable. Examples of the acid group include a carboxy group, a sulfo group, and a phosphoric acid group, and a carboxy group is preferable.

One A1 may include at least one pigment absorbing portion, or two or more pigment absorbing portions. A1 preferably includes 1 to 10 pigment absorbing portions and more preferably includes 1 to 6 pigment absorbing portions. In addition, examples of the group including a pigment absorbing portion, which is represented by A¹, include a group formed by bonding the above-described pigment absorbing portion to a linking group composed of 1 to 200 carbon atoms, 0 to 20 nitrogen atoms, 0 to 100 oxygen atoms, 1 to 400 hydrogen atoms, and 0 to 40 sulfur atoms. Examples thereof include a group formed by bonding one or more pigment absorbing portions with each other through a chain-like saturated hydrocarbon group having 1 to 10 carbon atoms, a cyclic saturated hydrocarbon group having 3 to 10 carbon atoms, or an aromatic hydrocarbon group having 5 to 10 carbon atoms. The chain-like saturated hydrocarbon group, the cyclic saturated hydrocarbon group, and the aromatic hydrocarbon group may further have a substituent. Examples of the substituent include an alkyl group having 1 to 20 carbon atoms, an aryl group having 6 to 16 carbon atoms, a hydroxy group, an amino group, a carboxy group, a sulfonic acid amide group, an N-sulfonylamide group, an acyloxy group having 1 to 6 carbon atoms, an alkoxy group having 1 to 20 carbon atoms, a halogen atom, an alkoxycarbonyl group having 2 to 7 carbon atoms, a cyano group, a carbonate ester group, and a photocurable group. In addition, in a case where the pigment absorbing portion itself can form a monovalent group, the pigment absorbing portion itself may be A¹.

In addition, the chemical formula weight of A¹ is preferably 30 to 2,000. The upper limit is preferably 1,000 or less and more preferably 800 or less. The lower limit is preferably 50 or more and more preferably 100 or more. In a case where the chemical formula weight of A¹ is within the above-described range, absorptivity to the colorant is good. The chemical formula weight of A¹ is a value calculated from the structural formula.

In Formula (SP-1), Z¹ represents an (m+n)-valent linking group. Examples of the (m+n)-valent linking group include a group composed of 1 to 100 carbon atoms, 0 to 10 nitrogen atoms, 0 to 50 oxygen atoms, 1 to 200 hydrogen atoms, and 0 to 20 sulfur atoms. Examples of the (m+n)-valent linking group also include a group (which may form a ring structure) composed of the following structural unit or a combination of two or more the following structural units.

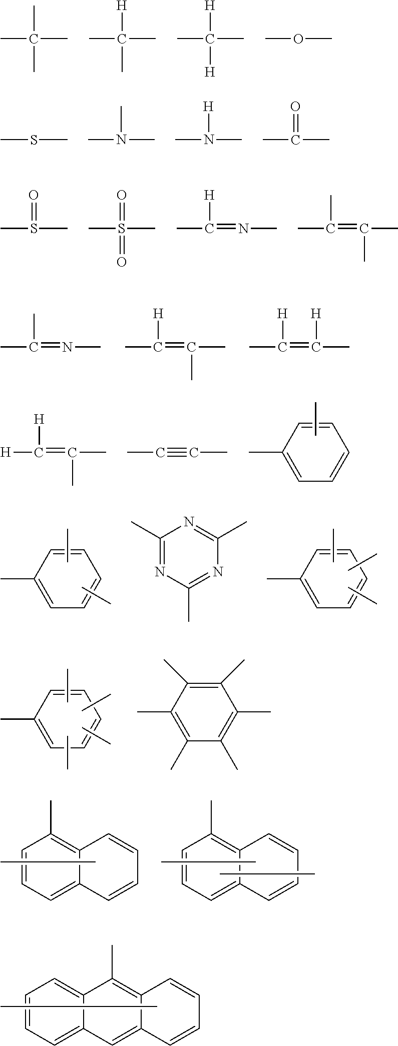

The chemical formula weight of Z is preferably 20 to 3,000. The upper limit is preferably 2,000 or less and more preferably 1,500 or less. The lower limit is preferably 50 or more and more preferably 100 or more. The chemical formula weight of Z¹ is a value calculated from the structural formula. Specific examples of the (m+n)-valent linking group can be found in paragraphs 0043 to 0055 of JP2014-177613A, the content of which is incorporated herein by reference.

In Formula (SP-1), Y¹ and Y² each independently represent a single bond or a linking group. Examples of the linking group include a group composed of 1 to 100 carbon atoms, 0 to 10 nitrogen atoms, 0 to 50 oxygen atoms, 1 to 200 hydrogen atoms, and 0 to 20 sulfur atoms. The above-described group may further have the above-described substituent. Specific examples of the linking group represented by Y¹ and Y² include a group composed of one of the following structural units or a combination of two or more of the structural units.

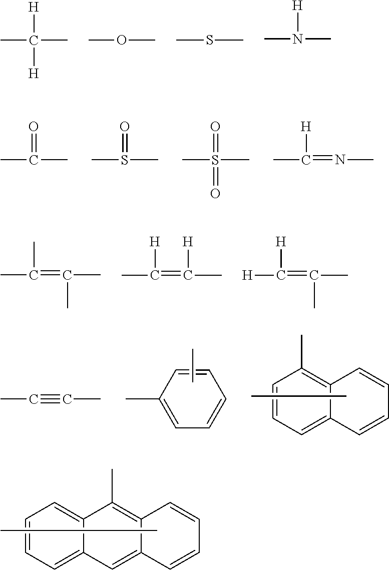

In Formula (SP-1), P¹ represents a polymer chain. As the polymer chain represented by P¹, a polymer chain which has, in the main chain, at least one structural repeating unit selected from the group consisting of a poly(meth)acrylic structural repeating unit, a polyether structural repeating unit, a polyester structural repeating unit, a polyamide structural repeating unit, a polyimide structural repeating unit, a polyimine structural repeating unit, and a polyurethane structural repeating unit is preferable. In addition, as the polymer chain represented by P¹, a polymer chain including a repeating unit represented by Formulae (P1-1) to (P1-5) is preferable.

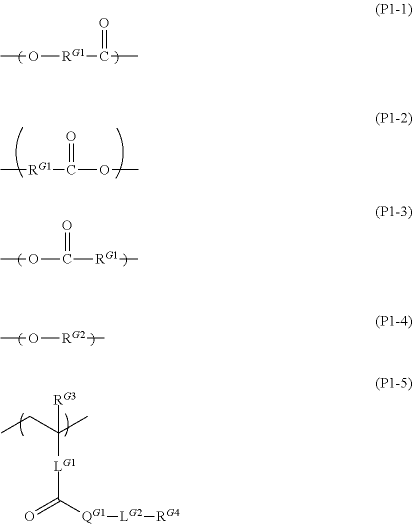

In the formulae, R^{G1} and R^{G2} each independently represent an alkylene group. As the alkylene group represented by R^{G1} and R^{G2}, a linear or branched alkylene group having 1 to 20 carbon atoms is preferable, a linear or branched alkylene group having 2 to 16 carbon atoms is more preferable, and a linear or branched alkylene group having 3 to 12 carbon atoms is still more preferable. The alkylene group may have a substituent. Examples of the substituent include an aryl group, a heteroaryl group, an alkoxy group, an aryloxy group, a heteroaryloxy group, an alkylthioether group, an arylthioether group, a heteroarylthioether group, and an ethylenically unsaturated group.

In the formulae, R^{G3} represents a hydrogen atom or a methyl group.

In the formulae, Q^{G1} represents —O— or —NH—, L^{G1} represents a single bond or an arylene group, and L^{G2} represents a single bond or a divalent linking group. It is preferable that Q^{G1} represents —O—. It is preferable that L^{G1} represents a single bond. Examples of the divalent linking group represented by L^{G2} include an alkylene group (preferably an alkylene group having 1 to 12 carbon atoms), an arylene group (preferably an arylene group having 6 to 20 carbon atoms), —NH—, —δO—, —SO₂—, —CO—, —O—, —COO—, —OCO—, —S—, —NHCO—, —CONH—, and a group formed by a combination of two or more these groups.

R^{G4} represents a hydrogen atom or a substituent. Examples of the substituent include an alkyl group, an aryl group, a heteroaryl group, an alkoxy group, an aryloxy group, a heteroaiyloxy group, an alkylthioether group, an arylthioether group, a heteroarylthioether group, an ethylenically unsaturated group, and an acid group.

The number of repetitions of the above-described structural repeating unit in P¹ is preferably 3 to 2,000. The upper limit is preferably 1,500 or less and more preferably 1,000 or less. The lower limit is preferably 5 or more and more preferably 7 or more. In addition, P¹ is preferably a polymer chain having a structural repeating unit including an ethylenically unsaturated group in the side chain. In addition, the proportion of the structural repeating unit including an ethylenically unsaturated group in the side chain in the total structural repeating units constituting P¹ is preferably 1 mol % or more, more preferably 2 mol % or more, and still more preferably 3 mol % or more. The upper limit may be 100 mol %. In addition, in a case where P¹ is a polymer chain having a structural repeating unit including an ethylenically unsaturated group in the side chain, it is also preferable that P¹ includes other structural repeating units in addition to the structural repeating unit including an ethylenically unsaturated group in the side chain. Examples of the other structural repeating units include a structural repeating unit including an acid group in the side chain. In a case where P¹ includes other structural repeating units including an acid group in the side chain, in addition to the structural repeating unit including an ethylenically unsaturated group in the side chain, the generation of the development residue can be effectively suppressed in the formation of a pattern by a photolithography method. In a case where P¹ includes the structural repeating unit including an acid group in the side chain, the proportion of the structural repeating unit including an acid group in the side chain in the total structural repeating units constituting P¹ is preferably 50 mol % or less, more preferably 2 mol % to 48 mol %, and still more preferably 4 mol % to 46 mol %.

The weight-average molecular weight of the polymer chain represented by P¹ is preferably 1,000 or more and more preferably 1,000 to 10,000. The upper limit is preferably 9,000 or less, more preferably 6,000 or less, and still more preferably 3,000 or less. The lower limit is preferably 1,200 or more and more preferably 1,400 or more. The weight-average molecular weight of P¹ is a value calculated from the weight-average molecular weight of a raw material used for introducing into the polymer chain.

A commercially available product is also available as the dispersant, and specific examples thereof include DISPERBYK series (for example, DISPERBYK-111, 161, and the like) manufactured by BYK Chemie, and Solsperse series (for example, Solsperse 76500) manufactured by Lubrizol Corporation. The dispersing agents described in paragraphs 0041 to 0130 of JP2014-130338A can also be used, the contents of which are incorporated herein by reference. In addition, as the dispersant, compounds described in JP2018-150498A, JP2017-100116A, JP2017-100115A, JP2016-108520A, JP2016-108519A, and JP2015-232105A may be used. The resin described as a dispersant can be used for an application other than the dispersant. For example, the resin can also be used as a binder polymer.

The curable composition according to the embodiment of the present disclosure may include only one kind of binder polymer or two or more kinds thereof.

In addition, the content of the binder polymer is preferably 1 mass % to 50 mass % with respect to the total solid content of the curable composition. The lower limit is preferably 3 mass % or more, more preferably 5 mass % or more, and still more preferably 10 mass % or more. The upper limit is preferably 45 mass % or less and more preferably 40 mass % or less.

In addition, in a case where the curable composition according to the embodiment of the present disclosure includes, as a dispersant, a resin other than the resin represented by Formula (1) according to the present disclosure, the content of the dispersant, which is the resin other than the resin represented by Formula (1), is preferably 10 mass % or less and more preferably 5 mass % or less with respect to the total solid content of the curable composition. In addition, the above-described content of the dispersant, which is the resin other than the resin represented by Formula (1), is preferably 10 mass % or less and more preferably 5 mass % or less with respect to the content of the resin represented by Formula (1) according to the present disclosure.

In addition, from the viewpoint of curing properties, developability, and film-forming property, the total content of the polymerizable compound and the resin described later in the total solid content of the curable composition is preferably 10 mass % to 65 mass %. The lower limit is more preferably 15 mass % or more, still more preferably 20 mass % or more, and particularly preferably 30 mass % or more. The upper limit is more preferably 60 mass % or less, still more preferably 50 mass % or less, and particularly preferably 40 mass % or less.

In addition, the curable composition according to the embodiment of the present disclosure preferably contains 30 parts by mass to 300 parts by mass of the resin with respect to 100 parts by mass of the polymerizable compound. The lower limit is more preferably 50 parts by mass or more and particularly preferably 80 parts by mass or more. The upper limit is more preferably 250 parts by mass or less and particularly preferably 200 parts by mass or less.

<Colorant>

The curable composition according to the embodiment of the present disclosure preferably includes a colorant.

As the colorant, a known colorant can be used, and examples thereof include a pigment and a dye.

<<Pigment>>

The curable composition according to the embodiment of the present disclosure preferably contains a pigment.

Examples of the pigment include a white pigment, a black pigment, a chromatic pigment, and a near-infrared absorbing pigment. In the present disclosure, the white pigment includes not only a pure white pigment but also a bright gray (for example, grayish-white, light gray, and the like) pigment close to white. In addition, the pigment may be an inorganic pigment or an organic pigment, but from the viewpoint that dispersion stability is more easily improved, an organic pigment is preferable. In addition, as the pigment, a pigment having a maximal absorption wavelength in a wavelength range of 400 nm to 2,000 nm is preferable, and a pigment having a maximal absorption wavelength in a wavelength range of 400 nm to 700 nm is more preferable. In addition, in a case of using a pigment (preferably a chromatic pigment) having a maximal absorption wavelength in a wavelength range of 400 nm to 700 nm, the curable composition according to the embodiment of the present disclosure can be preferably used as a curable composition for forming a colored layer in a color filter. Examples of the colored layer include a red-colored layer, a green-colored layer, a blue-colored layer, a magenta-colored layer, a cyan-colored layer, and a yellow-colored layer.

The average primary particle diameter of the pigment is preferably 1 nm to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the curable composition is good. In the present disclosure, the primary particle diameter of the pigment can be determined from an image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present disclosure is the arithmetic average value of the primary particle diameters with respect to 400 primary particles of the pigment. In addition, the primary particle of the pigment refers to a particle which is independent without aggregation.

—Chromatic Pigment—

The chromatic pigment is not particularly limited, and a known chromatic pigment can be used. Examples of the chromatic pigment include a pigment having a maximal absorption wavelength in a wavelength range of 400 nm to 700 nm. Examples thereof include a yellow pigment, an orange pigment, a red pigment, a green pigment, a violet pigment, and a blue pigment. Specific examples of these pigments include the following pigments.

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228 (directly connected quinophthalone dimer described in WO2013/098836A), 231, 232 (methine/polymethine-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279, 294 (xanthene-based, Organo Ultramarine, Bluish Red), 295 (monoazo-based), 296 (diazo-based), and the like (all of which are red pigments);

C. I. Pigment Green 7, 10, 36, 37, 58, 59, 62, and 63 (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 60, 64, 66, 79, 80, 87 (monoazo-based), 88 (methine-based), and the like (all of which are blue pigments).

As the green pigment, a halogenated zinc phthalocyanine compound having an average number of halogen atoms in one molecule of 10 to 14, an average number of bromine atoms in one molecule of 8 to 12, and an average number of chlorine atoms in one molecule of 2 to 5 can also be used. As specific examples thereof, compounds described in WO2015/118720A, compounds described in CN2010-6909027A, a phthalocyanine compound having a phosphoric acid ester as a ligand, and the like can also be used.

In addition, as the green pigment, green pigments described in JP2019-8014A or JP2018-180023A may be used.

An aluminum phthalocyanine compound having a phosphorus atom can also be used as the blue pigment. Specific examples thereof include the compounds described in paragraphs 0022 to 0030 of JP2012-247591A and paragraph 0047 of JP2011-157478A.

In addition, a pigment described in JP2017-201003A and a pigment described in JP2017-197719A can be used as the yellow pigment. In addition, as the yellow pigment, a metal azo pigment which includes at least one kind of an anion selected from the group consisting of an azo compound represented by Formula (Y) and an azo compound having a tautomeric structure of the azo compound represented by Formula (Y), two or more kinds of metal ions, and a melamine compound can be used.

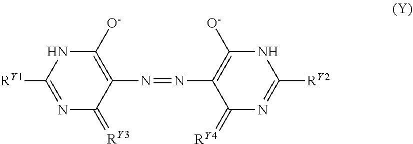

In Formula (Y), R^{Y1} and R^{Y2} each independently represent —OH or NR^{Y5}R^{Y6}, R^{Y3} and R^{Y4} each independently represent ═O or ═NR^{Y7}, and R^{Y5} to R^{Y7} each independently represent a hydrogen atom or an alkyl group.

The alkyl group represented by R^{Y5} to R^{Y7} preferably has 1 to 10 carbon atoms, more preferably has 1 to 6 carbon atoms, and still more preferably has 1 to 4 carbon atoms. The above-described alkyl group may be linear, branched, or cyclic, and is preferably linear or branched and more preferably linear. The above-described alkyl group may have a substituent. Preferred examples of the substituent include a halogen atom, a hydroxy group, an alkoxy group, a cyano group, and an amino group.

The details of the metal azo pigment can be found in paragraphs 0011 to 0062 and 0137 to 0276 of JP2017-171912A, paragraphs 0010 to 0062 and 0138 to 0295 of JP2017-171913A, paragraphs 0011 to 0062 and 0139 to 0190 of JP2017-171914A, and paragraphs 0010 to 0065 and 0142 to 0222 of JP2017-171915A, the contents of which are incorporated herein by reference.

In addition, as the yellow pigment, a quinophthalone dimer represented by Formula (Q) can also be suitably used. Further, a quinophthalone dimer described in JP6443711B can also be suitably used.

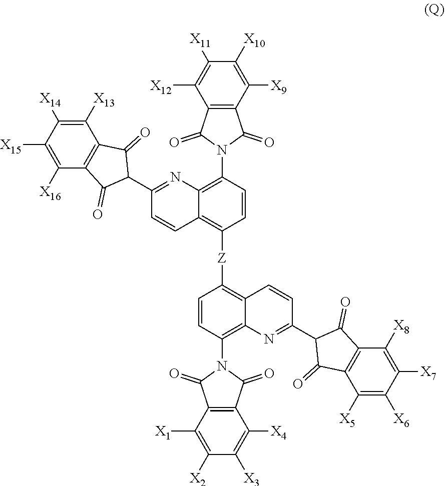

In Formula (Q), X₁ to X₁₆ each independently represent a hydrogen atom or a halogen atom, and Z represents an alkylene group having 1 to 3 carbon atoms.

As the yellow pigment, quinophthalone pigments described in JP2018-203798A, JP2018-62578A, JP6432077B, JP6432076B, JP2018-155881A, JP2018-111757A, JP2018-40835A, JP2017-197640A, JP2016-145282A, JP2014-85565A, JP2014-21139A, JP2013-209614A, JP2013-209435A, JP2013-181015A, JP2013-61622A, JP2013-54339A, JP2013-32486A, JP2012-226110A, JP2008-74987A, JP2008-81565A, JP2008-74986A, JP2008-74985A, JP2008-50420A, JP2008-31281A, or JP1973-32765B (JP-S48-32765B) can also be suitably used.

In addition, as the yellow pigment, the quinophthalone compounds described in paragraphs 0011 to 0034 of JP2013-54339A, the quinophthalone compounds described in paragraphs 0013 to 0058 of JP2014-26228A, yellow pigments described in JP2019-8014A, or the like can be used.

In addition, as the yellow pigment, compounds described in JP2018-62644A can also be used. These compounds can also be used as a pigment derivative.

Further, as described in JP2018-155881A, C. I. Pigment Yellow 129 may be added for the purpose of improving weather fastness.

A diketopyrrolopyrrole-based pigment described in JP2017-201384A, in which the structure has at least one substituted bromine atom, a diketopyrrolopyrrole-based pigment described in paragraphs 0016 to 0022 of JP6248838, and the like can also be used as the red pigment.

Further, as the red pigment, red pigments described in JP6516119B or JP6525101B can also be suitably used.

In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used. As the compound, a compound represented by Formula (DPP1) is preferable, and a compound represented by Formula (DPP2) is more preferable.

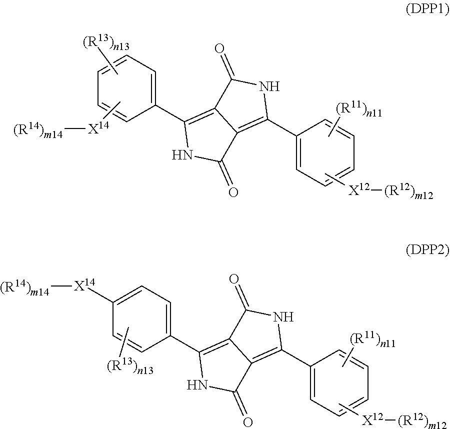

In the formulae, R¹¹ and R¹³ each independently represent a substituent, R¹² and R¹⁴ each independently represent a hydrogen atom, an alkyl group, an aryl group, or a heteroaryl group, n11 and n13 each independently represent an integer of 0 to 4, X¹² and X¹⁴ each independently represent an oxygen atom, a sulfur atom, or a nitrogen atom, in a case where X¹² is an oxygen atom or a sulfur atom, m12 represents 1, in a case where X¹² is a nitrogen atom, m12 represents 2, in a case where X¹⁴ is an oxygen atom or a sulfur atom, m14 represents 1, and in a case where X¹⁴ is a nitrogen atom, m14 represents 2. Preferred specific examples of the substituent represented by R¹¹ and R¹³ include an alkyl group, an aryl group, a halogen atom, an acyl group, an alkoxycarbonyl group, an aryloxycarbonyl group, a heteroaryloxycarbonyl group, an amide group, a cyano group, a nitro group, a trifluoromethyl group, a sulfoxide group, and a sulfo group.

In the present disclosure, the chromatic pigment may be used in combination of two or more kinds thereof. In addition, in a case where the chromatic pigment is used in combination of two or more kinds thereof, the combination of two or more chromatic pigments may form black. Examples of such a combination include the following aspects (1) to (7). In a case where two or more chromatic pigments are included in the curable composition and the combination of two or more chromatic pigments forms black, the curable composition according to the embodiment of the present disclosure can be preferably used as the near-infrared transmission filter.

(1) aspect in which a red pigment and a blue pigment are contained.

(2) aspect in which a red pigment, a blue pigment, and a yellow pigment are contained.

(3) aspect in which a red pigment, a blue pigment, a yellow pigment, and a violet pigment are contained.

(4) aspect in which a red pigment, a blue pigment, a yellow pigment, a violet pigment, and a green pigment are contained.

(5) aspect in which a red pigment, a blue pigment, a yellow pigment, and a green pigment are contained.

(6) aspect in which a red pigment, a blue pigment, and a green pigment are contained.

(7) aspect in which a yellow pigment and a violet pigment are contained.

In addition, in a case of a cyan-colored curable composition, as the colorant, it is preferable to include at least one phthalocyanine pigment selected from the group consisting of C. I. Pigment 15:3 and C. I. Pigment Blue 15:4. Hereinafter, C. I. Pigment Blue 15:3 and C. I. Pigment Blue 15:4 are also collectively referred to as a specific phthalocyanine pigment.

From the reason that it is easy to obtain a cured film having spectral characteristics suitable for cyan color by increasing transparency of visible light, the average secondary particle diameter of the specific phthalocyanine pigment is preferably 50 nm to 100 nm. From the viewpoint of light resistance, the lower limit is preferably 55 nm or more, and more preferably 60 nm or more. From the viewpoint of spectral characteristics, the upper limit is preferably 95 nm or less, and more preferably 90 nm or less.

In the present specification, the average secondary particle diameter of the pigment is measured by directly measuring the size of the secondary particle of the pigment from an electron micrograph using a transmission electron microscope (TEM). Specifically, the minor axis diameter and the major axis diameter of the secondary particle of each pigment are measured, and the average thereof is defined as the particle diameter of the pigment. Next, for each of the 100 pigments, the volume of each pigment is obtained by approximating it to a cube having the obtained particle diameter, and the volume average particle diameter is defined as the average secondary particle diameter.

In a case of a cyan-colored curable composition, the colorant contains the specific phthalocyanine pigment in an amount of preferably 50 mass % or more, more preferably 55 mass % or more, still more preferably 60 mass % or more, and particularly preferably 65 mass % or more with respect to the total mass of the colorant. The upper limit may be 100 mass %, 95 mass % or less, or 90 mass % or less.

In a case where the colorant used in the curable composition according to the embodiment of the present disclosure includes C. I. Pigment Blue 15:3 and C. I. Pigment Blue 15:4, the mass ratio of C. I. Pigment Blue 15:3 and C. I. Pigment Blue 15:4 is preferably 10 parts by mass to 1,000 parts by mass of C. I. Pigment Blue 15:4, more preferably 25 parts by mass to 400 parts by mass of C. I. Pigment Blue 15:4, and still more preferably 50 parts by mass to 200 parts by mass of C. I. Pigment Blue 15:4 with respect to 100 parts by mass of C. I. Pigment Blue 15:3.

—White Pigment—

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. In addition, the white pigment is preferably a particle having a refractive index of 2.10 or more with respect to light having a wavelength of 589 nm. The above-mentioned refractive index is preferably 2.10 to 3.00 and more preferably 2.50 to 2.75.

In addition, as the white pigment, the titanium oxide described in “Titanium Oxide-Physical Properties and Applied Technology, written by Manabu Kiyono, pages 13 to 45, published in Jun. 25, 1991, published by Shuppan Co., Ltd.” can also be used.

The white pigment is not limited to a compound fonned of a single inorganic substance, and may be particles combined with other materials. For example, it is preferable to use a particle having a pore or other materials therein, a particle having a number of inorganic particles attached to a core particle, or a core-shell composite particle composed of a core particle formed of polymer particles and a shell layer formed of inorganic fine nanoparticles. With regard to the core-shell composite particle composed of a core particle formed of polymer particles and a shell layer formed of inorganic fine nanoparticles, reference can be made to, for example, the descriptions in paragraphs 0012 to 0042 of JP2015-047520A, the contents of which are incorporated herein by reference.

As the white pigment, hollow inorganic particles can also be used. The hollow inorganic particles refer to inorganic particles having a structure with a cavity therein, and the cavity is enclosed by an outer shell. As the hollow inorganic particles, hollow inorganic particles described in JP2011-075786A, WO2013/061621A, JP2015-164881A, and the like can be used, the contents of which are incorporated herein by reference.

—Black Pigment—

The black pigment is not particularly limited, and a known black pigment can be used. Examples thereof include carbon black, titanium black, and graphite, and carbon black or titanium black is preferable and titanium black is more preferable. The titanium black is black particles containing a titanium atom, and is preferably lower titanium oxide or titanium oxynitride. The surface of the titanium black can be modified, as necessary, according to the purpose of improving dispersibility, suppressing aggregating properties, and the like. For example, the surface of the titanium black can be coated with silicon oxide, titanium oxide, germanium oxide, aluminum oxide, magnesium oxide, or zirconium oxide. In addition, a treatment with a water-repellent substance as described in JP2007-302836A can be performed. Examples of the black pigment include Color Index (C. I.) Pigment Black 1 and 7. It is preferable that the titanium black has a small primary particle diameter of the individual particles and has a small average primary particle diameter. Specifically, the average primary particle diameter thereof is preferably 10 to 45 nm. The titanium black can be used as a dispersion. Examples thereof include a dispersion which includes titanium black particles and silica particles and in which the content ratio of Si atoms to Ti atoms is adjusted to a range of 0.20 to 0.50. With regard to the dispersion, reference can be made to the description in paragraphs 0020 to 0105 of JP2012-169556A, the contents of which are incorporated herein by reference. Examples of a commercially available product of the titanium black include Titanium black 10S, 12S, 13R, 13M, 13M-C, 13R-N, 13M-T (trade name; manufactured by Mitsubishi Materials Corporation) and Tilack D (trade name; manufactured by Akokasei Co., Ltd.).

—Near-Infrared Absorbing Pigment—

The near-infrared absorbing pigment is preferably an organic pigment. In addition, the near-infrared absorbing pigment preferably has a maximal absorption wavelength in a wavelength range of more than 700 nm and 1,400 nm or less. In addition, the maximal absorption wavelength of the near-infrared absorbing pigment is preferably 1,200 nm or less, more preferably 1,000 nm or less, and still more preferably 950 nm or less. In addition, in the near-infrared absorbing pigment, A₅₅₀/Aₘₐₓ, which is a ratio of an absorbance A₅₅₀ at a wavelength of 550 nm to an absorbance Aₘₐₓ at the maximal absorption wavelength, is preferably 0.1 or less, more preferably 0.05 or less, still more preferably 0.03 or less, and particularly preferably 0.02 or less. The lower limit is not particularly limited, but for example, may be 0.0001 or more or may be 0.0005 or more. In a case where the ratio of the above-described absorbance is within the above-described range, a near-infrared absorbing pigment excellent in visible transparency and near-infrared rays shielding property can be obtained. In the present disclosure, the maximal absorption wavelength of the near-infrared absorbing pigment and values of absorbance at each wavelength are values obtained from an absorption spectrum of a film formed of a curable composition including the near-infrared absorbing pigment.

The near-infrared absorbing pigment is not particularly limited, and examples thereof include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. Among these, at least one compound selected from a pyrrolopyrrole compound, a squarylium compound, a cyanine compound, a phthalocyanine compound, or a naphthalocyanine compound is preferable, and a pyrrolopyrrole compound or a squarylium compound is more preferable, and a pyrrolopyrrole compound is particularly preferable.

The content of the pigment in the total solid content of the curable composition is preferably 5 mass % or more, more preferably 10 mass % or more, still more preferably 20 mass % or more, and even more preferably 30 mass % or more, and particularly preferably 40 mass % or more. The upper limit is preferably 80 mass % or less, more preferably 70 mass % or less, and still more preferably 60 mass % or less.

<<Dye>>

The curable composition according to the embodiment of the present disclosure can contain a dye. The dye is not particularly limited and a known dye can be used. The dye may be a chromatic dye or may be a near-infrared absorbing dye. Examples of the chromatic dye include a pyrazoleazo compound, an anilinoazo compound, a triarylmethane compound, an anthraquinone compound, an anthrapyridone compound, a benzylidene compound, an oxonol compound, a pyrazolotriazoleazo compound, a pyridoneazo compound, a cyanine compound, a phenothiazine compound, a pyrrolopyrazoleazomethine compound, a xanthene compound, a phthalocyanine compound, a benzopyran compound, an indigo compound, and a pyrromethene compound. In addition, the thiazole compound described in JP2012-158649A, the azo compound described in JP2011-184493A, or the azo compound described in JP2011-145540A can also be used. In addition, as yellow dyes, the quinophthalone compounds described in paragraphs 0011 to 0034 of JP2013-054339A, or the quinophthalone compounds described in paragraphs 0013 to 0058 of JP2014-026228A can be used. Examples of the near-infrared absorbing dye include a pyrrolopyrrole compound, a rylene compound, an oxonol compound, a squarylium compound, a cyanine compound, a croconium compound, a phthalocyanine compound, a naphthalocyanine compound, a pyrylium compound, an azurenium compound, an indigo compound, and a pyrromethene compound. In addition, the squarylium compounds described in JP2017-197437A, the squarylium compounds described in paragraphs 0090 to 0107 of WO2017/213047A, the pyrrole ring-containing compounds described in paragraphs 0019 to 0075 of JP2018-054760A, the pyrrole ring-containing compounds described in paragraphs 0078 to 0082 of JP2018-040955A, the pyrrole ring-containing compounds described in paragraphs 0043 to 0069 of JP2018-002773A, the squarylium compounds having an aromatic ring at the α-amide position described in paragraphs 0024 to 0086 of JP2018-041047A, the amide-linked squarylium compounds described in JP2017-179131A, the compounds having a pyrrole bis-type squarylium skeleton or a croconium skeleton described in JP2017-141215A, the dihydrocarbazole bis-type squarylium compounds described in JP2017-082029, the asymmetric compounds described in paragraphs 0027 to 0114 of JP2017-068120A, the pyrrole ring-containing compounds (carbazole type) described in JP2017-067963A, the phthalocyanine compounds described in JP6251530B, and the like can be used.

The content of the dye in the total solid content of the curable composition is preferably 1 mass % or more, more preferably 5 mass % or more, and particularly preferably 10 mass % or more. The upper limit is not particularly limited, but is preferably 70 mass % or less, more preferably 65 mass % or less, and still more preferably 60 mass % or less.

In addition, the content of the dye is preferably 5 to 50 parts by mass with respect to 100 parts by mass of the pigment. The upper limit is preferably 45 parts by mass or less and more preferably 40 parts by mass or less. The lower limit is preferably 10 parts by mass or more and still more preferably 15 parts by mass or more.

In addition, it is also possible that the curable composition according to the embodiment of the present disclosure does not substantially contain the dye. The case where the curable composition according to the embodiment of the present disclosure does not substantially include the dye means that the content of the dye in the total solid content of the curable composition according to the embodiment of the present disclosure is preferably 0.1 mass % or less, more preferably 0.05 mass % or less, and particularly preferably 0 mass %.

<Polymerizable Compound>

From the viewpoint of film hardness and pattern formability, the curable composition according to the embodiment of the present disclosure preferably further includes a polymerizable compound, and more preferably further includes a polymerizable compound and a photopolymerization initiator described later.

The reaction mechanism in the curing of the polymerizable compound is not particularly limited. Examples thereof include a radical polymerization reaction, a cationic polymerization reaction, a condensation polymerization reaction, a nucleophilic addition reaction, and a crosslinking reaction by a substitution reaction. The polymerizable compound is preferably a compound which is cured by a radical polymerization reaction.

Examples of the polymerizable group include an ethylenically unsaturated group and an epoxy group. Examples of the ethylenically unsaturated group include a vinyl group, a vinyloxy group, an allyl group, a methallyl group, a (meth)acryloyl group, a styrene group, a cinnamoyl group, and a maleimide group. Among these, a (meth)acryloyl group, a styrene group, or a maleimide group is preferable, a (meth)acryloyl group is more preferable, and an acryloyl group is particularly preferable.

The polymerizable compound may be either a monomer or a resin such as a polymer. It is also possible to use a monomer type polymerizable compound and a resin type polymerizable compound in combination.

However, with regard to the content, the polymer having a polymerizable group is treated as the above-described binder polymer.

The molecular weight of the polymerizable compound is preferably less than 3,000. The upper limit is more preferably 2,000 or less and still more preferably 1,500 or less. The lower limit is preferably 100 or more, more preferably 150 or more, and still more preferably 250 or more. The polymerizable compound is preferably a compound having 3 or more ethylenically unsaturated groups, more preferably a compound having 3 to 15 ethylenically unsaturated groups, and still more preferably a compound having 3 to 6 ethylenically unsaturated groups. In addition, the polymerizable compound is preferably a trifunctional to pentadecafunctional (meth)acrylate compound and more preferably a trifunctional to hexafunctional (meth)acrylate compound. Specific examples of the polymerizable monomer include the compounds described in paragraphs 0095 to 0108 of JP2009-288705A, paragraph 0227 of JP2013-029760A, paragraphs 0254 to 0257 of JP2008-292970A, paragraphs 0034 to 0038 of JP2013-253224A, paragraph 0477 of JP2012-208494A, JP2017-048367A, JP6057891B, and JP6031807B, the contents of which are incorporated herein by reference.

As the polymerizable compound, dipentaerythritol triacrylate (as a commercially available product, KAYARAD D-330 manufactured by Nippon Kayaku Co., Ltd.), dipentaerythritol tetraacrylate (as a commercially available product, KAYARAD D-320 manufactured by Nippon Kayaku Co., Ltd.), dipentaerythritol penta(meth)acrylate (as a commercially available product, KAYARAD D-310 manufactured by Nippon Kayaku Co., Ltd.), dipentaerythritol hexa(meth)acrylate (as a commercially available product, KAYARAD DPHA manufactured by Nippon Kayaku Co., Ltd., NK ESTER A-DPH-12E manufactured by Shin-Nakamura Chemical Co., Ltd.), or a compound having a structure in which these (meth)acryloyl groups are bonded through an ethylene glycol and/or a propylene glycol residue (for example, SR454 and SR499 which are commercially available products from Sartomer) is preferable. In addition, as the polymerizable compound, NK ESTER A-TMMT (manufactured by Shin-Nakamura Chemical Co., Ltd.) and KAYARAD RP-1040 and DPCA-20 (manufactured by Nippon Kayaku Co., Ltd.) can also be used. In addition, as the polymerizable monomer, it is also preferable to use a trifunctional (meth)acrylate compound such as trimethylolpropane tri(meth)acrylate, trimethylolpropane propyleneoxide-modified tri(meth)acrylate, trimethylolpropane ethyleneoxide-modified tri(meth)acrylate, isocyanuric acid ethyleneoxide-modified tri(meth)acrylate, and pentaerythritol tri(meth)acrylate. Examples of a commercially available product of the trifunctional (meth)acrylate compound include ARONIX M-309, M-310, M-321, M-350, M-360, M-313, M-315, M-306, M-305, M-303, M-452, and M-450 (manufactured by TOAGOSEI CO., LTD.), NK ESTER A9300, A-GLY-9E, A-GLY-20E, A-TMM-3, A-TMM-3L, A-TMM-3LM-N, A-TMPT, and TMPT (manufactured by Shin-Nakamura Chemical Co., Ltd.), and KAYARAD GPO-303, TMPTA, THE-330, TPA-330, and PET-30 (manufactured by Nippon Kayaku Co., Ltd.).

As the polymerizable compound, a compound having an acid group can also be used. By using a polymerizable compound having an acid group, the curable composition layer in a non-exposed portion is easily removed during development and the generation of the development residue can be suppressed.

Examples of the acid group include a carboxy group, a sulfo group, and a phosphoric acid group, and a carboxy group is preferable. Examples of the polymerizable compound having an acid group include succinic acid-modified dipentaerythritol penta(meth)acrylate. Examples of a commercially available product of the polymerizable monomer having an acid group include ARONIX M-510, M-520, and ARONIX TO-2349 (manufactured by TOAGOSEI CO., LTD). The acid value of the polymerizable monomer having an acid group is preferably 0.1 mgKOH/g to 40 mgKOH/g and more preferably 5 mgKOH/g to 30 mgKOH/g. In a case where the acid value of the polymerizable compound is 0.1 mgKOH/g or more, solubility in a developer is good, and in a case where the acid value of the polymerizable compound is 40 mgKOH/g or less, it is advantageous in production and handling.

The polymerizable compound is also preferably a compound having a caprolactone structure. Examples of the polymerizable compound having a caprolactone structure include DPCA-20, DPCA-30, DPCA-60, and DPCA-120, each of which is commercially available as KAYARAD DPCA series from Nippon Kayaku Co., Ltd.

As the polymerizable compound, a compound having an alkyleneoxy group can also be used. The polymerizable compound having an alkyleneoxy group is preferably a compound having an ethyleneoxy group and/or a propyleneoxy group, more preferably a compound having an ethyleneoxy group, and still more preferably a trifunctional to hexafunctional (meth)acrylate compound having 4 to 20 ethyleneoxy groups. Examples of a commercially available product of the polymerizable compound having an alkyleneoxy group include SR-494 manufactured by Sartomer, which is a tetrafunctional (meth)acrylate having 4 ethyleneoxy groups, and KAYARAD TPA-330 manufactured by Nippon Kayaku Co., Ltd., which is a trifunctional (meth)acrylate having 3 isobutyleneoxy groups.

As the polymerizable compound, it is also preferable to use a compound which does not substantially include environmentally regulated substances such as toluene. Examples of a commercially available product of such a compound include KAYARAD DPHA LT and KAYARAD DPEA-12 LT (manufactured by Nippon Kayaku Co., Ltd.).

The urethane acrylates described in JP1973-041708B (JP-S48-041708B), JP1976-037193A (JP-S51-037193A), JP1990-032293B (JP-H02-032293B), or JP1990-016765B (JP-H02-016765B), or the urethane compounds having an ethylene oxide skeleton described in JP1983-049860B (JP-S58-049860B), JP1981-017654B (JP-S56-017654B), JP1987-039417B (JP-S62-039417B), or JP1987-039418B (JP-S62-039418B) are also suitable as the polymerizable compound. In addition, the compounds having an amino structure or a sulfide structure in the molecule, described in JP1988-277653A (JP-S63-277653A), JP1988-260909A (JP-S63-260909A), or JP1989-105238A (JP-HO1-105238A), are also preferably used. In addition, as the polymerizable compound, commercially available products such as UA-7200 (manufactured by Shin-Nakamura Chemical Co., Ltd.), DPHA-40H (manufactured by Nippon Kayaku Co., Ltd.), and UA-306H, UA-306T, UA-306I, AH-600, T-600, AI-600, and LINC-202UA (manufactured by KYOEISHA CHEMICAL Co., Ltd.) can also be used.

As a compound having an epoxy group (hereinafter, also referred to as an epoxy compound) which is used as the polymerizable compound, a compound having two or more epoxy groups in one molecule is preferably used. The upper limit of epoxy groups of the epoxy compound is preferably 100 or less, more preferably 10 or less, and still more preferably 5 or less.

The epoxy equivalent (=the molecular weight of the compound having an epoxy group/the number of epoxy groups) of the epoxy compound is preferably 500 g/eq or less, more preferably 100 g/eq to 400 g/eq, and still more preferably 100 g/eq to 300 g/eq.

The epoxy compound may be a low-molecular-weight compound (for example, molecular weight: less than 1,000) or a high-molecular weight compound (macromolecule; for example, molecular weight: 1,000 or more, and in the case of a polymer, weight-average molecular weight: 1,000 or more). The molecular weight (in a case of the polymer, the weight-average molecular weight) of the epoxy compound is preferably 200 to 100,000 and more preferably 500 to 50,000. The upper limit of the molecular weight (in a case of the polymer, the weight-average molecular weight) is preferably 3,000 or less, more preferably 2,000 or less, and still more preferably 1,500 or less.

As the epoxy compound, compounds described in paragraphs 0034 to 0036 of JP2013-011869A, paragraphs 0147 to 0156 of JP2014-043556A, and paragraphs 0085 to 0092 of JP2014-089408A can also be used. The contents of the publications are incorporated herein by reference. With regard to a commercially available product of the epoxy compound, examples of a bisphenol A type epoxy resin include jER825, jER827, jER828, jER834, jER1001, jER1002, jER1003, jER1055, jER1007, jER1009, and jER1010 (all of which are manufactured by Mitsubishi Chemical Corporation), and EPICLON 860, EPICLON 1050, EPICLON 1051, and EPICLON 1055 (all of which are manufactured by DIC Corporation); examples of a bisphenol F type epoxy resin include jER806, jER807, jER4004, jER4005, jER4007, and jER4010 (all of which are manufactured by Mitsubishi Chemical Corporation), EPICLON 830 and EPICLON 835 (both of which are manufactured by DIC Corporation), and LCE-21 and RE-602S (both of which are manufactured by Nippon Kayaku Co., Ltd.); examples of a phenol novolac type epoxy resin include jER152, jER154, jER157S70, and jER157S65 (all of which are manufactured by Mitsubishi Chemical Corporation), and EPICLON N-740, EPICLON N-770, and EPICLON N-775 (all of which are manufactured by DIC Corporation); examples of a cresol novolac type epoxy resin include EPICLON N-660, EPICLON N-665, EPICLON N-670, EPICLON N-673, EPICLON N-680, EPICLON N-690, and EPICLON N-695 (all of which are manufactured by DIC Corporation), and EOCN-1020 (manufactured by Nippon Kayaku Co., Ltd.); and examples of an aliphatic epoxy resin include ADEKA RESIN EP-4080S, ADEKA RESIN EP-4085S, and ADEKA RESIN EP-4088S (all of which are manufactured by ADEKA Corporation), CELLOXIDE 2021P, CELLOXIDE 2081, CELLOXIDE 2083, CELLOXIDE 2085, EHPE 3150, EPOLEAD PB 3600, and EPOLEAD PB 4700 (all of which are manufactured by Daicel Corporation), and DENACOL EX-212L, DENACOL EX-214L, DENACOL EX-216L, DENACOL EX-321L, and DENACOL EX-850L (all of which are manufactured by Nagase ChemteX Corporation). Other examples thereof include ADEKA RESIN EP-4000S, ADEKA RESIN EP-4003S, ADEKA RESIN EP-4010S, and ADEKA RESIN EP-4011S (all of which manufactured by ADEKA Corporation), NC-2000, NC-3000, NC-7300, XD-1000, EPPN-501, and EPPN-502 (all of which are manufactured by ADEKA Corporation), and jER1031S (manufactured by Mitsubishi Chemical Corporation).

The polymerizable compound may be used alone or in combination of two or more kinds thereof.

The content of the polymerizable compound is preferably 0.1 mass % to 40 mass % with respect to the total solid content of the curable composition. The lower limit is preferably 1 mass % or more and more preferably 2 mass % or more. The upper limit is preferably 30 mass % or less, more preferably 20 mass % or less, and still more preferably 10 mass % or less.

In addition, in a case where the epoxy compound is used as the polymerizable compound, the content of the epoxy compound is preferably 0.1 mass % to 40 mass % with respect to the total solid content of the curable composition. The lower limit is, for example, more preferably 1 mass % or more and still more preferably 2 mass % or more. The upper limit is, for example, preferably 30 mass % or less and still more preferably 20 mass % or less. The epoxy compound may be used singly or in combination of two or more thereof. In addition, in a case where the ethylenically unsaturated compound and the compound having an epoxy group are used in combination, the proportion (mass ratio) between the compounds is preferably the mass of the ethylenically unsaturated compound:the mass of the compound having an epoxy group=100:1 to 100:400, more preferably 100:1 to 100:100, and still more preferably 100:1 to 100:50.

A preferred aspect of the curable composition according to the embodiment of the present disclosure is as follows.

The curable composition includes an ethylenically unsaturated compound and a resin, in which M¹/B¹, which is a ratio of a mass M¹ of the ethylenically unsaturated compound included in the curable composition to a mass B¹ of the binder polymer included in the curable composition, is preferably 0.35 or less, more preferably 0.25 or less, and particularly preferably 0.15 or less. Within the above-described range, a cured film having more excellent moisture resistance can be formed. Furthermore, it is also possible to suppress film contraction in a case of forming a cured film. In particular, in a case where a polymerizable resin is used as the resin, the above-described effects are obtained more significantly. The lower limit of the value of M¹/B¹ described above is preferably 0.01 or more, more preferably 0.04 or more, and still more preferably 0.07 or more.

In addition, in the above-described aspect, the total solid content of the polymerizable compound and the binder polymer is preferably 1 mass % to 50 mass % with respect to the total solid content of the curable composition. The lower limit is preferably 3 mass % or more, more preferably 5 mass % or more, and still more preferably 10 mass % or more. The upper limit is preferably 45 mass % or less and more preferably 40 mass % or less.

<Polymerization Initiator>

The curable composition according to the embodiment of the present disclosure preferably further includes a polymerization initiator, and more preferably further includes a photopolymerization initiator. In particular, in a case where the ethylenically unsaturated compound is used as the curable compound, it is particularly preferable that the curable composition according to the embodiment of the present disclosure further includes a photopolymerization initiator. The polymerization initiator is not particularly limited, and can be appropriately selected from known photopolymerization initiators and thermal polymerization initiators. As the photopolymerization initiator, a compound having photosensitivity to light in a range from an ultraviolet ray range to a visible range is preferable. In addition, the photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. The details of the photopolymerization initiator can be found in paragraphs 0065 to 0111 of JP2014-130173A and in JP6301489B, the contents of which are incorporated herein by reference.

Examples of a commercially available product of the α-hydroxyketone compound include IRGACURE-184, DAROCUR-1173, IRGACURE-500, IRGACURE-2959, and IRGACURE-127 (all manufactured by BASF). Examples of a commercially available product of the α-aminoketone compound include IRGACURE-907, IRGACURE-369, IRGACURE-379, and IRGACURE-379EG (all manufactured by BASF). Examples of a commercially available product of the acylphosphine compound include IRGACURE-819 and DAROCUR-TPO (both manufactured by BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, and the compounds described in paragraphs 0025 to 0038 of WO2017/164127A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

In addition, as an oxime compound in which a hydroxy group is substituted in a carbazole skeleton, which is used as the photopolymerization initiator, compounds described in WO2019/088055A can also be used.

In addition, an oxime compound having a fluorene ring can also be used as the photopolymerization initiator. Specific examples of the oxime compound having a fluorene ring include the compounds described in JP2014-137466A. The contents of the publications are incorporated herein by reference.

In addition, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A. The contents of the publications are incorporated herein by reference.

Further, an oxime compound having a nitro group can be used as the photopolymerization initiator. The oxime compound having a nitro group is also preferably used in the form of a dimer. Specific examples of the oxime compound having a nitro group include the compounds described in paragraphs 0031 to 0047 of JP2013-114249A and paragraphs 0008 to 0012 and 0070 to 0079 of JP2014-137466A, the compounds described in paragraphs 0007 to 0025 of JP4223071B, and ADEKA ARKLS NCI-831 (manufactured by ADEKA Corporation).

An oxime compound having a benzofuran skeleton can also be used as the photopolymerization initiator. Specific examples thereof include OE-01 to OE-75 described in WO2015/036910A.

Specific examples of the oxime compound preferably used are shown below, but the oxime compound is not limited thereto.

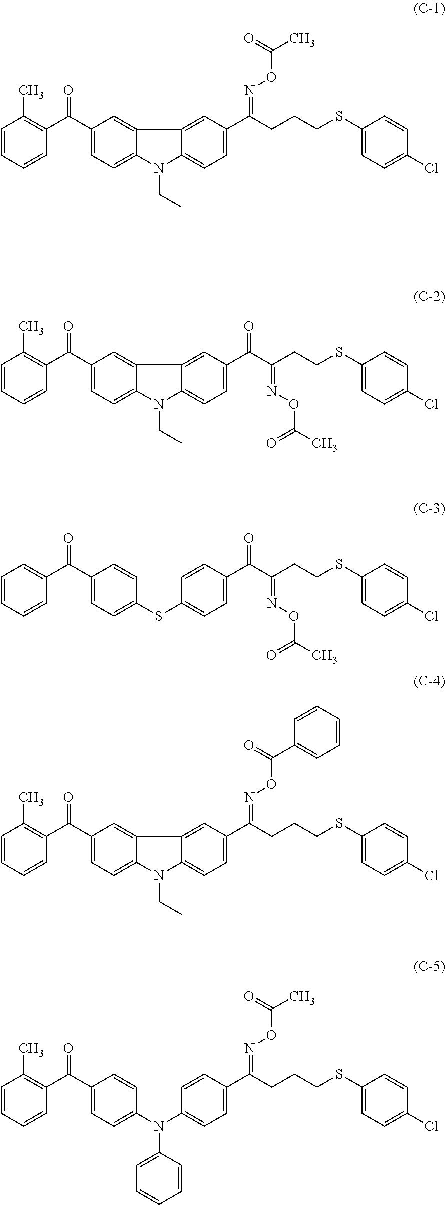 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1]

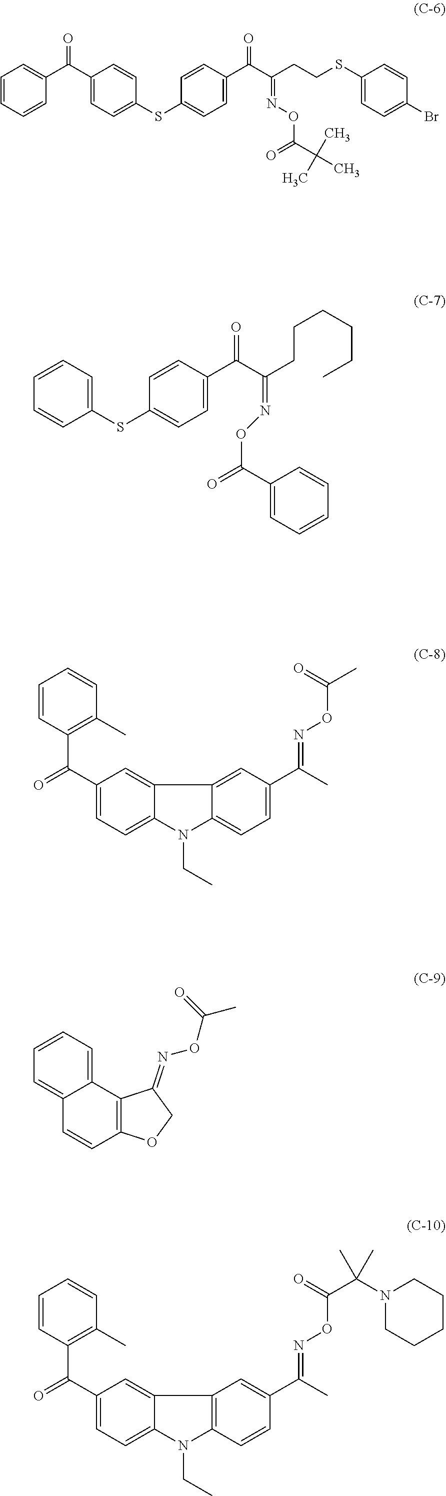 [SMILES: CC(C)(C)C(=O)O/N=C(\CCSc1ccc(Br)cc1)C(=O)c1ccc(Sc2ccc(C(=O)c3ccccc3)cc2)cc1 ; CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

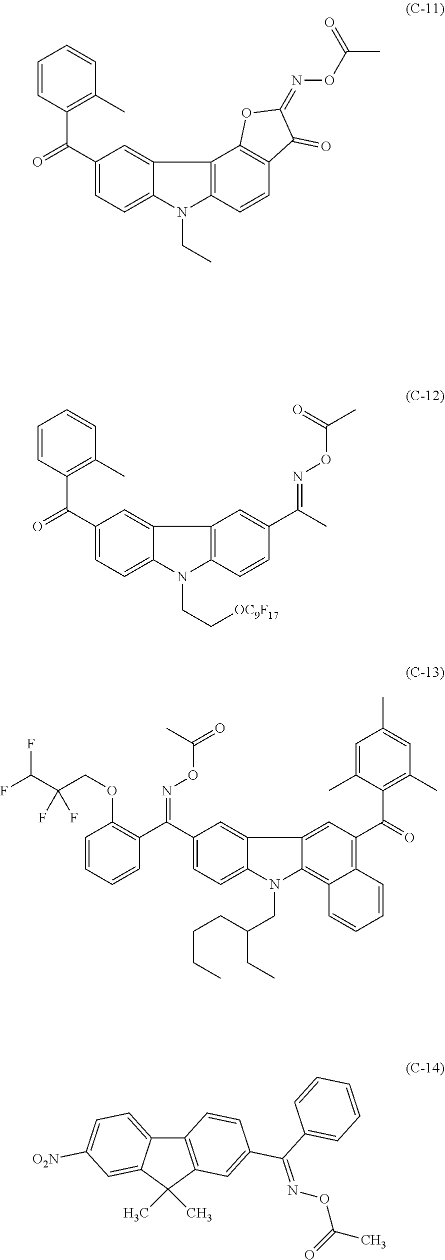

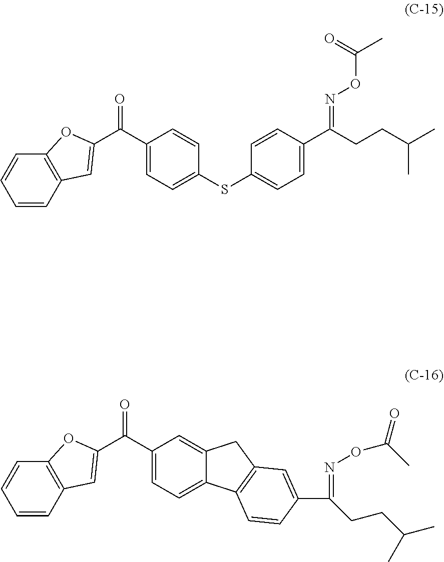 [SMILES: CC(=O)O/N=C(\CCC(C)C)c1ccc(Sc2ccc(C(=O)c3cc4ccccc4o3)cc2)cc1 ; CC(=O)O/N=C(\CCC(C)C)c1ccc2c(c1)Cc1cc(C(=O)c3cc4ccccc4o3)ccc1-2]

The oxime compound is preferably a compound having a maximal absorption wavelength in a wavelength range of 350 nm to 500 nm and more preferably a compound having a maximal absorption wavelength in a wavelength range of 360 nm to 480 nm. In addition, from the viewpoint of sensitivity, the molar absorption coefficient of the oxime compound at a wavelength of 365 nm or 405 nm is preferably high, more preferably 1,000 to 300,000, still more preferably 2,000 to 300,000, and particularly preferably 5,000 to 200,000. The molar absorption coefficient of a compound can be measured using a well-known method. For example, the molar absorption coefficient is preferably measured by a spectrophotometer (Cary-5 spectrophotometer, manufactured by Varian) using an ethyl acetate solvent at a concentration of 0.01 g/L.

In addition, examples of the thermal polymerization initiator or a polymerization initiator which can be polymerized with both light and heat include peroxide compounds described in MATERIAL STAGE p. 37 to 60, vol. 19, No. 3, 2019, WO2018/221177A, WO2018/110179A, or JP2019-43864A.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the curable composition can be improved. Specific examples of the bifunctional or tri- or higher functional photoradical polymerization initiator include dimers of the oxime compounds described in JP2010-527339A, JP2011-524436A, WO2015/004565A, paragraphs 0407 to 0412 of JP2016-532675A, and paragraphs 0039 to 0055 of WO2017/033680A; the compound (E) and compound (G) described in JP2013-522445A; Cmpd 1 to 7 described in WO2016/034963A; the oxime ester photoinitiators described in paragraph 0007 of JP2017-523465A; the photoinitiators described in paragraphs 0020 to 0033 of JP2017-167399A; and the photopolymerization initiator (A) described in paragraphs 0017 to 0026 of JP2017-151342A.

The content of the photopolymerization initiator in the total solid content of the curable composition according to the embodiment of the present disclosure is preferably 0.1 mass % to 30 mass %. The lower limit is preferably 0.5 mass % or more and more preferably 1 mass % or more. The upper limit is preferably 20 mass % or less and more preferably 15 mass % or less. In the curable composition according to the embodiment of the present disclosure, the photopolymerization initiator may be used singly or in combination of two or more kinds thereof. In a case where two or more kinds thereof are used, the total amount thereof is preferably within the above-described range.

<Pigment Derivative>

The curable composition according to the embodiment of the present disclosure can contain a pigment derivative.

Examples of the pigment derivative include a compound having a structure in which a portion of a pigment is substituted with an acid group, a basic group, or a phthalimidomethyl group.

As the pigment derivative, compounds described in JP1981-118462A (JP-S56-118462A), JP1988-264674A (JP-S63-264674A), JP1989-217077A (JP-HO1-217077A), JP1991-009961A (JP-H03-009961A), JP1991-026767A (JP-H03-026767A), JP1991-153780A (JP-H03-153780A), JP1991-045662A (JP-H03-045662A), JP1992-285669A (JP-H04-285669A), JP1994-145546A (JP-H06-145546A), JP1994-212088A (JP-H06-212088A), JP1994-240158A (JP-H06-240158A), JP1998-030063A (JP-H10-030063A), JP1998-195326A (JP-H10-195326A), paragraphs 0086 to 0098 of WO2011/024896A, paragraphs 0063 to 0094 of WO2012/102399A, paragraph 0082 of WO2017/038252A, paragraph 0171 of JP2015-151530A, JP2019-133154A, and the like can be used, the contents of which are incorporated herein by reference.

In addition, the pigment derivative preferably has, as a chromophore, a coloring agent skeleton such as a quinoline-based skeleton, a benzimidazolone-based skeleton, a diketopyrrolopyrrole-based skeleton, an azo-based skeleton, a phthalocyanine-based skeleton, an anthraquinone-based skeleton, a quinacridone-based skeleton, a dioxazine-based skeleton, a perinone-based skeleton, a perylene-based skeleton, a thioindigo-based skeleton, an isoindoline-based skeleton, an isoindolinone-based skeleton, a quinophthalone-based skeleton, a threne-based skeleton, and a metal complex-based skeleton. Among these, a quinoline-based skeleton, a benzimidazolone-based skeleton, a diketopyrrolopyrrole-based skeleton, an azo-based skeleton, a quinophthalone-based skeleton, an isoindoline-based skeleton, or a phthalocyanine-based skeleton is preferable, and an azo-based skeleton or a benzimidazolone-based skeleton is more preferable. As the acid group included in the pigment derivative, a sulfo group or a carboxy group is preferable and a sulfo group is more preferable. As the basic group included in the pigment derivative, an amino group is preferable and a tertiary amino group is more preferable.

The pigment derivative preferably includes a pigment derivative having a basic group (also referred to as a “basic pigment derivative”). In addition, from the viewpoint of developability and dispersion stability, the curable compound according to the embodiment of the present disclosure more preferably includes a binder polymer (dispersant) having an acid group and the pigment derivative having a basic group.

The content of the pigment derivative is preferably 1 part by mass to 50 parts by mass with respect to 100 parts by mass of the pigment. The lower limit value is preferably 3 parts by mass or more and more preferably 5 parts by mass or more. The upper limit value is preferably 40 parts by mass or less and more preferably 30 parts by mass or less. In a case where the content of the pigment derivative is within the above-described range, dispersibility of the pigment can be enhanced, and aggregation of the pigment can be efficiently suppressed. The pigment derivative may be used singly or in combination of two or more kinds thereof. In a case of using two or more kinds thereof, the total amount thereof is preferably within the above-described range.

<Silane Coupling Agent>

The curable composition according to the embodiment of the present disclosure can contain a silane coupling agent. According to this aspect, adhesiveness of a cured film to be obtained with a support can be improved. The silane coupling agent means a silane compound having a hydrolyzable group and other functional groups. In addition, the hydrolyzable group refers to a substituent directly linked to a silicon atom and capable of forming a siloxane bond due to at least one of a hydrolysis reaction or a condensation reaction. Examples of the hydrolyzable group include a halogen atom, an alkoxy group, and an acyloxy group, and an alkoxy group is preferable. That is, it is preferable that the silane coupling agent is a compound having an alkoxysilyl group. Examples of the functional group other than the hydrolyzable group include a vinyl group, a (meth)allyl group, a (meth)acryloyl group, a mercapto group, an epoxy group, an oxetanyl group, an amino group, a ureido group, a sulfide group, an isocyanate group, and a phenyl group, and an amino group, a (meth)acryloyl group, or an epoxy group is preferable. Specific examples of the silane coupling agent include the compounds described in paragraphs 0018 to 0036 of JP2009-288703A and the compounds described in paragraphs 0056 to 0066 of JP2009-242604A, the contents of which are incorporated herein by reference.

The content of the silane coupling agent in the total solid content of the curable composition is preferably 0.1 mass % to 5 mass %. The upper limit is preferably 3 mass % or less and more preferably 2 mass % or less. The lower limit is preferably 0.5 mass % or more and more preferably 1 mass % or more. The silane coupling agent may be used singly or in combination of two or more kinds thereof. In a case of using two or more kinds thereof, the total amount thereof is preferably within the above-described range.

<Solvent>

The curable composition according to the embodiment of the present disclosure can contain a solvent.

Examples of the solvent include an organic solvent. Basically, the solvent is not particularly limited as long as it satisfies solubility of the respective components or coating properties of the curable composition. Examples of the organic solvent include an ester-based solvent, a ketone-based solvent, an alcohol-based solvent, an amide-based solvent, an ether-based solvent, and a hydrocarbon-based solvent. With regard to details thereof, reference can be made to the description in paragraph 0223 of WO2015/166779A, the contents of which are incorporated herein by reference. In addition, an ester-based solvent substituted with a cyclic alkyl group or a ketone-based solvent substituted with a cyclic alkyl group can also be preferably used. Specific examples of the organic solvent include polyethylene glycol monomethyl ether (PGMEA), dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, propylene glycol monomethyl ether acetate, 3-methoxy-N,N-dimethylpropanamide, and 3-butoxy-N,N-dimethylpropanamide. However, it may be preferable that the content of aromatic hydrocarbons (such as benzene, toluene, xylene, and ethylbenzene) as the solvent is low (for example, 50 parts per million (ppm) by mass or less, 10 ppm by mass or less, or 1 ppm by mass or less with respect to the total amount of the organic solvent) in consideration of environmental aspects and the like.

The SP value of a typical organic solvent is as follows.

PGMEA (SP value=9.2), MFG (1-methoxy-2-propanol) (SP value=11.5), cyclohexanone (SP value=10.0), butyl acetate (SP value=8.7)

In the curable composition according to the embodiment of the present disclosure, a solvent having a low metal content is preferably used. For example, the metal content in the solvent is preferably 10 ppb (parts per billion) by mass or less. A solvent in which the metal content is at a level of ppt (parts per trillion) by mass may be used as desired, and such a high-purity solvent is provided by, for example, Toyo Kasei Kogyo Co., Ltd. (The Chemical Daily, Nov. 13, 2015).

Examples of a method for removing impurities such as a metal from the solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The solvent may include isomers (compounds having the same number of atoms and different structures). In addition, only one kind of isomers may be included, or a plurality of isomers may be included.

The organic solvent preferably has the content of peroxides of 0.8 mmol/L or less, and more preferably, the organic solvent does not substantially include peroxides.

The content of the solvent in the curable composition is preferably 10 mass % to 95 mass %, more preferably 20 mass % to 90 mass %, and still more preferably 30 mass % to 90 mass %.

In addition, from the viewpoint of environmental regulation, it is preferable that the curable composition according to the embodiment of the present disclosure does not substantially contain environmentally regulated substances. In the present disclosure, the description “does not substantially contain environmentally regulated substances” means that the content of the environmentally regulated substances in the coloring composition is 50 ppm by mass or less, preferably 30 ppm by mass or less, still more preferably 10 ppm by mass or less, and particularly preferably 1 ppm by mass or less. Examples of the environmentally regulated substances include benzenes; alkylbenzenes such as toluene and xylene; and halogenated benzenes such as chlorobenzene. These compounds are registered as enviromnentally regulated substances in accordance with Registration Evaluation Authorization and Restriction of CHemicals (REACH) rules, Pollutant Release and Transfer Register (PRTR) law, Volatile Organic Compounds (VOC) regulation, and the like, and strictly regulated in their usage and handling method. These compounds can be used as a solvent in a case of producing respective components used in the curable composition according to the embodiment of the present disclosure, and may be incorporated into the curable composition as a residual solvent. From the viewpoint of human safety and environmental considerations, it is preferable to reduce these substances as much as possible. Examples of a method for reducing the environmentally regulated substances include a method for reducing the environmentally regulated substances by distilling the environmentally regulated substances from a system by heating or depressurizing the system such that the temperature of the system is higher than a boiling point of the environmentally regulated substances. In addition, in a case of distilling a small amount of the environmentally regulated substances, it is also useful to azeotrope with a solvent having the boiling point equivalent to that of the above-described solvent in order to increase efficiency. In addition, in a case of containing a compound having radical polymerizability, in order to suppress the radical polymerization reaction proceeding during the distillation under reduced pressure to cause crosslinking between the molecules, a polymerization inhibitor or the like may be added and the distillation under reduced pressure is performed. These distillation methods can be performed at any stage of raw material, product (for example, resin solution after polymerization or polyfunctional monomer solution) obtained by reacting the raw material, or curable composition produced by mixing these compounds.

<Polymerization Inhibitor>

The curable composition according to the embodiment of the present disclosure preferably further includes a polymerization inhibitor.

Examples of the polymerization inhibitor include hydroquinone, p-methoxyphenol, di-tert-butyl-p-cresol, 2,2,6,6-tetramethylpiperidin-1-oxyl, 2,2,6,6-tetramethyl-4-hydroxypiperidin-1-oxyl, pyrogallol, tert-butyl catechol, benzoquinone, 4,4′-thiobis(3-methyl-6-tert-butylphenol), 2,2′-methylenebis(4-methyl-6-t-butylphenol), and an N-nitrosophenylhydroxylamine salt (an ammonium salt, a cerous salt, or the like). Among these, it is preferable to include at least one compound selected from the group consisting of 2,2,6,6-tetramethylpiperidin-1-oxyl and 2,2,6,6-tetramethyl-4-hydroxypiperidin-1-oxyl. The content of the polymerization inhibitor in the total solid content of the curable composition is preferably 0.0001 mass % to 5 mass %.

<Surfactant>

The curable composition according to the embodiment of the present disclosure can contain a surfactant.

As the surfactant, various surfactants such as a fluorine-based surfactant, a nonionic surfactant, a cationic surfactant, an anionic surfactant, and a silicon-based surfactant can be used. With regard to the surfactant, reference can be made to the description in paragraphs 0238 to 0245 of WO2015/166779A and paragraphs 0253 to 0260 of JP2018-173660A, the contents of which are incorporated herein by reference.

It is preferable that the surfactant is a fluorine-based surfactant. By containing a fluorine-based surfactant in the curable composition, liquid characteristics (particularly, fluidity) are further improved, and liquid saving properties can be further improved. In addition, it is possible to form a film with a small thickness unevenness.

The fluorine atom content in the fluorine-based surfactant is preferably 3 mass % to 40 mass %, more preferably 5 mass % to 30 mass %, and particularly preferably 7 mass % to 25 mass %. The fluorine-based surfactant in which the fluorine atom content is within the above-described range is effective in terms of the evenness of the thickness of the coating film or liquid saving properties and the solubility of the surfactant in the curable composition is also good.

The content of the surfactant in the total solid content of the curable composition is preferably 0.001 mass % to 5.0 mass % and more preferably 0.005 mass % to 3.0 mass %. The surfactant may be used singly or in combination of two or more kinds thereof. In a case of using two or more kinds thereof, the total amount thereof is preferably within the above-described range.

<Ultraviolet Absorber>

The curable composition according to the embodiment of the present disclosure preferably includes an ultraviolet absorber.

As the ultraviolet absorber, a conjugated diene compound, an aminodiene compound, a salicylate compound, a benzophenone compound, a benzotriazole compound, an acrylonitrile compound, a hydroxyphenyltriazine compound, an indole compound, a triazine compound, or the like can be used. With regard to details thereof, reference can be made to the description in paragraphs 0052 to 0072 of JP2012-208374A, paragraphs 0317 to 0334 of JP2013-068814A, and paragraphs 0061 to 0080 of JP2016-162946A, the contents of which are incorporated herein by reference. Examples of a commercially available product of the ultraviolet absorber include UV-503 (manufactured by Daito Chemical Co., Ltd). In addition, examples of the benzotriazole compound include MYUA series manufactured by Miyoshi Oil & Fat Co., Ltd. (The Chemical Daily, Feb. 1, 2016). In addition, as the ultraviolet absorber, compounds described in paragraphs 0049 to 0059 of JP6268967B can also be used.

The content of the ultraviolet absorber in the total solid content of the curable composition is preferably 0.01 mass % to 10 mass % and more preferably 0.01 mass % to 5 mass %. The ultraviolet absorber may be used singly or in combination of two or more kinds thereof. In a case where two or more kinds thereof are used, it is preferable that the total amount thereof is within the above-described range.

<Antioxidant>

The curable composition according to the embodiment of the present disclosure can contain an antioxidant.

Examples of the antioxidant include a phenol compound, a phosphite ester compound, and a thioether compound. As the phenol compound, any phenol compound which is known as a phenol-based antioxidant can be used. Preferred examples of the phenol compound include a hindered phenol compound. A compound having a substituent at a site (ortho position) adjacent to a phenolic hydroxy group is preferable. As the substituent, a substituted or unsubstituted alkyl group having 1 to 22 carbon atoms is preferable. In addition, as the antioxidant, a compound having a phenol group and a phosphite ester group in the same molecule is also preferable. In addition, as the antioxidant, a phosphorus antioxidant can also be suitably used. Examples of the phosphorus antioxidant include tris[2-[[2,4,8,10-tetrakis(1,1-dimethylethyl)dibenzo[d,f][1,3,2]dioxaphosphepin-6-yl]oxy]ethyl]amine, tris[2-[(4,6,9,11-tetra-tert-butyldibenzo[d,f][1,3,2]dioxaphosphepin-2-yl)oxy]ethyl]amine, and ethyl bis(2,4-di-tert-butyl-6-methylphenyl)phosphite. Examples of a commercially available product of the antioxidant include ADK STAB AO-20, ADK STAB AO-30, ADK STAB AO-40, ADK STAB AO-50, ADK STAB AO-50F, ADK STAB AO-60, ADK STAB AO-60G, ADK STAB AO-80, and ADK STAB AO-330 (all of which are manufactured by ADEKA Corporation). In addition, as the antioxidant, compounds described in paragraphs 0023 to 0048 of JP6268967B can also be used.

The content of the antioxidant in the total solid content of the curable composition is preferably 0.01 mass % to 20 mass % and more preferably 0.3 mass % to 15 mass %. The antioxidant may be used singly or in combination of two or more kinds thereof. In a case where two or more kinds thereof are used, it is preferable that the total amount thereof is within the above-described range.

<Other Components>

Optionally, the curable composition according to the embodiment of the present disclosure may further contain a sensitizer, a curing accelerator, a filler, a thermal curing accelerator, a plasticizer, and other auxiliary agents (for example, conductive particles, an antifoaming agent, a flame retardant, a leveling agent, a peeling accelerator, an aromatic chemical, a surface tension adjuster, or a chain transfer agent). By appropriately containing these components, properties such as film properties can be adjusted. The details of the components can be found in, for example, paragraphs 0183 and later of JP2012-003225A (corresponding to paragraph 0237 of US2013/0034812A) and paragraphs 0101 to 0104 and 0107 to 0109 of JP2008-250074A, the contents of which are incorporated herein by reference. In addition, optionally, the curable composition according to the embodiment of the present disclosure may contain a potential antioxidant. Examples of the potential antioxidant include a compound in which a site functioning as an antioxidant is protected by a protective group, and the protective group is eliminated by heating the compound at 100° C. to 250° C. or heating the compound at 80° C. to 200° C. in the presence of an acid or base catalyst so that the compound functions as an antioxidant. Examples of the potential antioxidant include the compounds described in WO2014/021023A, WO2017/030005A, and JP2017-008219A. Examples of a commercially available product thereof include ADEKA ARKLS GPA-5001 (manufactured by ADEKA Corporation).

In addition, in order to adjust the refractive index of a film to be obtained, the curable composition according to the embodiment of the present disclosure may contain a metal oxide. Examples of the metal oxide include TiO₂, ZrO₂, Al₂O₃, and SiO₂. The primary particle diameter of the metal oxide is preferably 1 nm to 100 nm, more preferably 3 nm to 70 nm, and most preferably 5 nm to 50 nm. The metal oxide may have a core-shell structure, and in this case, the core portion may be hollow.

In addition, the curable composition according to the embodiment of the present disclosure may include a light-resistance improver. Examples of the light-resistance improver include the compounds described in paragraphs 0036 and 0037 of JP2017-198787A, the compounds described in paragraphs 0029 to 0034 of JP2017-146350A, the compounds described in paragraphs 0036 and 0037, and 0049 to 0052 of JP2017-129774A, the compounds described in paragraphs 0031 to 0034, 0058, and 0059 of JP2017-129674A, the compounds described in paragraphs 0036 and 0037, and 0051 to 0054 of JP2017-122803A, the compounds described in paragraphs 0025 to 0039 of WO2017/164127A, the compounds described in paragraphs 0034 to 0047 of JP2017-186546A, the compounds described in paragraphs 0019 to 0041 of JP2015-025116A, the compounds described in paragraphs 0101 to 0125 of JP2012-145604A, the compounds described in paragraphs 0018 to 0021 of JP2012-103475A, the compounds described in paragraphs 0015 to 0018 of JP2011-257591A, the compounds described in paragraphs 0017 to 0021 of JP2011-191483A, the compounds described in paragraphs 0108 to 0116 of JP2011-145668A, and the compounds described in paragraphs 0103 to 0153 of JP2011-253174A.

In addition, the curable composition according to the embodiment of the present disclosure may include a dispersion aid. Examples of the dispersion aid include a pigment derivative (synergist) in which an organic pigment is used as a parent skeleton, and an acidic group, a basic group, or an aromatic group is introduced as a substituent in the side chain. The dispersion aid is preferably added in an amount of 1 to 50 parts by mass with respect to 100 parts by mass of the pigment.

For example, in a case where a film is formed by application, the viscosity (25° C.) of the curable composition according to the embodiment of the present disclosure is preferably 1 mPa·s to 100 mPa·s. The lower limit is more preferably 2 mPa·s or more and still more preferably 3 mPa·s or more. The upper limit is more preferably 50 mPa·s or less, still more preferably 30 mPa·s or less, and particularly preferably 15 mPa·s or less.

In the curable composition according to the embodiment of the present disclosure, the content of liberate metal which is not bonded to or coordinated with a pigment or the like is preferably 100 ppm or less, more preferably 50 ppm or less, and still more preferably 10 ppm or less, it is particularly preferable to not contain the liberate metal substantially. According to this aspect, effects such as stabilization of pigment dispersibility (restraint of aggregation), improvement of spectral characteristics due to improved dispersibility, restraint of conductivity fluctuation due to stabilization of curable components or elution of metal atoms and metal ions, and improvement of display characteristics can be expected. In addition, the effects described in JP2012-153796A, JP2000-345085A, JP2005-200560A, JP1996-043620A (JP-H08-043620A), JP2004-145078A, JP2014-119487A, JP2010-083997A, JP2017-090930A, JP2018-025612A, JP2018-025797A, JP2017-155228A, JP2018-036521A, and the like can also be obtained. Examples of the types of the above-described liberated metals include Na, K, Ca, Sc, Ti, Mn, Cu, Zn, Fe, Cr, Co, Mg, Al, Sn, Zr, Ga, Ge, Ag, Au, Pt, Cs, Ni, Cd, Pb, and Bi. In addition, in the curable composition according to the embodiment of the present disclosure, the content of liberated halogen which is not bonded to or coordinated with a pigment or the like is preferably 100 ppm or less, more preferably 50 ppm or less, and still more preferably 10 ppm or less, it is particularly preferable to not contain the liberated halogen substantially. Examples of halogen include F, Cl, Br, I, and anions thereof. Examples of a method for reducing liberated metals and halogens in the curable composition include washing with ion exchange water, filtration, ultrafiltration, and purification with an ion exchange resin.

It is also preferable that the curable composition according to the embodiment of the present disclosure does not substantially include terephthalic acid ester. Here, the “does not substantially include” means that the content of terephthalic acid ester is 1,000 mass ppb or less in the total mass of the curable composition, and it is more preferable to be 100 mass ppb or less and particularly preferable to be 0.

The moisture content of the curable composition in the present disclosure is preferably 3 mass % or less, more preferably 0.01 mass % to 1.5 mass %, and particularly preferably 0.1 mass % to 1.0 mass %. The moisture content can be measured by a Karl Fischer method.

<Storage Container>

A storage container of the curable composition according to the embodiment of the present disclosure is not particularly limited, and a known storage container can be used. In addition, as the storage container, it is also preferable to use a multilayer bottle having a container interior wall constituted with six layers from six kinds of resins or a bottle having a 7-layer structure from 6 kinds of resins for the purpose of suppressing infiltration of impurities into raw materials or curable compositions. Examples of such a container include the containers described in JP2015-123351A.

In addition, for the curable composition according to the embodiment of the present disclosure and a composition used for manufacturing an image sensor, for the purpose of preventing metal elution from the container interior wall, improving storage stability of the composition, and suppressing the alteration of components, it is also preferable that the interior wall of the storage container is formed of glass, stainless steel, or the like.

<Method for Producing Curable Composition>

The curable composition according to the embodiment of the present disclosure can be produced by mixing the above-described components. During the production of the curable composition, all the components may be dissolved and/or dispersed in a solvent at the same time to produce the curable composition. Optionally, two or more solutions or dispersion liquids in which the respective components are appropriately blended may be prepared, and the solutions or dispersion liquids may be mixed with each other during use (during application) to produce the curable composition.

In addition, in the production of the curable composition, a process of dispersing the pigment is preferably included. In the process for dispersing the pigment, examples of a mechanical force which is used for dispersing the pigment include compression, pressing, impact, shear, and cavitation. Specific examples of these processes include a beads mill, a sand mill, a roll mill, a ball mill, a paint shaker, a microfluidizer, a high-speed impeller, a sand grinder, a flow jet mixer, high-pressure wet atomization, and ultrasonic dispersion. In addition, in the pulverization of the pigment in a sand mill (beads mill), it is preferable to perform a treatment under the condition for increasing a pulverization efficiency by using beads having small diameters; increasing the filling rate of the beads; or the like. Incidentally, it is preferable to remove coarse particles by filtration, centrifugation, or the like after the pulverization treatment. In addition, as the process and the dispersing machine for dispersing the pigment, the process and the dispersing machine described in “Dispersion Technology Comprehension, published by Johokiko Co., Ltd., Jul. 15, 2005”, “Actual comprehensive data collection on dispersion technology and industrial application centered on suspension (solid/liquid dispersion system), published by Publication Department, Management Development Center, Oct. 10, 1978”, and paragraph 0022 of JP2015-157893A can be suitably used. In addition, in the process for dispersing the pigment, a refining treatment of particles in a salt milling step may be performed. With regard to the materials, equipment, treatment conditions, and the like used in the salt milling step, reference can be made to, for example, the description in JP2015-194521A and JP2012-046629A.

During the production of the curable composition, it is preferable that the curable composition is filtered through a filter, for example, in order to remove foreign matters or to reduce defects. As the filter, any filters that have been used in the related art for filtration use and the like may be used without particular limitation. Examples of a material of the filter include: a fluororesin such as polytetrafluoroethylene (PTFE); a polyamide resin such as nylon (for example, nylon-6 or nylon-6,6); and a polyolefin resin (including a polyolefin resin having a high density and an ultrahigh molecular weight) such as polyethylene or polypropylene (PP). Among these materials, polypropylene (including a high-density polypropylene) and nylon are preferable.

The pore size of the filter is preferably 0.01 μm to 7.0 m, more preferably 0.01 μm to 3.0 m, and still more preferably 0.05 μm to 0.5 μm. In a case where the pore size of the filter is within the above-described range, fine foreign matters can be reliably removed. With regard to the pore size value of the filter, reference can be made to a nominal value of filter manufacturers. As the filter, various filters provided by Nihon Pall Corporation (DFA4201NIEY and the like), Advantec Toyo Kaisha., Ltd., Nihon Entegris G.K. (formerly Nippon Microlith Co., Ltd.), Kitz Microfilter Corporation, and the like can be used.

In addition, it is preferable that a fibrous filter material is used as the filter. Examples of the fibrous filter material include a polypropylene fiber, a nylon fiber, and a glass fiber. Examples of a commercially available product include SBP type series (SBP008 and the like), TPR type series (TPR002, TPR005, and the like), or SHPX type series (SHPX003 and the like), all manufactured by Roki Techno Co., Ltd.

In a case of using a filter, different filters (for example, a first filter, a second filter, and the like) may be combined. In this case, the filtration with each of the filters may be performed once or may be performed twice or more times. In addition, filters having different pore sizes within the above-described range may be combined. In addition, the filtration through the first filter may be performed with only a dispersion liquid, the other components may be mixed therewith, and then the filtration through the second filter may be performed.

(Cured Product)

The cured product according to the embodiment of the present disclosure is a cured product obtained by curing the curable composition according to the embodiment of the present disclosure.

The cured product according to the embodiment of the present disclosure can be suitably used in a color filter or the like. Specifically, the cured product according to the embodiment of the present invention can be preferably used as a colored layer (pixel) of a color filter.

The cured product according to the embodiment of the present disclosure is preferably a film-like cured product (cured film), and the film thickness thereof can be appropriately adjusted depending on the purposes. For example, the film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

(Color Filter)

Next, the color filter according to an embodiment of the present disclosure will be described.

The color filter according to the embodiment of the present disclosure has the cured product according to the embodiment of the present disclosure, and it is preferable to have the cured product according to the embodiment of the present disclosure as a pixel of the color filter. The color filter according to the embodiment of the present disclosure can be used for a solid-state imaging element such as a charge coupled device (CCD) and a complementary metal-oxide semiconductor (CMOS), an image display device, or the like.

The above-described pixel of the color filter is not particularly limited, and examples thereof include a red pixel, a green pixel, a blue pixel, a cyan pixel, a yellow pixel, and a magenta pixel.

In the color filter according to the embodiment of the present disclosure, the thickness of a film obtained from the cured product according to the embodiment of the present disclosure can be appropriately adjusted depending on the purposes. The film thickness is preferably 20 μm or less, more preferably 10 μm or less, and still more preferably 5 μm or less. The lower limit of the film thickness is preferably 0.1 μm or more, more preferably 0.2 μm or more, and still more preferably 0.3 μm or more.

In the color filter according to the embodiment of the present disclosure, the width of the pixel is preferably 0.5 μm to 20.0 μm. The lower limit is preferably 1.0 μm or more and more preferably 2.0 μm or more. The upper limit is preferably 15.0 μm or less and more preferably 10.0 μm or less. In addition, the Young's modulus of the pixel is preferably 0.5 GPa to 20 GPa and more preferably 2.5 GPa to 15 GPa.

Each pixel included in the color filter according to the embodiment of the present disclosure preferably has high flatness. Specifically, the surface roughness Ra of the pixel is preferably 100 nm or less, more preferably 40 nm or less, and still more preferably 15 nm or less. The lower limit is not specified, but is preferably, for example, 0.1 nm or more. The surface roughness of the pixel can be measured, for example, using an atomic force microscope (AFM) Dimension 3100 manufactured by Veeco Instruments, Inc. In addition, the contact angle of water on the pixel can be appropriately set to a preferred value and is typically in the range of 500 to 110°. The contact angle can be measured, for example, using a contact angle meter CV-DT-A Model (manufactured by Kyowa Interface Science Co., Ltd.). In addition, it is preferable that the volume resistivity value of the pixel is high. Specifically, the volume resistivity value of the pixel is preferably 10⁹ Ω·cm or more and more preferably 10¹¹ Ω·cm or more. The upper limit is not specified, but is, for example, preferably 10¹⁴ Ω·cm or less. The volume resistivity value of the pixel can be measured, for example, using an ultra-high resistance meter 5410 (manufactured by Advantest Corporation).

In addition, the pixel obtained by curing the curable composition according to the embodiment of the present disclosure can also be suitably used in a pixel configuration described in WO2019/102887A.

In addition, in the color filter according to the embodiment of the present disclosure, a protective layer may be provided on a surface of the cured product according to the embodiment of the present disclosure. By providing the protective layer, various functions such as oxygen shielding, low reflection, hydrophilicity/hydrophobicity, and shielding of light (ultraviolet rays, near-infrared rays, and the like) having a specific wavelength can be imparted. The thickness of the protective layer is preferably 0.01 μm to 10 μm and more preferably 0.1 μm to 5 μm. Examples of a method for forming the protective layer include a method of forming the protective layer by applying a resin composition dissolved in an organic solvent, a chemical vapor deposition method, and a method of attaching a molded resin with an adhesive material. Examples of components constituting the protective layer include a (meth)acrylic resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, a styrene resin, a polyol resin, a polyvinylidene chloride resin, a melamine resin, a urethane resin, an aramid resin, a polyamide resin, an alkyd resin, an epoxy resin, a modified silicone resin, a fluororesin, a polycarbonate resin, a polyacrylonitrile resin, a cellulose resin, Si, C, W, Al₂O₃, Mo, SiO₂, and Si₂N₄, and two or more kinds of these components may be contained. For example, in a case of a protective layer for oxygen shielding, it is preferable that the protective layer contains a polyol resin, SiO₂, and Si₂N₄. In addition, in a case of a protective layer for low reflection, it is preferable that the protective layer contains a (meth)acrylic resin and a fluororesin.

In a case of forming the protective layer by applying a resin composition, as a method for applying the resin composition, a known method such as a spin coating method, a casting method, a screen printing method, and an ink jet method can be used. As the organic solvent included in the resin composition, a known organic solvent (for example, propylene glycol 1-monomethyl ether 2-acetate, cyclopentanone, ethyl lactate, and the like) can be used. In a case of forming the protective layer by a chemical vapor deposition method, as the chemical vapor deposition method, a known chemical vapor deposition method (thermochemical vapor deposition method, plasma chemical vapor deposition method, and photochemical vapor deposition method) can be used.

The protective layer may contain, as desired, an additive such as organic or inorganic particles, an absorber of a specific wavelength (for example, ultraviolet rays, near-infrared rays, and the like), a refractive index adjusting agent, an antioxidant, an adhesive agent, and a surfactant. Examples of the organic or inorganic particles include polymer fine particles (for example, silicone resin particles, polystyrene particles, and melamine resin particles), titanium oxide, zinc oxide, zirconium oxide, indium oxide, aluminum oxide, titanium nitride, titanium oxynitride, magnesium fluoride, hollow silica, silica, calcium carbonate, and barium sulfate. As the absorber of a specific wavelength, a known absorber can be used. Examples of the ultraviolet absorber and near-infrared absorber include the above-described materials. The content of these additives can be appropriately adjusted, but is preferably 0.1 mass % to 70 mass % and more preferably 1 mass % to 60 mass % with respect to the total weight of the protective layer.

In addition, as the protective layer, the protective layers described in paragraphs 0073 to 0092 of JP2017-151176A can also be used.

The color filter may have a base layer. The base layer can be formed, for example, of a composition obtained by removing the colorant from the above-described curable composition according to the embodiment of the present disclosure. In addition, the composition forming the base layer preferably includes at least one selected from the group consisting of the above-described binder polymer, surfactant, and polymerizable compound.

Further, a surface contact angle of the base layer in a color filter having red, green, and blue (RGB) pixels, is preferably 20 to 70 in a case of being measured with diiodomethane, and preferably 30 to 80 in a case of being measured with water. Within the above-described range of contact angle, coating properties in a case of forming the color filter are appropriate, and application properties of the composition forming the base layer are also excellent. In order to set the contact angle within the above-described range, a method such as addition of a surfactant can be mentioned.

<Method for Manufacturing Color Filter>

Next, a method for manufacturing the color filter according to the embodiment of the present disclosure will be described.

The color filter according to the embodiment of the present disclosure can be suitably manufactured through a step of forming a curable composition layer on a support using the curable composition according to the embodiment of the present disclosure, and a step of forming a pattern on the curable composition layer by a photolithography method or a dry etching method.

—Photolithography Method—

First, a case of forming a pattern by a photolithography method to manufacture a color filter will be described.

Pattern formation by a photolithography method preferably includes a step of forming a curable composition layer on a support using the curable composition according to the embodiment of the present disclosure, a step of exposing the curable composition layer in a patterned manner, and a step of removing a non-exposed portion of the curable composition layer by development to form a pattern (pixel). A step (pre-baking step) of baking the curable composition layer and a step (post-baking step) of baking the developed pattern (pixel) may be provided, as desired.

In the step of forming a curable composition layer, a coloring composition layer is formed on a support using the curable composition according to the embodiment of the present disclosure. The support is not particularly limited, and can be appropriately selected depending on applications. Examples thereof include a glass substrate and a silicon substrate, and a silicon substrate is preferable. In addition, a charge coupled device (CCD), a complementary metal-oxide semiconductor (CMOS), a transparent conductive film, or the like may be formed on the silicon substrate. In some cases, a black matrix for isolating each pixel is formed on the silicon substrate. In addition, an undercoat layer may be provided on the silicon substrate so as to improve adhesiveness to an upper layer, prevent the diffusion of materials, or planarize the surface of the substrate.

As a method for applying the curable composition, a known method can be used. Examples thereof include a dropping method (drop casting); a slit coating method; a spray method; a roll coating method; a spin coating method (spin coating); a cast coating method; a slit and spin method; a pre-wet method (for example, a method described in JP2009-145395A), various printing methods such as an ink jet (for example, on-demand type, piezo type, thermal type), a discharge printing such as nozzle jet, a flexo printing, a screen printing, a gravure printing, a reverse offset printing, and a metal mask printing; a transfer method using molds and the like; and a nanoimprinting method. A method for applying the ink jet is not particularly limited, and examples thereof include a method described in “Extension of Use of Ink Jet—Infinite Possibilities in Patent—” (February, 2005, S. B. Research Co., Ltd.) (particularly, pp. 115 to 133) and methods described in JP2003-262716A, JP2003-185831A, JP2003-261827A, JP2012-126830A, and JP2006-169325A. In addition, with regard to the method for applying the curable composition, reference can be made to the description in WO2017/030174A and WO2017/018419A, the contents of which are incorporated herein by reference.

The curable composition layer formed on the support may be dried (pre-baked). In a case of producing a film by a low-temperature process, pre-baking may not be performed. In a case of performing the pre-baking, the pre-baking temperature is preferably 150° C. or lower, more preferably 120° C. or lower, and still more preferably 110° C. or lower. The lower limit may be set to, for example, 50° C. or higher, or to 80° C. or higher. The pre-baking time is preferably 10 seconds to 300 seconds, more preferably 40 seconds to 250 seconds, and still more preferably 80 seconds to 220 seconds. The pre-baking can be performed using a hot plate, an oven, or the like.

<<Exposing Step>>

Next, the curable composition layer is exposed in a patterned manner (exposing step). For example, the curable composition layer can be exposed in a patterned manner using an exposure device such as a stepper exposure device and a scanner exposure device through a mask having a predetermined mask pattern. Thus, the exposed portion can be cured.

Examples of the radiation (light) which can be used during the exposure include g-rays and i-rays. In addition, light (preferably light having a wavelength of 180 nm to 300 nm) having a wavelength of 300 nm or less can be used. Examples of the light having a wavelength of 300 nm or less include KrF-rays (wavelength: 248 nm) and ArF-rays (wavelength: 193 nm), and KrF-rays (wavelength: 248 nm) are preferable. In addition, a long-wave light source of 300 nm or more can be used.

In addition, in a case of exposure, the photosensitive composition layer may be irradiated with light continuously to expose the photosensitive composition layer, or the photosensitive composition layer may be irradiated with light in a pulse to expose the photosensitive composition layer (pulse exposure). The pulse exposure refers to an exposing method in which light irradiation and resting are repeatedly performed in a short cycle (for example, millisecond-level or less). In a case of the pulse exposure, the pulse width is preferably 100 nanoseconds (ns) or less, more preferably 50 nanoseconds or less, and still more preferably 30 nanoseconds or less. The lower limit of the pulse width is not particularly limited, and may be 1 femtosecond (fs) or more or 10 femtoseconds or more. The frequency is preferably 1 kHz or more, more preferably 2 kHz or more, and still more preferably 4 kHz or more. The upper limit of the frequency is preferably 50 kHz or less, more preferably 20 kHz or less, and still more preferably 10 kHz or less. The maximum instantaneous illuminance is preferably 50,000,000 W/m² or more, more preferably 100,000,000 W/m² or more, and still more preferably 200,000,000 W/m² or more. In addition, the upper limit of the maximum instantaneous illuminance is preferably 1,000,000,000 W/m² or less, more preferably 800,000,000 W/m² or less, and still more preferably 500,000,000 W/m² or less. The pulse width refers to a time during which light is irradiated in a pulse period. In addition, the frequency refers to the number of pulse periods per second. In addition, the maximum instantaneous illuminance refers to an average illuminance within the period of light irradiation in the pulse period. In addition, the pulse period refers to a period in which light irradiation and resting in the pulse exposure are defined as one cycle.

The irradiation dose (exposure amount) is, for example, preferably 0.03 J/cm² to 2.5 J/cm² and more preferably 0.05 J/cm² to 1.0 J/cm². The oxygen concentration during the exposure can be appropriately selected, and the exposure may also be performed, for example, in a low-oxygen atmosphere having an oxygen concentration of 19% by volume or less (for example, 15% by volume, 5% by volume, and substantially oxygen-free) or in a high-oxygen atmosphere having an oxygen concentration of more than 21% by volume (for example, 22% by volume, 30% by volume, and 50% by volume), in addition to an atmospheric air. In addition, the exposure illuminance can be appropriately set, and can be preferably selected from a range of 1,000 W/m² to 100,000 W/m² (for example, 5,000 W/m², 15,000 W/m², or 35,000 W/m²). Appropriate conditions of each of the oxygen concentration and the exposure illuminance may be combined, and for example, a combination of the oxygen concentration of 10% by volume and the illuminance of 10,000 W/m², a combination of the oxygen concentration of 35% by volume and the illuminance of 20,000 W/m², or the like is available.

Next, the non-exposed portion of the curable composition layer is removed by development to form a pattern (pixel). The non-exposed portion of the coloring composition layer can be removed by development using a developer. Thus, the curable composition layer of the non-exposed portion in the exposing step is eluted into the developer, and as a result, only a photocured portion remains. As the developer, an organic alkaline developer causing no damage on a base of element, circuit, or the like is desirable. The temperature of the developer is preferably, for example, 20° C. to 30° C. The development time is preferably 20 seconds to 180 seconds. In addition, in order to improve residue removing properties, a step of removing the developer by shaking off per 60 seconds and supplying a fresh developer may be repeated multiple times.

As the developer, an aqueous alkaline solution (alkaline developer) obtained by diluting an alkali agent with pure water is preferable. Examples of the alkali agent include organic alkaline compounds such as ammonia, ethylamine, diethylamine, dimethylethanolamine, diglycol amine, diethanolamine, hydroxyamine, ethylenediamine, tetramethylammonium hydroxide, tetraethylamnonium hydroxide, tetrapropylammonium hydroxide, tetrabutylammonium hydroxide, ethyltrimethylammonium hydroxide, benzyltrimethylammonium hydroxide, dimethylbis(2-hydroxyethyl)ammonium hydroxide, choline, pyrrole, piperidine, and 1,8-diazabicyclo[5.4.0]-7-undecene, and inorganic alkaline compounds such as sodium hydroxide, potassium hydroxide, sodium carbonate, sodium hydrogen carbonate, sodium silicate, and sodium metasilicate. In consideration of environmental aspects and safety aspects, the alkali agent is preferably a compound having a high molecular weight. The concentration of the alkali agent in the aqueous alkaline solution is preferably 0.001 to 10 mass % and more preferably 0.01 to 1 mass %. In addition, the developer may further contain a surfactant. Examples of the surfactant include the surfactants described above, and the surfactant is preferably a nonionic surfactant. From the viewpoint of transportation, storage, and the like, the developer may be first produced as a concentrated solution and then diluted to a concentration required upon the use. The dilution ratio is not particularly limited, and can be set to, for example, a range of 1.5 to 100 times. In addition, it is also preferable to wash (rinse) with pure water after development. In addition, it is preferable that the rinsing is performed by supplying a rinsing liquid to the curable composition layer after development while rotating the support on which the curable composition layer after development is formed. In addition, it is preferable that the rinsing is performed by moving a nozzle discharging the rinsing liquid from a center of the support to a peripheral edge of the support. In this case, in the movement of the nozzle from the center of the support to the peripheral edge of the support, the nozzle may be moved while gradually decreasing the moving speed of the nozzle. By performing rinsing in this manner, in-plane variation of rinsing can be suppressed. In addition, the same effect can be obtained by gradually decreasing the rotating speed of the support while moving the nozzle from the center of the support to the peripheral edge of the support.

After the development, it is preferable to carry out an additional exposure treatment or a heating treatment (post-baking) after carrying out drying. The additional exposure treatment or the post-baking is a curing treatment after development in order to complete curing. The heating temperature in the post-baking is preferably, for example, 100° C. to 240° C. and more preferably 200° C. to 240° C. The post-baking can be performed continuously or batchwise by using a heating unit such as a hot plate, a convection oven (hot-air circulation dryer), and a high-frequency heater so that the film after development satisfies the conditions. In a case of carrying out the additional exposure treatment, light used for the exposure is preferably light having a wavelength of 400 nm or less. In addition, the additional exposure treatment may be carried out by the method described in KR2017-0122130A.

—Dry Etching Method—

Next, a case of forming a pattern by a dry etching method to manufacture a color filter will be described. Pattern formation by a dry etching method preferably includes a step of forming a curable composition layer on a support using the curable composition according to the embodiment of the present disclosure and curing the entire curable composition layer to form a cured composition layer, a step of forming a photoresist layer on the cured composition layer, a step of exposing the photoresist layer in a patterned manner and then developing the photoresist layer to form a resist pattern, and a step of dry-etching the cured composition layer through this resist pattern as a mask and using an etching gas. It is preferable that pre-baking treatment is further performed in order to form the photoresist layer. In particular, as the forming process of the photoresist layer, it is desirable that a heating treatment after exposure and a heating treatment after development (post-baking treatment) are performed. The details of the pattern formation by the dry etching method can be found in paragraphs 0010 to 0067 of JP2013-064993A, the content of which is incorporated herein by reference.

<Solid-State Imaging Element>

It is preferable that the solid-state imaging element according to the embodiment of the present disclosure includes the cured product according to the embodiment of the present disclosure and has the color filter according to the embodiment of the present disclosure.

Examples of a preferred aspect of the solid-state imaging element according to the embodiment of the present disclosure include an aspect in which at least one pixel selected from the group consisting of a red pixel, a green pixel, and a blue pixel is the cured product according to the embodiment of the present disclosure (RGB pixels).

In addition, examples of another preferred aspect of the solid-state imaging element according to the embodiment of the present disclosure include an aspect in which at least one pixel selected from the group consisting of a cyan pixel, a yellow pixel, and a magenta pixel is the cured product according to the embodiment of the present disclosure (CMY pixels).

The configuration of the solid-state imaging element according to the embodiment of the present disclosure is not particularly limited as long as the solid-state imaging element is configured to include the cured product according to the embodiment of the present disclosure and functions as a solid-state imaging element. Examples of the configuration include the following configurations.

The solid-state imaging element is configured to have a plurality of photodiodes constituting a light receiving area of the solid-state imaging element (a charge coupled device (CCD) image sensor, a complementary metal-oxide semiconductor (CMOS) image sensor, or the like), and a transfer electrode formed of polysilicon or the like on a substrate; have a light-shielding film having openings only over the light receiving section of the photodiodes on the photodiodes and the transfer electrodes; have a device-protective film formed of silicon nitride or the like, which is formed to coat the entire surface of the light-shielding film and the light receiving section of the photodiodes, on the light-shielding film; and have a color filter on the device-protective film. Further, the solid-state imaging element may also be configured, for example, such that it has a light collecting unit (for example, a microlens, which is the same hereinafter) on a device-protective film under a color filter (a side closer to the substrate), or has a light collecting unit on a color filter. In addition, the color filter may have a structure in which each colored pixel is embedded in a space partitioned in, for example, a lattice shape by a partition wall. The partition wall in this case preferably has a low refractive index for each colored pixel. Examples of an imaging device having such a structure include the devices described in JP2012-227478A, JP2014-179577A, and WO2018/043654A. An imaging device including the solid-state imaging element according to the embodiment of the present disclosure can also be used as a vehicle camera or a surveillance camera, in addition to a digital camera or electronic apparatus (mobile phones or the like) having an imaging function.

(Image Display Device)

It is preferable that the image display device according to the embodiment of the present disclosure includes the cured product according to the embodiment of the present disclosure and has the color filter according to the embodiment of the present disclosure. Examples of the image display device include a liquid crystal display device or an organic electroluminescent display device. The definitions of image display devices or the details of the respective image display devices are described in, for example, “Electronic Display Device (Akio Sasaki, Kogyo Chosakai Publishing Co., Ltd., published in 1990)”, “Display Device (Sumiaki Ibuki, Sangyo Tosho Co., Ltd.)”, and the like. In addition, the liquid crystal display device is described in, for example, “Liquid Crystal Display Technology for Next Generation (edited by Tatsuo Uchida, Kogyo Chosakai Publishing Co., Ltd., published in 1994)”. The liquid crystal display device is not particularly limited, and examples thereof include various liquid crystal display devices described in “Next-Generation Liquid Crystal Display Techniques”.

### EXAMPLES

Hereinafter, the present disclosure will be described in detail with reference to examples, but the present disclosure is not limited thereto.

In the examples, “%” and “parts” respectively indicate “mass %” and “parts by mass” unless otherwise specified. In a polymer compound, the molecular weight indicates the weight-average molecular weight (Mw) and the proportion of constitutional units indicates mole percentage unless otherwise specified.

—Measuring Method of Weight-Average Molecular Weight—

The weight-average molecular weight (Mw) of each macromonomer and resin was calculated by Gel permeation chromatography (GPC) measurement under the following measurement conditions.

Column type: following 3 columns are directly connected in series (all manufactured by Tosoh Corporation)

TOSOH TSKgel Super HZM-H 6.0 mm×150 mm

TOSOH TSKgel Super HZ4000 6.0 mm×150 mm

TOSOH TSKgel Super HZ2000 6.0 mm×150 mm

Developing solvent: tetrahydrofuran

Column temperature: 40° C.

Flow rate (amount of a sample to be injected): 1.0 μL (sample concentration: 0.1 mass %)

Device name: HLC-8220GPC manufactured by Tosoh Corporation

Detector: refractive index (RI) detector

Calibration curve base resin: polystyrene resin

—Measuring Method of Acid Value—

The acid value of each dispersed resin represents a mass of potassium hydroxide required to neutralize acidic components per 1 g of solid content of a sample. Specifically, the obtained resin was dissolved in a mixed solvent of tetrahydrofuran/water=9/1 (mass ratio), and the obtained solution was subjected to neutralization titration with a 0.1 mol/L sodium hydroxide aqueous solution at 25° C. using a potentiometric titrator (trade name: AT-510, manufactured by KYOTO ELECTRONICS MANUFACTURING CO., LTD.). An inflection point of a titration pH curve was set as a titration end point, and the acid value was calculated from the following equation.

A=56.11×Vs×0.5×f/w

A: acid value (mgKOH/g)

Vs: amount (mL) of the 0.1 mol/L sodium hydroxide aqueous solution used for the titration

f: titer of the 0.1 mol/L sodium hydroxide aqueous solution

w: mass (g) of the measurement sample (expressed in terms of solid contents)

—Synthesis of macromonomer R1—

449 parts by mass of propylene glycol monomethyl ether acetate (PGMEA) was charged into a three-neck flask, and the mixture was heated to 75° C. while flowing nitrogen into the flask. Separately, a dropping solution in which 261 parts by mass of methyl methacrylate and 261 parts by mass of butyl acrylate as monomers forming P¹ shown in Table 1, 38.9 parts by mass of 6-mercapto-1-hexanol as an S-introducing compound shown in Table 1, 2.93 parts by mass of 2,2′-azobis(methyl 2-methylpropionate) (trade name: “V-601”, manufactured by FUJIFILM Wako Pure Chemical Corporation), and 257 parts by mass of PGMEA were mixed was prepared. This dropping solution was added dropwise to the mixture over 2 hours. After dropwise addition, the mixture was further heated and stirred at the same temperature for 1 hour. After further adding 2.93 parts by mass of V-601, the mixture was heated at the same temperature for 2 hours. 2.93 parts by mass of V-601 was further added thereto, the temperature was increased to 90° C. and the mixture was heated for 3 hours, and then the polymerization reaction was terminated.

Next, 46.3 parts by mass of 2-isocyanatoethyl methacrylate (product name: Karenz MOI, manufactured by SHOWA DENKO K.K.) as an introduction compound shown in Table 1, 2.46 parts by mass of bismuth tris(2-ethylhexanoate) (product name: NEOSTANN U-600, manufactured by NITTO KASEI CO., LTD.), and 0.185 parts by mass of dibutylhydroxytoluene (BHT) were added to the obtained polymerization reaction product, the mixture was heated at 750 for 4 hours, and then after confirming by NMR that the MOI peak had disappeared, the reaction was terminated.

With regard to the obtained compound, it was confirmed by GPC measurement that Mw=3,200.

—Synthesis of Macromonomers R2 to R4, R6, R9 to R15, R19 to R33, R50 to R54, and R57 to R67—

Each macromonomer was synthesized in the same manner as in the macromonomer R1, except that, in the synthesis of the macromonomer R1, methyl methacrylate and butyl acrylate were changed to monomers forming P¹ shown in Table 1 or Table 2, 6-mercapto-1-hexanol was changed to an S-introducing compound shown in Table 1 or Table 2, and 2-isocyanatoethyl methacrylate was changed to an introduction compound shown in Table 1 or Table 2.

Each of the macromonomer R1 and the like synthesized above is the same compound as R1 and the like described above as an exemplary compound of the polymer compound represented by Formula (1a).

TABLE 1

| | | | S-introducing | Introduction | | L | | |
|---|---|---|---|---|---|---|---|---|
| Macromonomer | Monomer forming P¹ | | compound | compound | X¹ | L¹ | L² | Z¹ |
| R1 | Methyl | Butyl | 6-mercapto- | MOI | —C6— | Urethane | —C2— | Methacryloxy |
| | methacrylate | acrylate | 1-hexanol | | | | | group |
| R2 | Methyl | Butyl | 3-mercapto-3- | MOI | —C3— | Urethane | —C2— | Methacryloxy |
| | methacrylate | acrylate | methyl-1- | | | | | group |
| | | | butanol | | | | | |
| R3 | Methyl | Butyl | 4-mercapto- | MOI | —C4— | Urethane | —C2— | Methacryloxy |
| | methacrylate | acrylate | 1-butanol | | | | | group |
| R4 | Methyl | Butyl | 5-mercapto- | MOI | —C5— | Urethane | —C2— | Methacryloxy |
| | methacrylate | acrylate | 1-heptanol | | | | | group |
| R6 | Methyl | Butyl | 8-mercapto- | MOI | —C8— | Urethane | —C2— | Methacryloxy |
| | methacrylate | acrylate | 1-octanol | | | | | group |
| R9 | Methyl | Butyl | 20-mercapto- | MOI | —C20— | Urethane | —C2— | Methacryloxy |
| | methacrylate | acrylate | 1-eicosanol | | | | | group |
| R10 | Methyl | Butyl | 6-mercapto- | Conversion | —C6— | Urea | —C2— | Methacryloxy |
| | methacrylate | acrylate | 1-hexanol | into | | | | group |
| | | | | NH₂ | | | | |
| | | | | group → MOI | | | | |
| R11 | Methyl | Butyl | 6-mercapto- | 3-chloro- | —C6— | Ester | —C2— | Methacryloxy |
| | methacrylate | acrylate | 1-hexanol | 3-oxopropyl | | | | group |
| | | | | methacrylate | | | | |
| R12 | Methyl | Butyl | 6-mercapto- | 3-chloro-3- | —C6— | Amide | —C2— | Methacryloxy |
| | methacrylate | acrylate | 1-hexanol | oxopropyl | | | | group |
| | | | | methacrylate | | | | |
| R13 | Methyl | Butyl | 6-mercapto- | 2-bromoethyl | —C6— | Ether | —C2— | Methacryloxy |
| | methacrylate | acrylate | 1-hexanol | methacrylate | | | | group |
| R14 | Methyl | Butyl | 6-mercapto- | MOI-EG | —C6— | Urethane | —C2—O—C2— | Methacryloxy |
| | methacrylate | acrylate | 1-hexanol | | | | | group |
| R15 | Methyl | Butyl | 6-mercapto- | AO1 | —C6— | Urethane | —C2— | Acryloxy |
| | methacrylate | acrylate | 1-hexanol | | | | | group |
| R17 | Methyl | Butyl | 5-mercapto-1,2- | None | —C3— | None (single bond) | | Group having |
| | methacrylate | acrylate | heptanediol | | | | | diol structure |
| R18 | Methyl | Butyl | 2-(3- | None | —C3— | None (single bond) | | Group having |
| | methacrylate | acrylate | mercapto- | | | | | diol structure |
| | | | propyl)- | | | | | |
| | | | 1,3-propanediol | | | | | |
| R19 | Ethyl | | 6-mercapto- | MOI | —C6— | Urethane | —C2— | Methacryloxy |
| | methacrylate | | 1-hexanol | | | | | group |
| R20 | Ethyl | Butyl | 6-mercapto- | MOI | —C6— | Urethane | —C2— | Methacryloxy |
| | methacrylate | acrylate | 1-hexanol | | | | | group |
| R21 | Methyl | HEMA | 6-mercapto- | MOI | —C6— | Urethane | —C2— | Methacryloxy |
| | methacrylate | | 1-hexanol | | | | | group |
| R22 | Methyl | Methacrylic | 6-mercapto- | MOI | —C6— | Urethane | —C2— | Methacryloxy |
| | methacrylate | acid | 1-hexanol | | | | | group |
| R23 | Methyl | Butyl | 6-mercapto- | Methacryloyl | —C6— | None | None | Methacryloxy |
| | methacrylate | acrylate | 1-hexanol | chloride | | | | group |
| R24 | Methyl | Butyl | 6-mercapto- | Acryloyl | —C6— | None | None | Acryloxy |
| | methacrylate | acrylate | 1-hexanol | chloride | | | | group |
| R25 | Methyl | Butyl | 6-mercapto- | GMA | —C6— | Ether | —C1—C(OH)—C1— | Methacryloxy |
| | methacrylate | acrylate | 1-hexanol | | | | | group |
| R26 | Methyl | Butyl | 6-mercapto- | GA | —C6— | Ether | —C1—C(OH)—C1— | Acryloxy |
| | methacrylate | acrylate | 1-hexanol | | | | | group |
| R27 | Methyl | Butyl | 6-mercapto- | 4HBAGE | —C6— | Ether | —C1—C(OH)—C1—O—C4— | Acryloxy |
| | methacrylate | acrylate | 1-hexanol | | | | | group |
| R28 | Methyl methacrylate | Butyl acrylate | 6-mercapto- 1-hexanol | CYCLOMER M100 | —C6— | Ether | 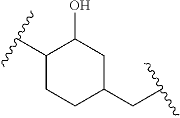 [SMILES: *CC1CCC(*)C(O)C1] | Methacryloxy group |

TABLE 2

| | | | S-introducing | Introduction | | L | | |
|---|---|---|---|---|---|---|---|---|
| Macromonomer | Monomer forming P¹ | | compound | compound | X¹ | L¹ | L² | Z¹ |
| R29 | Methyl methacrylate | Butyl acrylate | 6-mercapto- 1-hexanol | ((4-(bromomethyl) cyclohexyl)methyl methacrylate | —C6— | Ether | 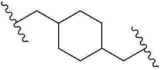 [SMILES: *CC1CCC(C*)CC1] | Acryloxy group |
| R30 | Methyl | Butyl | 6-mercapto- | 2-methacryl | —C6— | Ether | —C1—COO—C2— | Acrylamide |
| | methacrylate | acrylate | 1-hexanol | amidoethyl | | | | group |
| | | | | 2-chloroacetate | | | | |
| R31 | Methyl | Butyl | 6-mercapto- | 4-(chloromethyl) | —C6— | Ether | —C1— | Styryl group |
| | methacrylate | acrylate | 1-hexanol | styrene | | | | |
| R32 | Methyl | Butyl | 6-mercapto- | 10-undecenoyl | —C6— | Ester | —C7— | Allyl group |
| | methacrylate | acrylate | 1-hexanol | chloride | | | | |
| R33 | Methyl | Butyl | 6-mercapto- | chloroacetic acid | —C6— | Ether | —C1— | Vinyl ester |
| | methacrylate | acrylate | 1-hexanol | vinyl acetate | | | | group |
| R50 | Methyl | Butyl | 3-mercapto- | MOI | —C3— | Urethane | —C2— | Methacryloxy |
| | methacrylate | acrylate | 1-propanol | | | | | group |
| R51 | Methyl | Butyl | 3-mercapto- | MOI | —C3— | Urethane | —C2— | Methacryloxy |
| | methacrylate | acrylate | 1-hexanol | | | | | group |
| R52 | Methyl | Butyl | 4-mercapto- | MOI | —C3— | Urethane | —C2— | Methacryloxy |
| | methacrylate | acrylate | 4-methyl-1- | | | | | group |
| | | | pentanol | | | | | |
| R53 | Methyl | Butyl | 9-hydroxy- | MOI | —C9— | Urethane | —C2— | Methacryloxy |
| | methacrylate | acrylate | nonanol | | | | | group |
| R54 | Methyl | Butyl | 11-hydroxy- | MOI | —C11— | Urethane | —C2— | Methacryloxy |
| | methacrylate | acrylate | 1-undecanol | | | | | group |
| R55 | Methyl | Butyl | 5-mercapto- | Conversion | —C3— | None (single bond) | | Group having |
| | methacrylate | acrylate | 1,2-heptane | into | | | | diamine |
| | | | diol | NH₂ group | | | | structure |
| R56 | Methyl | Butyl | 2-(3- | Conversion | —C3— | None (single bond) | | Group having |
| | methacrylate | acrylate | mercapto- | into | | | | diamine |
| | | | propyl)-1,3- | NH₂ group | | | | structure |
| | | | propanediol | | | | | |
| R57 | Methyl | Butyl | 6-mercapto- | MOI | —C6— | Urethane | —C2— | Methacryloxy |
| | methacrylate | acrylate | 1-hexanol | | | | | group |
| R58 | Methyl | Benzyl | 6-mercapto- | MO1 | —C6— | Urethane | —C2— | Methacryloxy |
| | methacrylate | methacrylate | 1-hexanol | | | | | group |
| R59 | Methyl | Lauryl | 6-mercapto- | MO1 | —C6— | Urethane | —C2— | Methacryloxy |
| | methacrylate | methacrylate | 1-hexanol | | | | | group |
| R60 | Methyl | HPMA | 6-mercapto- | MO1 | —C6— | Urethane | —C2— | Methacryloxy |
| | methacrylate | | 1-hexanol | | | | | group |
| R61 | Methyl | Dipropylene | 6-mercapto- | MOI | —C6— | Urethane | —C2— | Methacryloxy |
| | methacrylate | glycol | 1-hexanol | | | | | group |
| | | acrylate | | | | | | |
| R62 | Butyl | Butyl | 6-mercapto- | MOI | —C6— | Urethane | —C2— | Methacryloxy |
| | acrylate | methacrylate | 1-hexanol | | | | | group |
| R63 | Butyl | Benzyl | 6-mercapto- | MOI | —C6— | Urethane | —C2— | Methacryloxy |
| | acrylate | methacrylate | 1-hexanol | | | | | group |
| R64 | Butyl | Lauryl | 6-mercapto- | MOI | —C6— | Urethane | —C2— | Methacryloxy |
| | acrylate | methacrylate | 1-hexanol | | | | | group |
| R65 | Butyl | HPMA | 6-mercapto- | MOI | —C6— | Urethane | —C2— | Methacryloxy |
| | acrylate | | 1-hexanol | | | | | group |
| R66 | Butyl | Dipropylene | 6-mercapto- | MOI | —C6— | Urethane | —C2— | Methacryloxy |
| | acrylate | glycol | 1-hexanol | | | | | group |
| | | acrylate | | | | | | |
| R67 | Butyl | Benzyl | 6-mercapto- | MO1 | —C6— | Urethane | —C2— | Methacryloxy |
| | methacrylate | methacrylate | 1-hexanol | | | | | group |
| R101 | Butyl | Benzyl | 3-mercapto- | None | —C1— | None (single bond) | | Group having |
| | methacrylate | methacrylate | 1,2-propane | | | | | diol structure |
| | | | diol | | | | | |

“Conversion into NIH₂ group→MOI” shown in Tables 1 and 2 means that a hydroxy group was converted into a leaving group (a halogen group, a mesyl group, a tosyl group, or the like), further treated with ammonia water to convert the hydroxy group into an NH₂ group, and then reacted with MOI, and “Conversion into NH₂ group” means that a hydroxy group was converted into a leaving group (a halogen group, a mesyl group, a tosyl group, or the like) and further treated with ammonia water to convert the hydroxy group into an NH₂ group. In Tables 1 and 2, a wavy line represents a bonding site with other configurations.

Abbreviations and details shown in Tables 1 and 2 are as follows.
MOI: 2-isocyanatoethyl methacrylate (product name: Karenz MOI, manufactured by SHOWA DENKO K.K.)
2-Bromoethyl methacrylate (manufactured by TOKYO CHEMICAL INDUSTRY CO., LTD.)
HEMA: 2-hydroxyethyl methacrylate, manufactured by TOKYO CHEMICAL INDUSTRY CO., LTD.
MOI-EG: methacryloyloxyethoxyethyl isocyanate, manufactured by SHOWA DENKO K.K.
AOI: 2-isocyanatoethyl acrylate, manufactured by SHOWA DENKO K.K.
Methacryloyl chloride (manufactured by TOKYO CHEMICAL INDUSTRY CO., LTD.)
Acryloyl chloride (manufactured by TOKYO CHEMICAL INDUSTRY CO., LTD.)
GMA: glycidyl methacrylate (manufactured by TOKYO CHEMICAL INDUSTRY CO., LTD.)
GA: glycidyl acrylate (manufactured by TOKYO CHEMICAL INDUSTRY CO., LTD.)
4HBAGE: 4-hydroxybutyl acrylate glycidyl ether (manufactured by Mitsubishi Chemical Corporation)
CYCLOMER M100: 3,4-epoxycyclohexylmethyl methacrylate (manufactured by Daicel Corporation)
N-(hydroxymethyl) acrylamide (manufactured by TOKYO CHEMICAL INDUSTRY CO., LTD.)
4-(Chloromethyl)styrene (manufactured by TOKYO CHEMICAL INDUSTRY CO., LTD.)
10-Undecenoyl chloride (manufactured by TOKYO CHEMICAL INDUSTRY CO., LTD.)
Vinyl chloroacetate (manufactured by TOKYO CHEMICAL INDUSTRY CO., LTD.)

<Synthesis of Dispersed Resin>

—Synthesis of Dispersed Resin P1—

375 parts by mass of a 40 mass % PGMEA solution of the macromonomer R1 synthesized above, 30 parts by mass of methacrylic acid, 120 parts by mass of benzyl methacrylate, and 455 parts by mass of PGMEA were charged into a three-neck flask, the temperature of the mixture was increased to 75° C. while flowing nitrogen into the flask. 8.26 parts by mass of dodecyl mercaptan and 1.57 parts by mass of V-601 were further added thereto, and the mixture was heated at the same temperature for 2 hours. After further adding 1.57 parts by mass of V-601, the mixture was heated at the same temperature for 2 hours. 1.57 parts by mass of V-601 was further added thereto, the temperature was increased to 90° C., the mixture was heated for 3 hours, and the polymerization reaction was terminated to synthesize a resin, thereby obtaining a dispersed resin P1 (30 mass % PGMEA solution). The weight-average molecular weight of the obtained dispersed resin P1 was 18,000, and the acid value was 64 mgKOH/g.

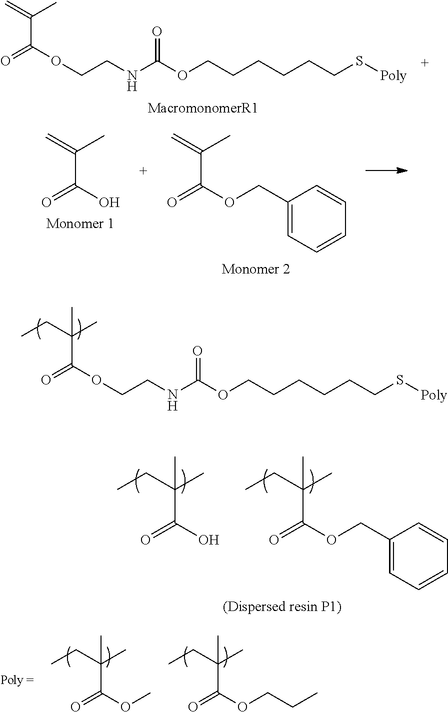

—Synthesis of Dispersed Resins P2 to P4, P6, P9 to P15, P19 to P33, P50 to P54, and P57 to P79—

Dispersed resins P2 to p4, P6, P9 to P15, P19 to P33, P50 to P54, and P57 to P79 were synthesized in the same manner as in the dispersed resin P1, except that, in the synthesis of the dispersed resin P1, the macromonomers and monomers 1 and 2 were changed as shown in Table 3 or Table 4.

—Synthesis of Dispersed Resin P17—

100 parts by mass of methyl methacrylate and 100 parts by mass of n-butyl acrylate were charged into a reaction container, and the atmosphere gas was replaced with nitrogen gas. The inside of the reaction container was heated to 80° C., 15.1 parts by mass of 5-mercapto-1,2-heptanediol was added thereto, and the mixture was reacted for 12 hours to obtain a macromonomer R17. It was confirmed by solid content measurement that 95% thereof was reacted. Next, 12 parts by mass of pyromellitic acid anhydride, 224 parts by mass of PGMEA, and 0.40 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated to synthesize a dispersed resin P17. PGMEA was added to the obtained P17 to adjust the concentration of solid contents to be 30 mass %.

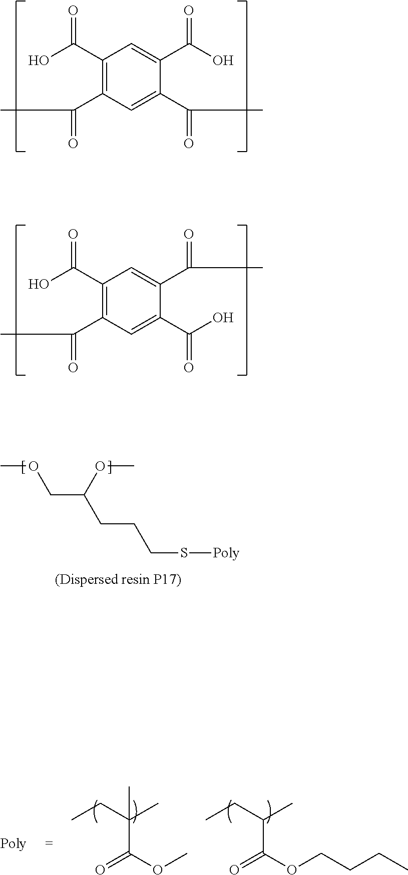

—Synthesis of Dispersed Resin P18—

The synthesis was carried out in the same manner as the method for synthesizing the dispersed resin P17, except that, in the synthesis of the dispersed resin P17, 5-mercapto-1,2-heptanediol was changed to 2-(3-mercaptopropyl)-1,3-propanediol to obtain a macromonomer R18.

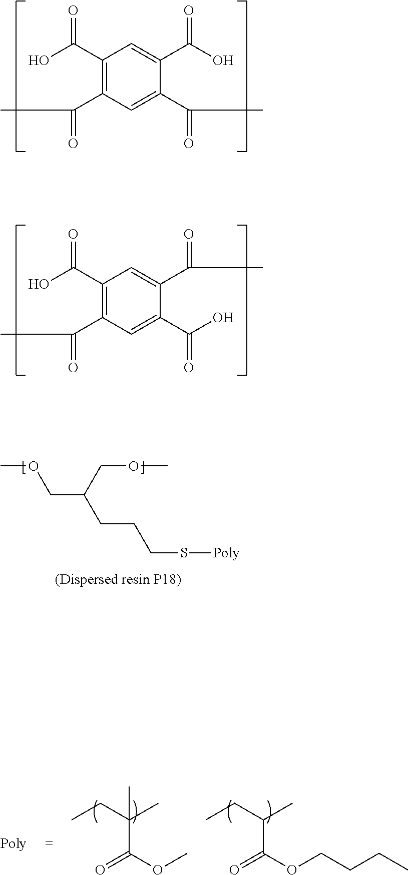

—Synthesis of Dispersed Resin P55—

100 parts by mass of methyl methacrylate and 100 parts by mass of n-butyl acrylate were charged into a reaction container, and the atmosphere gas was replaced with nitrogen gas. The inside of the reaction container was heated to 80° C., 15.1 parts by mass of 5-mercapto-1,2-heptanediol was added thereto, and the mixture was reacted for 12 hours to obtain a precursor of a macromonomer R55. It was confirmed by solid content measurement that 95% thereof was reacted.

Next, 11.8 parts by mass of triethylamine and 13.33 parts by mass of mesyl chloride were added thereto, and the mixture was heated at 80° C. for 8 hours. 800 parts by mass of ammonia water (28 mass %) was further added thereto, and the mixture was heated at 80° C. for 24 hours to obtain a macromonomer R55.

Next, 12 parts by mass of pyromellitic acid anhydride, 224 parts by mass of PGMEA, and 0.40 parts by mass of 1,8-diazabicyclo-[5.4.0]-7-undecene (DBU) as a catalyst were added thereto, and the mixture was reacted at 120° C. for 7 hours. It was confirmed by acid value measurement that 98% or more of the acid anhydride was half-esterified, and the reaction was terminated to synthesize a dispersed resin P55. PGMEA was added to the obtained dispersed resin P55 to adjust the concentration of solid contents to be 30 mass %.

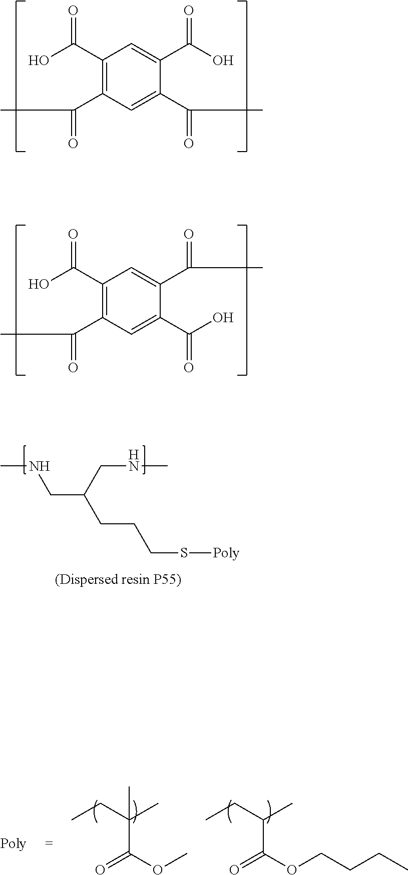

—Synthesis of Dispersed Resin P56—

The synthesis was carried out in the same manner as the method for synthesizing the dispersed resin P55, except that, in the synthesis of the dispersed resin P55, 5-mercapto-1,2-heptanediol was changed to 2-(3-mercaptopropyl)-1,3-propanediol to obtain a macromonomer R56.

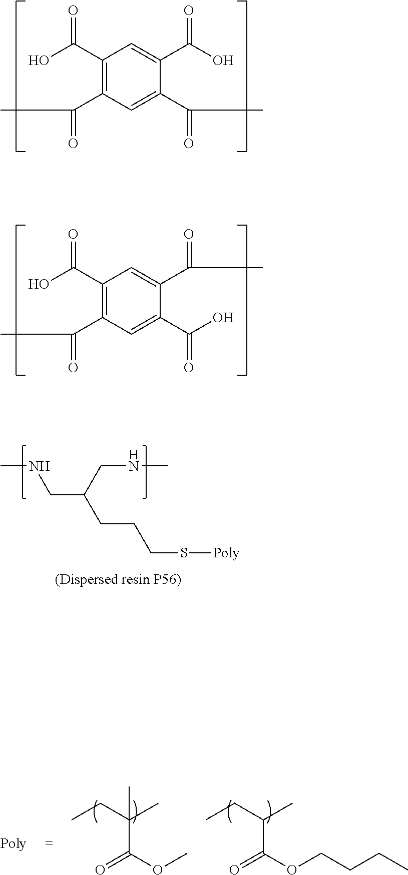

—Synthesis of Dispersed Resin P101—

100 parts by mass of n-butyl methacrylate and 100 parts by mass of benzyl methacrylate were charged into a reaction container equipped with gas inlet pipe, thermometer, condenser, and stirrer, and the atmosphere gas was replaced with nitrogen gas. The inside of the reaction container was heated to 80° C., 12 parts by mass of 3-mercapto-1,2-propanediol was added thereto, and the mixture was reacted for 12 hours to obtain a macromonomer R101. It was confirmed by solid content measurement that 95% thereof was reacted. Next, 12 parts by mass of pyromellitic acid anhydride, 224 parts by mass of cyclohexanone, and 0.40 parts by mass of 1,8-diazabicyclo-[5.4.0]-7-undecene as a catalyst were added thereto, and the mixture was reacted at 120° C. for 7 hours. It was confirmed by acid value measurement that 98% or more of the acid anhydride was half-esterified, and the reaction was terminated to obtain a dispersed resin P101 having an acid value of 28 mgKOH/g and a weight-average molecular weight (Mw) of 5,800. PGMEA was added to the obtained dispersed resin P101 to adjust non-volatile content (concentration of solid contents) to be 20 mass %, thereby obtaining a solution of the dispersed resin P101.

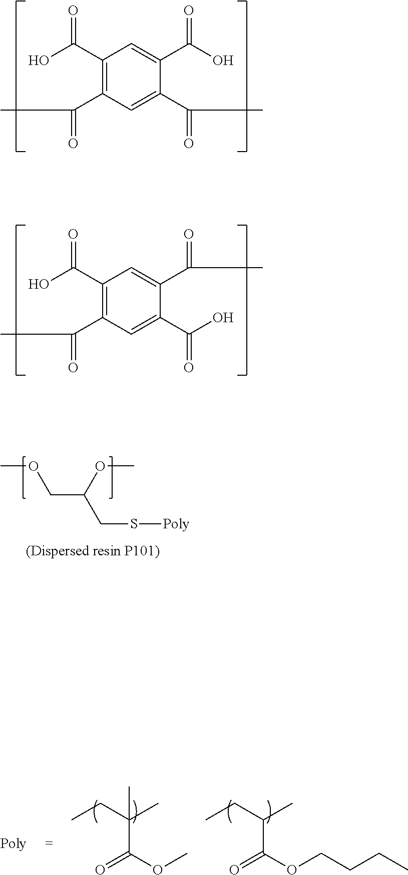

TABLE 3

| | Polymer composition and structure | | | | | | Physical characteristics of dispersed | |
|---|---|---|---|---|---|---|---|---|
| Dispersed | Macromonomer | | Monomer 1 | | Monomer 2 | | resin | |
| resin | Type | Mass ratio | Type | Mass ratio | Type | Mass ratio | Acid value (mgKOH/g) | Mw |
| P1 | R1 | 50 | Methacrylic acid | 10 | Benzyl methacrylate | 40 | 64 | 18,000 |
| P2 | R2 | 50 | Methacrylic acid | 10 | Benzyl methacrylate | 40 | 64 | 18,000 |
| P3 | R3 | 50 | Methacrylic acid | 10 | Benzyl methacrylate | 40 | 64 | 18,000 |
| P4 | R4 | 50 | Methacrylic acid | 10 | Benzyl methacrylate | 40 | 64 | 18,000 |
| P6 | R6 | 50 | Methacrylic acid | 10 | Benzyl methacrylate | 40 | 64 | 18,000 |
| P9 | R9 | 50 | Methacrylic acid | 10 | Benzyl methacrylate | 40 | 64 | 18,000 |
| P10 | R10 | 50 | Methacrylic acid | 10 | Benzyl methacrylate | 40 | 64 | 18,000 |
| P11 | R11 | 50 | Methacrylic acid | 10 | Benzyl methacrylate | 40 | 64 | 18,000 |
| P12 | R12 | 50 | Methacrylic acid | 10 | Benzyl methacrylate | 40 | 64 | 18,000 |
| P13 | R13 | 50 | Methacrylic acid | 10 | Benzyl methacrylate | 40 | 64 | 18,000 |
| P14 | R14 | 50 | Methacrylic acid | 10 | Benzyl methacrylate | 40 | 64 | 18,000 |
| P15 | R15 | 50 | Methacrylic acid | 10 | Benzyl methacrylate | 40 | 64 | 18,000 |
| P19 | R19 | 50 | Methacrylic acid | 10 | Benzyl methacrylate | 40 | 64 | 18,000 |
| P20 | R20 | 50 | Methacrylic acid | 10 | Benzyl methacrylate | 40 | 64 | 18,000 |
| P21 | R21 | 50 | Methacrylic acid | 10 | Benzyl methacrylate | 40 | 64 | 18,000 |
| P22 | R22 | 50 | Methacrylic acid | 10 | Benzyl methacrylate | 40 | 64 | 18,000 |
| P23 | R23 | 50 | Methacrylic acid | 10 | Benzyl methacrylate | 40 | 64 | 18,000 |
| P24 | R24 | 50 | Methacrylic acid | 10 | Benzyl methacrylate | 40 | 64 | 18,000 |
| P25 | R25 | 50 | Methacrylic acid | 10 | Benzyl methacrylate | 40 | 64 | 18,000 |
| P26 | R26 | 50 | Methacrylic acid | 10 | Benzyl methacrylate | 40 | 64 | 18,000 |
| P27 | R27 | 50 | Methacrylic acid | 10 | Benzyl methacrylate | 40 | 64 | 18,000 |
| P28 | R28 | 50 | Methacrylic acid | 10 | Benzyl methacrylate | 40 | 64 | 18,000 |
| P29 | R29 | 50 | Methacrylic acid | 10 | Benzyl methacrylate | 40 | 64 | 18,000 |
| P30 | R30 | 50 | Methacrylic acid | 10 | Benzyl methacrylate | 40 | 64 | 18,000 |

TABLE 4

| | Polymer composition and structure | | | | | | Physical characteristics of dispersed | |
|---|---|---|---|---|---|---|---|---|
| | Macromonomer | | | | | | resin | |
| Dispersed | | Mass | Monomer 1 | | Monomer 2 | | Acid value | |
| resin | Type | ratio | Type | Mass ratio | Type | Mass ratio | (mgKOH/g) | Mw |
| P31 | R31 | 50 | Methacrylic acid | 10 | Benzyl methacrylate | 40 | 64 | 18,000 |
| P32 | R32 | 50 | Methacrylic acid | 10 | Benzyl methacrylate | 40 | 64 | 18,000 |
| P33 | R33 | 50 | Methacrylic acid | 10 | Benzyl methacrylate | 40 | 64 | 18,000 |
| P34 | R1 | 50 | Methacrylic acid | 10 | Benzyl methacrylate | 40 | 64 | 10,000 |
| P35 | R1 | 50 | Methacrylic acid | 10 | Benzyl methacrylate | 40 | 64 | 30,000 |
| P50 | R50 | 50 | Methacrylic acid | 10 | Benzyl methacrylate | 40 | 64 | 18,000 |
| P51 | R51 | 50 | Methacrylic acid | 10 | Benzyl methacrylate | 40 | 64 | 18,000 |
| P52 | R52 | 50 | Methacrylic acid | 10 | Benzyl methacrylate | 40 | 64 | 18,000 |
| P53 | R53 | 50 | Methacrylic acid | 10 | Benzyl methacrylate | 40 | 64 | 18,000 |
| P54 | R54 | 50 | Methacrylic acid | 10 | Benzyl methacrylate | 40 | 64 | 18,000 |
| P57 | R57 | 50 | Methacrylic acid | 10 | Benzyl methacrylate | 40 | 64 | 18,000 |
| P58 | R58 | 50 | Methacrylic acid | 10 | Benzyl methacrylate | 40 | 64 | 18,000 |
| P59 | R59 | 50 | Methacrylic acid | 10 | Benzyl methacrylate | 40 | 64 | 18,000 |
| P60 | R60 | 50 | Methacrylic acid | 10 | Benzyl methacrylate | 40 | 64 | 18,000 |
| P61 | R61 | 50 | Methacrylic acid | 10 | Benzyl methacrylate | 40 | 64 | 18,000 |
| P62 | R62 | 50 | Methacrylic acid | 10 | Benzyl methacrylate | 40 | 64 | 18,000 |
| P63 | R63 | 50 | Methacrylic acid | 10 | Benzyl methacrylate | 40 | 64 | 18,000 |
| P64 | R64 | 50 | Methacrylic acid | 10 | Benzyl methacrylate | 40 | 64 | 18,000 |
| P65 | R65 | 50 | Methacrylic acid | 10 | Benzyl methacrylate | 40 | 64 | 18,000 |
| P66 | R66 | 50 | Methacrylic acid | 10 | Benzyl methacrylate | 40 | 64 | 18,000 |
| P67 | R67 | 50 | Methacrylic acid | 10 | Benzyl methacrylate | 40 | 64 | 18,000 |
| P68 | R1 | 50 | Acrylic acid | 10 | Benzyl methacrylate | 40 | 76 | 18,000 |
| P69 | R1 | 50 | ARONIX M5300 | 20 | Benzyl methacrylate | 30 | 43 | 19,000 |
| P70 | R1 | 50 | 2-methacryloyloxyethyl | 20 | Benzyl methacrylate | 30 | 40 | 19,000 |
| | | | phthalic acid | | | | | |
| P71 | R1 | 50 | BBA-AE | 20 | Benzyl methacrylate | 30 | 42 | 19,000 |
| P72 | R1 | 50 | Acrylic acid | 10 | Butyl methacrylate | 40 | 76 | 18,000 |
| P73 | R1 | 50 | ARONIX M5300 | 20 | Butyl methacrylate | 30 | 43 | 19,000 |
| P74 | R1 | 50 | 2-methacryloyloxyethyl | 20 | Butyl methacrylate | 30 | 40 | 19,000 |
| | | | Phthalic acid | | | | | |
| P75 | R1 | 50 | BBA-AE | 20 | Butyl methacrylate | 30 | 42 | 19,000 |
| P76 | R1 | 50 | Acrylic acid | 10 | (2-ethylhexyl) | 40 | 76 | 18,000 |
| | | | | | methacrylate | | | |
| P77 | R1 | 50 | ARONIX M5300 | 20 | (2-ethylhexyl) | 30 | 43 | 19,000 |
| | | | | | methacrylate | | | |
| P78 | R1 | 50 | 2-methacryloyloxyethyl | 20 | (2-ethylhexyl) | 30 | 40 | 19,000 |
| | | | phthalic acid | | methacrylate | | | |
| P79 | R1 | 50 | BBA-AE | 20 | (2-ethylhexyl) | 30 | 42 | 19,000 |
| | | | | | methacrylate | | | |

Abbreviations shown in Tables 3 and 4 are as follows.
ARONIX M5300: co-carboxy-polycaprolactone (n≈2) monoacrylate, manufactured by TOAGOSEI CO., LTD.
3-methacryloyloxyethyl phthalic acid: manufactured by Shin-Nakamura Chemical Co., Ltd.)
BBA-AE: 4-(4-(acryloyloxy)butoxy) benzoic acid

The acid value and weight-average molecular weight (Mw) of the dispersed resins P17, P18, P55, P56, and P101 were as follows.
P17: acid value=28 mgKOH/g, weight-average molecular weight (Mw)=5,800
P18: acid value=28 mgKOH/g, weight-average molecular weight (Mw)=5,800
P55: acid value=27 mgKOH/g, weight-average molecular weight (Mw)=5,800
P56: acid value=27 mgKOH/g, weight-average molecular weight (Mw)=5,800
P101: acid value=28 mgKOH/g, weight-average molecular weight (Mw)=5,800

<Preparation of Dispersion Liquid>

Raw materials described in Tables 5 and 6 below were mixed, and then 230 parts by mass of zirconia beads having a diameter of 0.3 mm were added thereto to perform a dispersion treatment for 5 hours using a paint shaker. The beads were separated by filtration, and a dispersion liquid was produced. The numerical values described in the following tables indicate parts by mass. Each value of the blending amounts of the resins (dispersants) is the value of the blending amount in the resin solution having a solid content of 20 mass %.

TABLE 5

| Pigment | | | Dispersion aid | | | | | | | |
|---|---|---|---|---|---|---|---|---|---|---|
| dispersion | Pigment | | | Part by | Dispersed resin | | Polymerization inhibitor | | Solvent | |
| liquid | Type | Part by mass | Type | mass | Type | Part by mass | Type | Part by mass | Type | Part by mass |
| G-1 | PG58 | 9.20 | B1 | 1.20 | P1 | 4.95 | Q1 | 0.01 | J1 | 82.34 |
| | PY185 | 2.30 | | | | | | | | |
| G-2 | PG58 | 9.20 | B1 | 1.20 | P2 | 4.95 | Q1 | 0.01 | J1 | 82.34 |
| | PY185 | 2.30 | | | | | | | | |
| G-3 | PG58 | 9.20 | B1 | 1.20 | P3 | 4.95 | Q1 | 0.01 | J1 | 82.34 |
| | PY185 | 2.30 | | | | | | | | |
| G-4 | PG58 | 9.20 | B1 | 1.20 | P4 | 4.95 | Q1 | 0.01 | J1 | 82.34 |
| | PY185 | 2.30 | | | | | | | | |
| G-5 | PG58 | 9.20 | B1 | 1.20 | P5 | 4.95 | Q1 | 0.01 | J1 | 82.34 |
| | PY185 | 2.30 | | | | | | | | |
| G-6 | PG58 | 9.20 | B1 | 1.20 | P6 | 4.95 | Q1 | 0.01 | J1 | 82.34 |
| | PY185 | 2.30 | | | | | | | | |
| G-7 | PG58 | 9.20 | B1 | 1.20 | P7 | 4.95 | Q1 | 0.01 | J1 | 82.34 |
| | PY185 | 2.30 | | | | | | | | |
| G-8 | PG58 | 9.20 | B1 | 1.20 | P8 | 4.95 | Q1 | 0.01 | J1 | 82.34 |
| | PY185 | 2.30 | | | | | | | | |
| G-9 | PG58 | 9.20 | B1 | 1.20 | P9 | 4.95 | Q1 | 0.01 | J1 | 82.34 |
| | PY185 | 2.30 | | | | | | | | |
| G-10 | PG58 | 9.20 | B1 | 1.20 | P10 | 4.95 | Q1 | 0.01 | J1 | 82.34 |
| | PY185 | 2.30 | | | | | | | | |
| G-11 | PG58 | 9.20 | B1 | 1.20 | P11 | 4.95 | Q1 | 0.01 | J1 | 82.34 |
| | PY185 | 2.30 | | | | | | | | |
| G-12 | PG58 | 9.20 | B1 | 1.20 | P12 | 4.95 | Q1 | 0.01 | J1 | 82.34 |
| | PY185 | 2.30 | | | | | | | | |
| G-13 | PG58 | 9.20 | B1 | 1.20 | P13 | 4.95 | Q1 | 0.01 | J1 | 82.34 |
| | PY185 | 2.30 | | | | | | | | |
| G-14 | PG58 | 9.20 | B1 | 1.20 | P14 | 4.95 | Q1 | 0.01 | J1 | 82.34 |
| | PY185 | 2.30 | | | | | | | | |
| G-15 | PG58 | 9.20 | B1 | 1.20 | P15 | 4.95 | Q1 | 0.01 | J1 | 82.34 |
| | PY185 | 2.30 | | | | | | | | |
| G-16 | PG58 | 9.20 | B1 | 1.20 | P16 | 4.95 | Q1 | 0.01 | J1 | 82.34 |
| | PY185 | 2.30 | | | | | | | | |
| G-17 | PG58 | 9.20 | B1 | 1.20 | P17 | 4.95 | Q1 | 0.01 | J1 | 82.34 |
| | PY185 | 2.30 | | | | | | | | |
| G-18 | PG58 | 9.20 | B1 | 1.20 | P18 | 4.95 | Q1 | 0.01 | J1 | 82.34 |
| | PY185 | 2.30 | | | | | | | | |
| G-19 | PG58 | 9.20 | B1 | 1.20 | P19 | 4.95 | Q1 | 0.01 | J1 | 82.34 |
| | PY185 | 2.30 | | | | | | | | |
| G-20 | PG58 | 9.20 | B1 | 1.20 | P20 | 4.95 | Q1 | 0.01 | J1 | 82.34 |
| | PY185 | 2.30 | | | | | | | | |
| G-21 | PG58 | 9.20 | B1 | 1.20 | P21 | 4.95 | Q1 | 0.01 | J1 | 82.34 |
| | PY185 | 2.30 | | | | | | | | |
| G-22 | PG58 | 9.20 | B1 | 1.20 | P22 | 4.95 | Q1 | 0.01 | J1 | 82.34 |
| | PY185 | 2.30 | | | | | | | | |
| G-23 | PG58 | 9.20 | B1 | 1.20 | P23 | 4.95 | Q1 | 0.01 | J1 | 82.34 |
| | PY185 | 2.30 | | | | | | | | |

TABLE 6

| Pigment | | | Dispersion aid | | | | | | | |
|---|---|---|---|---|---|---|---|---|---|---|
| dispersion | Pigment | | | Part by | Dispersed resin | | Polymerization inhibitor | | Solvent | |
| liquid | Type | Part by mass | Type | mass | Type | Part by mass | Type | Part by mass | Type | Part by mass |
| G-24 | PG58 | 9.20 | B1 | 1.20 | P24 | 4.95 | Q1 | 0.01 | J1 | 82.34 |
| | PY185 | 2.30 | | | | | | | | |
| G-25 | PG58 | 9.20 | B1 | 1.20 | P25 | 4.95 | Q1 | 0.01 | J1 | 82.34 |
| | PY185 | 2.30 | | | | | | | | |
| G-26 | PG58 | 9.20 | B1 | 1.20 | P26 | 4.95 | Q1 | 0.01 | J1 | 82.34 |
| | PY185 | 2.30 | | | | | | | | |
| G-27 | PG58 | 9.20 | B1 | 1.20 | P27 | 4.95 | Q1 | 0.01 | J1 | 82.34 |
| | PY185 | 2.30 | | | | | | | | |
| G-28 | PG58 | 9.20 | B1 | 1.20 | P28 | 4.95 | Q1 | 0.01 | J1 | 82.34 |
| | PY185 | 2.30 | | | | | | | | |
| G-29 | PG58 | 9.20 | B1 | 1.20 | P29 | 4.95 | Q1 | 0.01 | J1 | 82.34 |
| | PY185 | 2.30 | | | | | | | | |
| G-30 | PG58 | 9.20 | B1 | 1.20 | P30 | 4.95 | Q1 | 0.01 | J1 | 82.34 |
| G-31 | PG58 | 9.20 | B1 | 1.20 | P31 | 4.95 | Q1 | 0.01 | J1 | 82.34 |
| G-32 | PG58 | 9.20 | B1 | 1.20 | P32 | 4.95 | Q1 | 0.01 | J1 | 82.34 |
| G-33 | PG58 | 9.20 | B1 | 1.20 | P33 | 4.95 | Q1 | 0.01 | J1 | 82.34 |
| G-34 | PG58 | 9.20 | B1 | 1.20 | P34 | 4.95 | Q1 | 0.01 | J! | 82.34 |
| G-35 | PG58 | 9.20 | B1 | 1.20 | P35 | 4.95 | Q1 | 0.01 | Jl | 82.34 |
| G-36 | PG58 | 9.20 | B1 | 1.20 | P1/ | 4.95 | Q1 | 0.01 | J1 | 82.34 |
| | PY185 | 2.30 | | | P2 = 1/1 | | | | | |
| G-101 | PG36 | 12.10 | B1 | 1.20 | P1 | 4.95 | Q1 | 0.01 | J1 | 79.24 |
| | PY150 | 1.80 | | | | | | | | |
| | PY185 | 0.70 | | | | | | | | |
| G-102 | PG58 | 6.20 | B1 | 1.20 | P1 | 4.95 | Q1 | 0.01 | J1 | 82.34 |
| | PG36 | 3.00 | | | | | | | | |
| | PY185 | 2.30 | | | | | | | | |
| CG-1 | PG58 | 9.20 | B1 | 1.20 | P101 | 4.95 | Q1 | 0.01 | J1 | 82.34 |
| Y-1 | PY139 | 11.00 | B1 | 1.59 | P1 | 4.4 | Q1 | 0.01 | J1 | 83.01 |
| R-1 | PR254 | 12.00 | B1 | 1.39 | P1 | 4.2 | Q1 | 0.01 | J1 | 82.40 |
| B-1 | PB15:6 | 10.00 | — | — | P1 | 5.38 | Q1 | 0.01 | J1 | 83.01 |
| | PV23 | 2.59 | | | | | | | | |
| Bk-1 | TiON | 12.00 | — | — | P1 | 4.2 | Q1 | 0.01 | J2 | 74.90 |
| IR-1 | K1 | 11.00 | B1 | 1.59 | P1 | 6.0 | Q1 | 0.01 | J1 | 81.41 |
| IR-2 | K2 | 6.70 | K3 | 0.80 | P1 | 6.0 | Q1 | 0.01 | J1 | 86.50 |
| IR-3 | K2 | 6.70 | K3 | 0.80 | P1 | 6.0 | Q1 | 0.01 | J1 | 86.50 |

Abbreviations shown in Tables 5 and 6 are as follows.
(Pigment)
PR254: C. I. Pigment Red 254
PG58: C. I. Pigment Green 58
PG36: C. I. Pigment Green 36
PY139: C. I. Pigment Yellow 139
PY150: C. I. Pigment Yellow 150
PY185: C. 1. Pigment Yellow 185
PB 15:6: C. 1. Pigment Blue 15:6
PV23: C. I. Pigment Violet 23
TiON: titanium black

K1, K2: compounds having the following structures

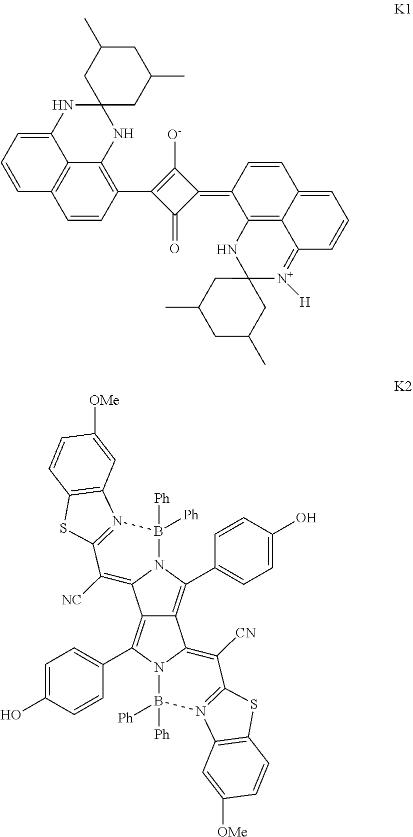

(Dispersion Aid)

B1: Compound Having the Following Structure

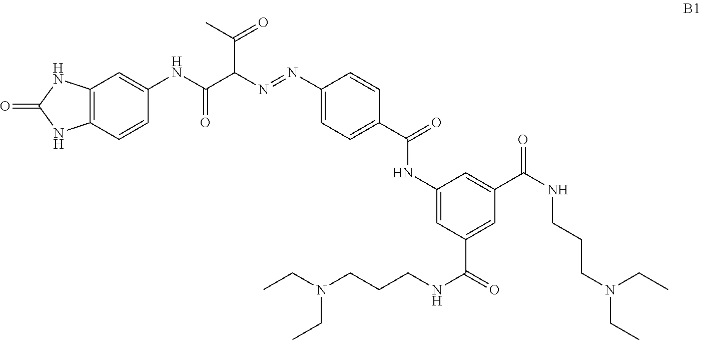 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

K3: Compound Having the Following Structure

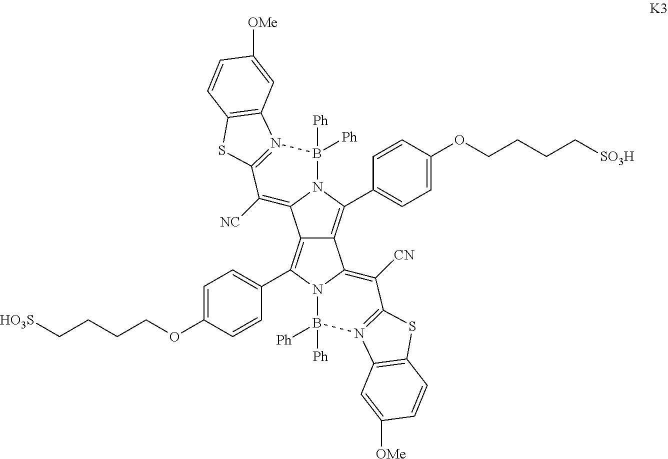

(Polymerization Inhibitor)

Q1: 2,2,6,6,-tetramethylpiperidin-1-oxyl (TEMPO) (manufactured by TOKYO CHEMICAL INDUSTRY CO., LTD.)

(Solvent)

J1: propylene glycol monomethyl ether acetate (PGMEA)

J2: cyclopentanone

### Examples 1 to 50 and Comparative Example 1

<Preparation of Curable Composition>

Raw materials described in Table 7 or 8 below were mixed to prepare a curable composition.

TABLE 7

| | Pigment dispersion | | Photopolymerization | | Polymerizable | | | | | | | |
|---|---|---|---|---|---|---|---|---|---|---|---|---|
| | liquid | | initiator | | compound | | Surfactant | | Solvent | | Evaluation | |
| | | Part by | | Part by | | Part by | | Part by | | Part by | | Storage |
| | Type | mass | Type | mass | Type | mass | Type | mass | Type | mass | Developability | stability |
| Example 1 | G-1 | 65 | I1 | 0.37 | M1 | 0.3 | H1 | 3.34 | J1 | 30.99 | 5 | 5 |
| Example 2 | G-2 | 65 | I1 | 0.37 | M1 | 0.3 | H1 | 3.34 | J1 | 30.99 | 5 | 4 |
| Example 3 | G-3 | 65 | I1 | 0.37 | M1 | 0.3 | H1 | 3.34 | J1 | 30.99 | 5 | 4 |
| Example 4 | G-4 | 65 | I1 | 0.37 | M1 | 0.3 | H1 | 3.34 | J1 | 30.99 | 5 | 4 |
| Example 5 | G-6 | 65 | I1 | 0.37 | M1 | 0.3 | H1 | 3.34 | J1 | 30.99 | 4 | 5 |
| Example 6 | G-9 | 65 | I1 | 0.37 | M1 | 0.3 | H1 | 3.34 | J1 | 30.99 | 4 | 5 |
| Example 7 | G-10 | 65 | I1 | 0.37 | M1 | 0.3 | H1 | 3.34 | J1 | 30.99 | 4 | 5 |
| Example 8 | G-11 | 65 | I1 | 0.37 | M1 | 0.3 | H1 | 3.34 | J1 | 30.99 | 4 | 5 |
| Example 9 | G-12 | 65 | I1 | 0.37 | M1 | 0.3 | H1 | 3.34 | J1 | 30.99 | 5 | 5 |
| Example 10 | G-13 | 65 | I1 | 0.37 | M1 | 0.3 | H1 | 3.34 | J1 | 30.99 | 4 | 5 |
| Example 11 | G-14 | 65 | I1 | 0.37 | M1 | 0.3 | H1 | 3.34 | J1 | 30.99 | 4 | 5 |
| Example 12 | G-15 | 65 | I1 | 0.37 | M1 | 0.3 | H1 | 3.34 | J1 | 30.99 | 5 | 4 |
| Example 13 | G-17 | 65 | I1 | 0.37 | M1 | 0.3 | H1 | 3.34 | J1 | 30.99 | 4 | 4 |
| Example 14 | G-18 | 65 | I1 | 0.37 | M1 | 0.3 | H1 | 3.34 | J1 | 30.99 | 4 | 4 |
| Example 15 | G-19 | 65 | I1 | 0.37 | M1 | 0.3 | H1 | 3.34 | J1 | 30.99 | 5 | 4 |
| Example 16 | G-20 | 65 | I1 | 0.37 | M1 | 0.3 | H1 | 3.34 | J1 | 30.99 | 5 | 4 |
| Example 17 | G-21 | 65 | I1 | 0.37 | M1 | 0.3 | H1 | 3.34 | J1 | 30.99 | 5 | 3 |
| Example 18 | G-22 | 65 | I1 | 0.37 | M1 | 0.3 | H1 | 3.34 | J1 | 30.99 | 5 | 3 |
| Example 19 | G-23 | 65 | I1 | 0.37 | M1 | 0.3 | H1 | 3.34 | J1 | 30.99 | 4 | 5 |
| Example 20 | G-24 | 65 | I1 | 0.37 | M1 | 0.3 | H1 | 3.34 | J1 | 30.99 | 4 | 5 |
| Example 21 | G-25 | 65 | I1 | 0.37 | M1 | 0.3 | H1 | 3.34 | J1 | 30.99 | 4 | 5 |
| Example 22 | G-26 | 65 | I1 | 0.37 | M1 | 0.3 | H1 | 3.34 | J1 | 30.99 | 4 | 5 |
| Example 23 | G-27 | 65 | I1 | 0.37 | M1 | 0.3 | H1 | 3.34 | J1 | 30.99 | 4 | 5 |
| Example 24 | G-28 | 65 | I1 | 0.37 | M1 | 0.3 | H1 | 3.34 | J1 | 30.99 | 4 | 4 |
| Example 25 | G-29 | 65 | I1 | 0.37 | M1 | 0.3 | H1 | 3.34 | J1 | 30.99 | 4 | 4 |
| Example 26 | G-30 | 65 | I1 | 0.37 | M1 | 0.3 | H1 | 3.34 | J1 | 30.99 | 4 | 4 |
| Example 27 | G-31 | 65 | I1 | 0.37 | M1 | 0.3 | H1 | 3.34 | J1 | 30.99 | 4 | 4 |
| Example 28 | G-32 | 65 | I1 | 0.37 | M1 | 0.3 | H1 | 3.34 | J1 | 30.99 | 4 | 4 |
| Example 29 | G-33 | 65 | I1 | 0.37 | M1 | 0.3 | H1 | 3.34 | J1 | 30.99 | 4 | 4 |
| Example 30 | G-34 | 65 | I1 | 0.37 | M1 | 0.3 | H1 | 3.34 | J1 | 30.99 | 4 | 4 |
| Example 31 | G-35 | 65 | I1 | 0.37 | M1 | 0.3 | H1 | 3.34 | J1 | 30.99 | 4 | 4 |
| Example 32 | G-36 | 65 | I1 | 0.37 | M1 | 0.3 | H1 | 3.34 | J1 | 30.99 | 4 | 4 |
| Example 33 | G-101 | 68 | I1 | 0.37 | M1 | 0.3 | H1 | 3.34 | J1 | 27.99 | 4 | 4 |
| Example 34 | G-102 | 68 | I1 | 0.37 | M1 | 0.4 | H1 | 3.34 | J1 | 27.89 | 3 | 4 |
| Comparative | CG-1 | 68 | I1 | 0.37 | M1 | 0.4 | H1 | 3.34 | J1 | 27.89 | 2 | 2 |
| example 1 | | | | | | | | | | | | |

TABLE 8

| | Pigment dispersion | | Photopolymerization | | Polymerizable | | | | | | | |
|---|---|---|---|---|---|---|---|---|---|---|---|---|
| | liquid | | initiator | | compound | | Surfactant | | Solvent | | Evaluation | |
| | | Part by | | Part by | | Part by | | Part by | | Part by | | Storage |
| | Type | mass | Type | mass | Type | mass | Type | mass | Type | mass | Developability | stability |
| Example 35 | G-1 | 65.00 | I1 | 0.37 | M1 | 0.3 | H1 | 3.34 | J1 | 30.99 | 5 | 5 |
| Example 36 | G-1 | 65.00 | I1 | 0.37 | M2 | 0.3 | H1 | 3.34 | J1 | 30.99 | 4 | 5 |
| Example 37 | G-1 | 65.00 | I1 | 0.37 | M1/ | 0.3 | H1 | 3.34 | J1 | 30.99 | 4 | 5 |
| | | | I1 | | M3 = 3/1 | | | | | | | |
| Example 38 | G-1 | 65.00 | I1 | 0.37 | M1/ | 0.3 | H1 | 3.34 | J1 | 30.99 | 4 | 5 |
| | | | | | M4 = 3/1 | | | | | | | |
| Example 39 | G-1 | 65.00 | I1 | 0.37 | M1/ | 0.3 | H1 | 3.34 | J1 | 30.99 | 4 | 5 |
| | | | | | M5 = 3/1 | | | | | | | |
| Example 40 | G-1 | 65.00 | I2 | 0.37 | M1 | 0.3 | H1 | 3.34 | J1 | 30.99 | 4 | 5 |
| Example 41 | G-1 | 65.00 | I3 | 0.37 | M1 | 0.3 | H1 | 3.34 | J1 | 30.99 | 4 | 5 |
| Example 42 | G-1 | 65.00 | I4 | 0.37 | M1 | 0.3 | H1 | 3.34 | J1 | 30.99 | 4 | 5 |
| Example 43 | G-1 | 65.00 | I1/ | 0.37 | M1 | 0.3 | H1 | 3.34 | J1 | 30.99 | 4 | 5 |
| | | | I5 = 1/1 | | | | | | | | | |
| Example 44 | G-1 | 65.00 | I1 | 0.37 | M1 | 0.3 | H1 | 3.34 | J1/ | 30.99 | 5 | 5 |
| | | | | | | | | | J2 = 1/1 | | | |
| Example 45 | R-19 | 48.2 | I1 | 0.37 | M1 | 0.1 | H1 | 3.34 | J1 | 26.79 | 5 | 5 |
| | Y-1 | 21.2 | | | | | | | | | | |
| Example 46 | B-1 | 71.30 | I1 | 0.37 | M1 | 0.1 | H1 | 3.24 | J1 | 24.99 | 5 | 5 |
| Example 47 | Bk-1 | 65.00 | I1 | 0.37 | M1 | 0.8 | H1 | 3.34 | J1 | 30.49 | 5 | 5 |
| Example 48 | IR-1 | 65.00 | I1 | 0.37 | M1 | 0.8 | H1 | 3.34 | J1 | 30.49 | 5 | 5 |
| Example 49 | IR-2 | 65.00 | I1 | 0.37 | M1 | 0.8 | H1 | 3.34 | J1 | 30.49 | 5 | 5 |
| Example 50 | IR-3 | 65.00 | I1 | 0.37 | M1 | 0.8 | H1 | 3.34 | J1 | 30.49 | 5 | 5 |

Abbreviations shown in Tables 7 and 8 other than those described above are as follows.

(Pigment Dispersion Liquid)

Pigment dispersion liquids R-1, Y-1, B-1, Bk-1: pigment dispersion liquids R-1, Y-1, B-1, and Bk-1 described above

Pigment dispersion liquids G-1 to G-36, G-101, G-102, G-1001: pigment dispersion liquids G-1 to G-36, G-101, G-102, and G-1001 described above

Pigment dispersion liquids IR-1 to IR-3: pigment dispersion liquids IR-1 to IR-3 described above

(Photopolymerization Initiator)

I2: IRGACURE OXE-03 (oxime-based polymerization initiator, manufactured by BASF)

I3: IRGACURE OXE-04 (oxime-based polymerization initiator, manufactured by BASF)

I4: ADEKA ARKLS NCI-831 (oxime-based polymerization initiator, manufactured by ADEKA Corporation, containing a nitro group)

I5: IRGACURE 369 (2-benzyl-2-dimethylamino-1l-(4-morpholinophenyl)-1-butanone, manufactured by BASF)

(Polymerizable Compound)

M1: compound shown below, in which a+b+c=3

M2: compound shown below, in which a+b+c=4

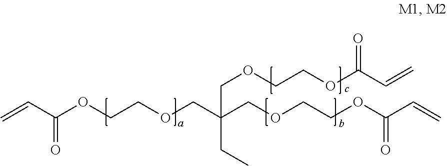

M3: KAYARAD DPHA (mixture of dipentaerythritol hexaacrylate and dipentaerythritol pentaacrylate, manufactured by Nippon Kayaku Co., Ltd.)

M4: UA-7200 (urethane acrylate, manufactured by Shin-Nakamura Chemical Co., Ltd.)

M5: compound shown below

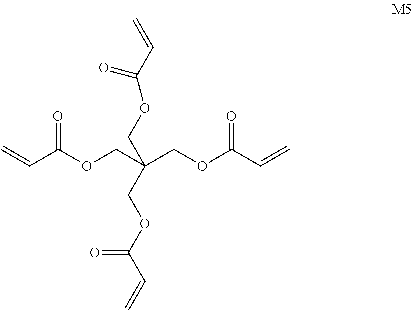 [SMILES: C=CC(=O)OCC(COC(=O)C=C)(COC(=O)C=C)COC(=O)C=C]

(Surfactant)

H1: fluorine-based surfactant, MEGAFACE F-781F (manufactured by DIC Corporation)

<Performance Evaluation>

(Evaluation of Storage Stability)

The viscosity of the curable product obtained as described above was measured by “RE-85L” manufactured by TOKI SANGYO CO., LTD. After that, the curable product was left to stand under the conditions of 45° C. and 3 days, and then the viscosity thereof was measured again. Storage stability was evaluated according to the following evaluation standard from a viscosity difference (ΔVis) before and after leaving to stand. It can be said that the smaller the numerical value of the viscosity difference (ΔVis), the better the storage stability.

The viscosity of the curable product was measured in a state in which the temperature was adjusted to 25° C. The evaluation standard is as follows, and the evaluation results are shown in Tables 7 and 8.

Evaluation “3” or higher is preferable, and “4” and “5” are evaluated as having excellent storage stability.

### [Evaluation Standard]

5: ΔVis was 0.5 mPa·s or less.

4: ΔVis was more than 0.5 mPa·s and 1.0 mPa·s or less.

3: ΔVis was more than 1.0 mPa·s and 2.0 mPa s or less.

2: ΔVis was more than 2.0 mPa·s and 5.0 mPa·s or less.

1: ΔVis was more than 5.0 mPa·s.

(Evaluation of Developability (Dispersibility))

A CT-4000L solution (manufactured by Fujifilm Electronic Materials Co., Ltd.; transparent base coat agent) was applied to a silicon wafer so that the thickness of a dried film was 0.1 μm, and dried to form a transparent film, and a heating treatment was performed at 220° C. for 5 minutes.

The above-described curable composition was applied using a spin coater such that the film thickness was 0.65 μm, and a heating treatment (pre-baking) was performed for 120 seconds using a hot plate at 100° C.

Next, using an i-ray stepper exposure device (product name: FPA-3000 i5+, manufactured by Canon Inc.), the composition layer was irradiated with light having a wavelength of 365 nm through a mask pattern in which each of the square pixels with a side length of 1.1 m was arranged on the substrate in a region of 4 mm×3 mm to perform exposure thereon with an exposure amount of 500 mJ/cm².

The composition layer after exposure was placed on a horizontal rotary table of a spin-shower developing machine (DW-30 Type, manufactured by Chemitronics Co., Ltd.), and was subjected to a puddle development at 23° C. for 60 seconds using CD-2000 (manufactured by FUJIFILM Electronic Materials Co., Ltd.). Thereafter, while rotating the silicon wafer substrate by a rotation device at a rotation speed of 50 r.p.m., the silicon wafer substrate was rinsed by supplying pure water from above the center of rotation in shower-like from an ejection nozzle, and then spray-dried. Using a length measuring scanning electron microscope (SEM) (S-7800H, manufactured by Hitachi, Ltd.), the obtained colored pattern (pixel) was observed at a magnification of 30,000 times from the silicon wafer. The evaluation was performed according to the following standard.

5: no residue was observed in the non-exposed portion.

4: 1 to 3 residues were observed in 1.1 μm square of the non-exposed portion.

3: 4 to 10 residues were observed in 1.1 m square of the non-exposed portion.

2: 11 to 100 residues were observed in 1.1 μm square of the non-exposed portion.

1: 101 or more residues were observed in 1.1 m square of the non-exposed portion.

From the results shown in Tables 7 and 8, it was found that Examples 1 to 50, which are the curable compositions of the resin according to the embodiment of the present disclosure, were superior in dispersibility and storage stability, as compared with the composition of Comparative Example 1.

In addition, in the pigment dispersion liquid G-1 of Example 1, even in a case where the dispersed resin P1 was changed to the dispersed resins P50 to P79 shown in Table 4, dispersibility and storage stability were obtained as in Examples 1 to 50.

### Examples 101 to 146

In Examples 101 to 146, the curable compositions of Examples 1 to 46 were used, respectively.

Such that color did not overlap with color of the curable composition, overlapping color compositions of Red composition, Green composition, and Blue composition, which will be described later, were used in place of the obtained curable compositions of Examples 1 to 46, respectively. For example, the color of the curable compositions of Examples 1 to 44 was Green, the color of the curable composition of Example 45 was Red, and the color of the curable composition of Example 46 was Blue.

A silicon wafer was coated with a Red composition by a spin coating method so that the thickness of a film after film formation was 1.0 μm. Next, the silicon wafer was heated using a hot plate at 100° C. for 2 minutes. Next, using an i-ray stepper exposure device FPA-3000 i5+(manufactured by Canon Inc.), exposure was performed at 1,000 mJ/cm² through a mask having a dot pattern of 2 μm square. Next, puddle development was performed at 23° C. for 60 seconds using a 0.3 mass % of tetramethylammonium hydroxide (TMAH) aqueous solution. Next, the coating film was rinsed by spin showering and was cleaned with pure water. Next, the coating film was heated using a hot plate at 200° C. for 5 minutes. As a result, the Red composition was patterned on the pattern of the infrared cut filter. Likewise, a Green composition and a Blue composition were sequentially patterned to form red, green, and blue colored patterns (Bayer pattern).

The Bayer pattern refers to a pattern, as disclosed in the specification of U.S. Pat. No. 3,971,065A, in which a 2×2 array of color filter element having one Red element, two Green elements, and one Blue element is repeated. This filter was incorporated into a solid-state imaging element using a known method.

The obtained solid-state imaging element was irradiated with infrared rays by an infrared light emitting diode (infrared LED) in a low-illuminance environment (0.001 Lux) to acquire images. Next, the imaging performance of the solid-state imaging element was evaluated.

In a case where any of the curable compositions obtained in Examples 1 to 46 was used, a solid-state imaging element having suitable image recognition ability and moisture resistance was obtained.

The Red composition, the Green composition, and the Blue composition other than the curable compositions of Examples 1 to 46, which were used in Examples 101 to 146, are as follows.

—Red Composition—

The following components were mixed and stirred, and the obtained mixture was filtered through a nylon filter (manufactured by Nihon Pall Corporation) having a pore size of 0.45 μm to prepare a Red composition.

Red pigment dispersion liquid: 51.7 parts by mass

Resin 4 (40 mass % PGMEA solution): 0.6 parts by mass

Polymerizable compound 4: 0.6 parts by mass

Photopolymerization initiator 1: 0.3 parts by mass

Surfactant 1: 4.2 parts by mass

PGMEA: 42.6 parts by mass

—Green Composition—

The following components were mixed and stirred, and the obtained mixture was filtered through a nylon filter (manufactured by Nihon Pall Corporation) having a pore size of 0.45 μm to prepare a Green composition.

Green pigment dispersion liquid: 73.7 parts by mass

Resin 4 (40 mass % PGMEA solution): 0.3 parts by mass

Polymerizable compound 1: 1.2 parts by mass

Photopolymerization initiator 1: 0.6 parts by mass

Surfactant 1: 4.2 parts by mass

Ultraviolet absorber (UV-503, manufactured by Daito Chemical Co., Ltd.): 0.5 parts by mass

PGMEA: 19.5 parts by mass

—Blue Composition—

The following components were mixed and stirred, and the obtained mixture was filtered through a nylon filter (manufactured by Nihon Pall Corporation) having a pore size of 0.45 μm to prepare a Blue composition.

Blue pigment dispersion liquid: 44.9 parts by mass

Resin 4 (40 mass % PGMEA solution): 2.1 parts by mass

Polymerizable compound 1: 1.5 parts by mass

Polymerizable compound 4: 0.7 parts by mass

Photopolymerization initiator 1: 0.8 parts by mass

Surfactant 1: 4.2 parts by mass

PGMEA: 45.8 parts by mass

Raw materials used in the Red composition, the Green composition, and the Blue composition are as follows.

Red Pigment Dispersion Liquid

A mixed solution consisting of 9.6 parts by mass of C. I. Pigment Red 254, 4.3 parts by mass of C. I. Pigment Yellow 139, 6.8 parts by mass of a dispersant (Disperbyk-161, manufactured by BYK Chemie), and 79.3 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining a Red pigment dispersion liquid.

Green Pigment Dispersion Liquid

A mixed solution consisting of 6.4 parts by mass of C. I. Pigment Green 36, 5.3 parts by mass of C. I. Pigment Yellow 150, 5.2 parts by mass of a dispersant (Disperbyk-161, manufactured by BYK Chemie), and 83.1 parts by mass of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times. As a result, a Green pigment dispersion liquid was obtained.

Blue Pigment Dispersion Liquid

A mixed solution consisting of 9.7 parts by mass of C. I. Pigment Blue 15:6, 2.4 parts by mass of C. I. Pigment Violet 23, 5.5 parts of a dispersant (Disperbyk-161, manufactured by BYK Chemie), and 82.4 parts of PGMEA was mixed and dispersed using a beads mill (zirconia beads; diameter: 0.3 mm) for 3 hours to prepare a pigment dispersion liquid. Next, using a high-pressure disperser NANO-3000-10 (manufactured by Nippon BEE Chemical Co., Ltd.) equipped with a pressure reducing mechanism, the pigment dispersion liquid was further dispersed under a pressure of 2,000 kg/cm³ at a flow rate of 500 g/min. This dispersion treatment was repeated 10 times, thereby obtaining a Blue pigment dispersion liquid.
Polymerizable compound 1: KAYARAD DPHA (mixture of dipentaerythritol hexaacrylate and dipentaerythritol pentaacrylate, manufactured by Nippon Kayaku Co., Ltd.)
Polymerizable compound 4: following structure

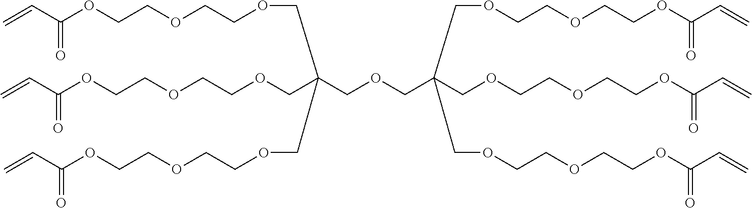 [SMILES: C=CC(=O)OCCOCCOCC(COCCOCCOC(=O)C=C)(COCCOCCOC(=O)C=C)COCC(COCCOCCOC(=O)C=C)(COCCOCCOC(=O)C=C)COCCOCCOC(=O)C=C]

Polymerizable compound 5: following structure (mixture in which a molar ratio between a left compound and a right compound is 7:3)

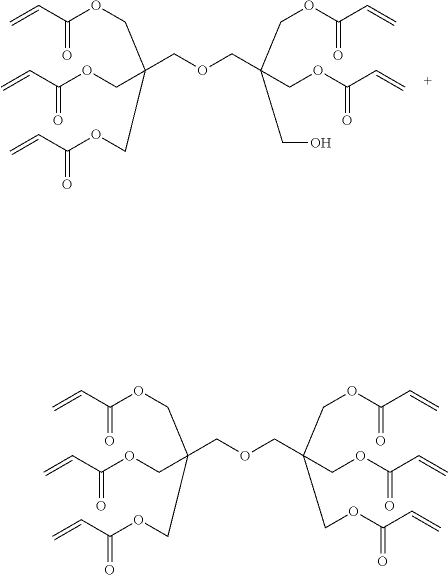

Resin 4: following structure (acid value: 70 mgKOH/g, Mw=11,000; a ratio in a constitutional unit is a molar ratio)

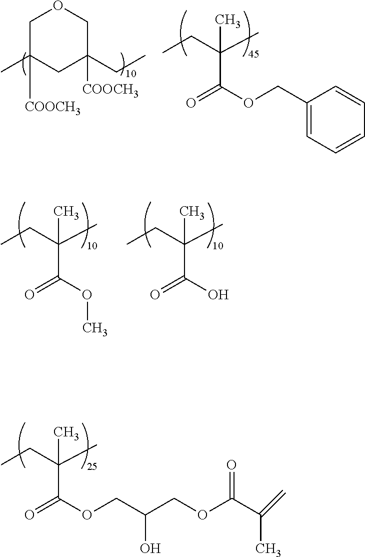

Photopolymerization Initiator 1: IRGACURE-OXE01

### 1-[4-(phenylthio)]-1,2-octanedione-2-(O-benzoyloxime), manufactured by BASF

Surfactant 1: 1 mass % PGMEA solution of the following mixture (Mw: 14,000; in the following formula, the unit of % (62% and 38%) indicating the proportion of a constitutional unit is mass %)

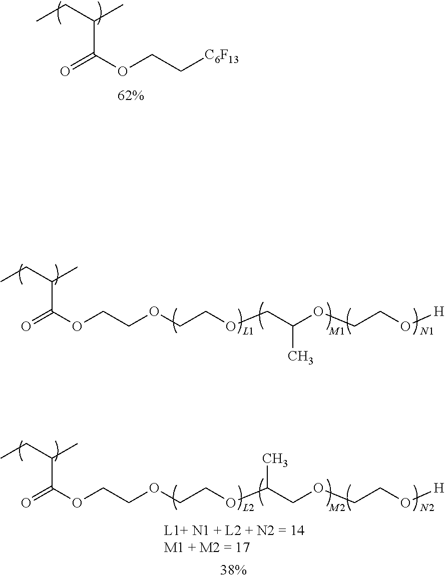

The disclosure of Japanese Patent Application No. 2019-158702 filed on Aug. 30, 2019 is incorporated in the present specification by reference.

All documents, patent applications, and technical standards described in the present specification are incorporated herein by reference to the same extent as in a case of being specifically and individually noted that individual documents, patent applications, and technical standards are incorporated by reference.

What is claimed is:

1. A resin having a graft structure represented by Formula (1),
P¹—S—X¹-L-* (1)
in Formula (1), P¹ represents a polymer chain, X¹ represents an alkylene group having a length of 3 or more atoms, L represents a single bond or a divalent linking group, and * represents a connection position with a structure including a main chain.

2. The resin according to claim 1,
wherein P¹ is a poly(meth)acrylate chain.

3. The resin according to claim 1,
wherein L is a linking group including a urethane bond, a urea bond, an ester bond, an amide bond, or an ether bond.

4. The resin according to claim 1,
wherein the number of consecutive carbon atoms included in X¹ is 3 to 20.

5. The resin according to claim 1,
wherein the resin is an acrylic resin, a polyester resin, a polyamide resin, or a polyurethane resin.

6. The resin according to claim 1,
wherein the resin is a dispersant.

7. A curable composition comprising:
the resin according to claim 1.

8. A cured product obtained by curing the curable composition according to claim 7.

9. A color filter comprising:
the cured product according to claim 8.

10. A solid-state imaging element comprising:
the color filter according to claim 9.

11. An image display device comprising:
the color filter according to claim 9.

12. A polymer compound represented by Formula (1a),
P¹—S—X¹-L-Z (1a)
in Formula (1a), P¹ represents a polymer chain, X¹ represents a divalent linking group having a length of 3 or more atoms, L represents a single bond or a divalent linking group, and Z¹ represents an ethylenically unsaturated group or a group having a diol structure, a diamine structure, or an amino alcohol structure.

13. The polymer compound according to claim 12,
wherein P¹ is a poly(meth)acrylate chain.

14. The polymer compound according to claim 12,
wherein L is a linking group including a urethane bond, a urea bond, an ester bond, an amide bond, or an ether bond.

15. The polymer compound according to claim 12,
wherein the ethylenically unsaturated group in Z¹ includes a (meth)acryloxy group.

16. The polymer compound according to claim 13,
wherein the number of consecutive carbon atoms included in X¹ is 3 to 20.
